(19) United States
(12) Patent Application Publication
(10) Pub. No.: US 2025/0015078 A1
(43) Pub. Date: Jan. 9, 2025

(54) SEMICONDUCTOR DEVICE

(71) Applicant: ROHM CO., LTD., Kyoto-shi (JP)

(72) Inventors: Seigo MORI, Kyoto-shi (JP); Yuki NAKANO, Kyoto-shi (JP); Keigo MINODE, Kyoto-shi (JP)

(73) Assignee: ROHM CO., LTD., Kyoto-shi (JP)

(21) Appl. No.: 18/895,440

(22) Filed: Sep. 25, 2024

Related U.S. Application Data
(63) Continuation of application No. PCT/JP2023/006633, filed on Feb. 24, 2023.

(30) Foreign Application Priority Data
Mar. 31, 2022 (JP) 2022-061314
Mar. 31, 2022 (JP) 2022-061316

(51) Int. Cl. H01L 27/06; H01L 29/417; H01L 29/78

(52) U.S. Cl. CPC H01L 27/0629; H01L 28/20; H01L 29/41741; H01L 29/7813

(57) ABSTRACT

A semiconductor device includes a chip that has a main surface, a gate resistor that includes a trench resistor structure formed in the main surface, a gate pad that has a lower resistance value than the trench resistor structure and is arranged on the main surface such as to be electrically connected to the trench resistor structure, and a gate wiring that has a lower resistance value than the trench resistor structure and is arranged on the main surface such as to be electrically connected to the gate pad via the trench resistor structure.

### CROSS-REFERENCE TO RELATED APPLICATIONS

The present application is a bypass continuation of International Patent Application No. PCT/JP2023/006633, filed on Feb. 24, 2023, which claims priority to Japanese Patent Application No. 2022-061314 filed on Mar. 31, 2022 and Japanese Patent Application No. 2022-061316 filed on Mar. 31, 2022, and the entire disclosures of those applications are hereby incorporated herein by reference.

### BACKGROUND

### 1. Field of the Disclosure

The present invention relates to a semiconductor device.

### 2. Description of the Related Art

US2017/0040423A1 discloses a semiconductor device that includes a semiconductor substrate, a plurality of trench structures, and a gate pad portion. The plurality of trench structures are formed in a front surface of the semiconductor substrate. The gate pad portion is arranged on the semiconductor substrate such as to cover the plurality of trench structures.

### BRIEF DESCRIPTION OF THE DRAWINGS

FIG. 1 is a plan view showing a semiconductor device according to an embodiment.

FIG. 2 is a cross sectional view taken along line II-II shown in FIG. 1.

FIG. 3 is a plan view showing a layout of a gate electrode and a source electrode.

FIG. 4 is a plan view showing a layout of a first main surface.

FIG. 5 is an enlarged plan view showing a layout of an active region.

FIG. 6 is an enlarged plan view showing a layout of a peripheral edge region.

FIG. 7 is a cross sectional view taken along line VII-VII shown in FIG. 5.

FIG. 8 is a cross sectional view taken along line VIII-VIII shown in FIG. 5.

FIG. 9 is a cross sectional view taken along line IX-IX shown in FIG. 6.

FIG. 10 is a cross sectional view taken along line X-X shown in FIG. 6.

FIG. 11 is a cross sectional view taken along line XI-XI shown in FIG. 6.

FIG. 12 is a cross sectional view taken along line XII-XII shown in FIG. 6.

FIG. 13 is an enlarged plan view showing a layout of a terminal region.

FIG. 14 is an enlarged plan view showing a layout of a gate resistor.

FIG. 15 is an enlarged plan view showing an inner portion of the gate resistor.

FIG. 16 is an enlarged plan view showing a peripheral edge portion of the gate resistor.

FIG. 17 is a cross sectional view taken along line XVII-XVII shown in FIG. 15.

FIG. 18 is a cross sectional view taken along line XVIII-XVIII shown in FIG. 15.

FIG. 19 is a cross sectional view taken along line XIX-XIX shown in FIG. 16.

FIG. 20 is a cross sectional view taken along line XX-XX shown in FIG. 16.

FIG. 21 is a cross sectional view taken along line XXI-XXI shown in FIG. 16.

FIG. 22 is a cross sectional view taken along line XXII-XXII shown in FIG. 16.

FIG. 23 is an enlarged plan view showing a principal part of the gate resistor.

FIG. 24 is an enlarged plan view showing a layout of a terminal dummy structure.

FIG. 25 is a more enlarged plan view showing a layout of the terminal dummy structure.

FIG. 26 is a cross sectional view taken along line XXVI-XXVI shown in FIG. 25.

FIG. 27 is an electric circuit diagram showing a connection configuration of the gate electrode and the gate resistor.

FIG. 28 is a cross sectional view showing a structure of an outer region.

FIG. 29 is a cross sectional view showing trench resistor structures according to a first modification example.

FIG. 30 is a cross sectional view showing the trench resistor structures according to a second modification example.

FIG. 31 is an enlarged plan view showing the trench resistor structures according to a third modification example.

FIG. 32 is an enlarged plan view showing a gate pad according to a modification example.

FIG. 33 is a cross sectional view showing a chip according to a first modification example.

FIG. 34 is a cross sectional view showing the chip according to a second modification example.

### DETAILED DESCRIPTION OF THE PREFERRED EMBODIMENTS

Hereinafter, embodiments shall be described in detail with reference to attached drawings. The attached drawings are schematic views and are not strictly illustrated, and scales and the like thereof do not always match. Also, identical reference signs are given to corresponding structures among the attached drawings and duplicate descriptions thereof shall be omitted or simplified. For the structures whose description have been omitted or simplified, the description given before the omission or simplification shall apply.

When the wording “substantially equal” is used in a description in which a comparison target is present, the wording includes a numerical value (shape) equal to a numerical value (shape) of the comparison target and also includes numerical errors (shape errors) in a range of ±10% on a basis of the numerical value (shape) of the comparison target. Although the wordings “first,” “second,” “third,” etc., are used with the embodiments, these are symbols attached to names of respective structures in order to clarify the order of description and are not attached with an intention of restricting the names of the respective structures.

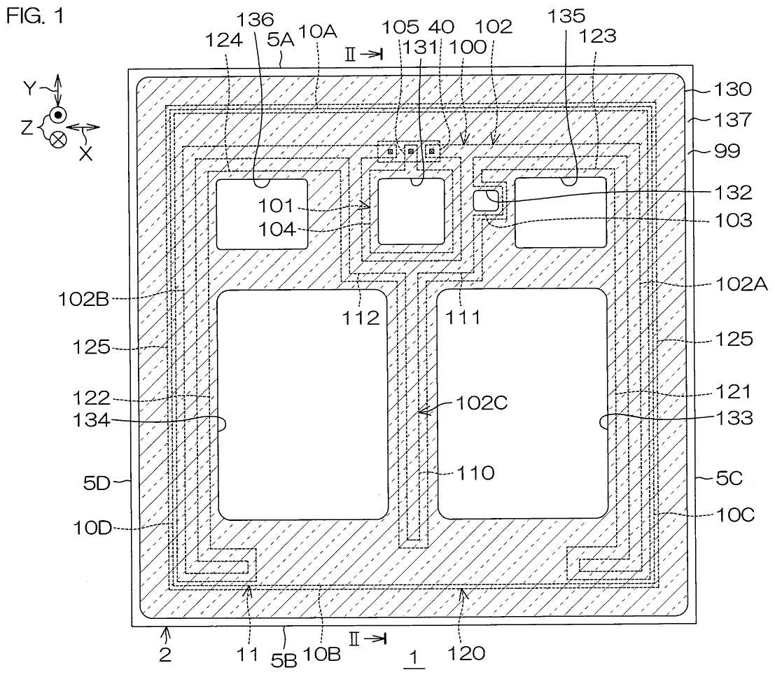

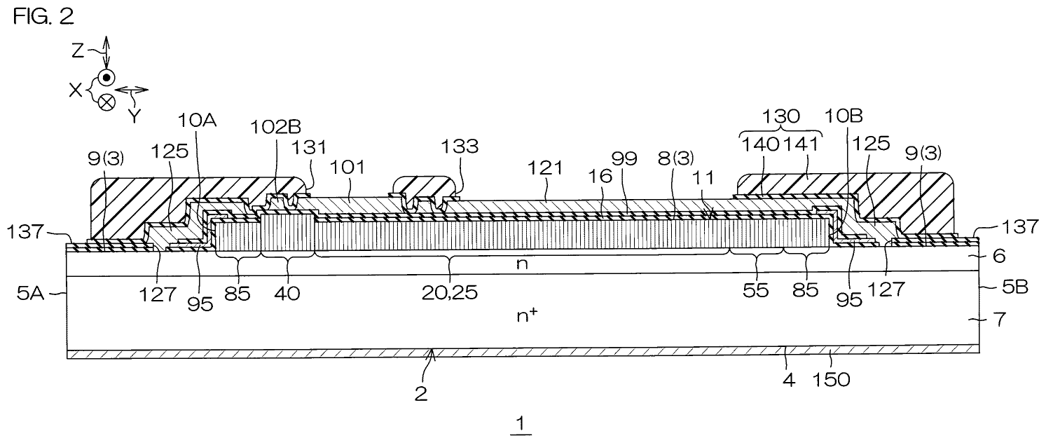

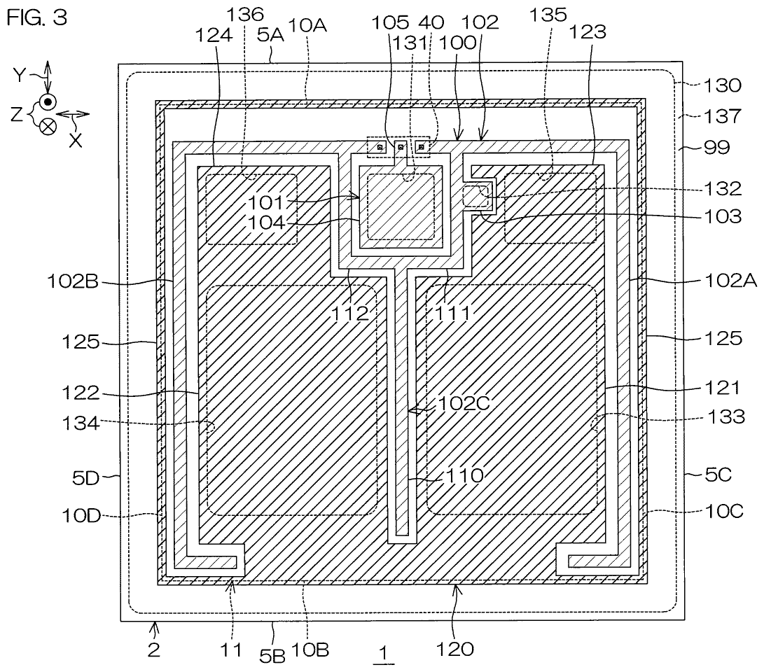

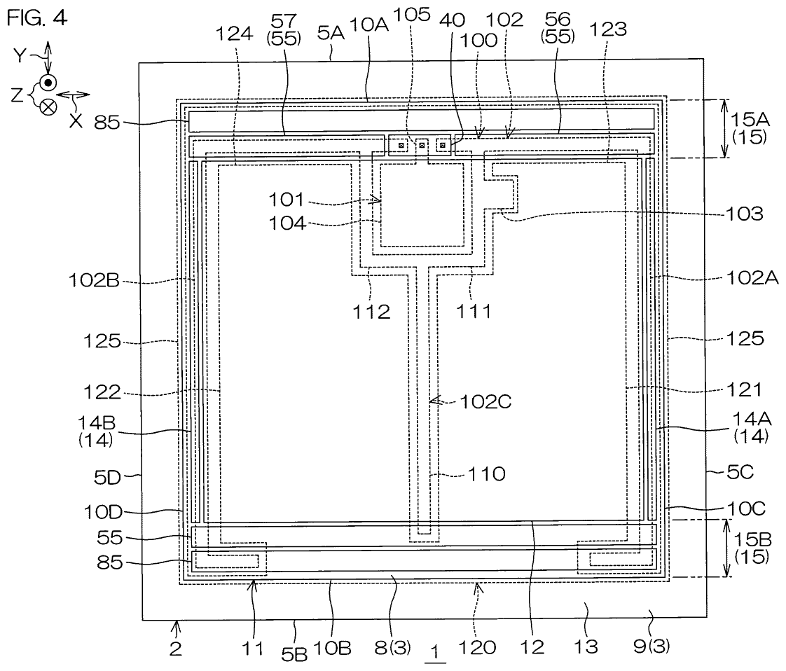

FIG. 1 is a plan view showing a semiconductor device 1 according to an embodiment. FIG. 2 is a cross sectional view taken along line II-II shown in FIG. 1. FIG. 3 is a plan view showing a layout of a gate electrode 100 and a source electrode 120. FIG. 4 is a plan view showing a layout of a first main surface 3. With reference to FIG. 1 to FIG. 4, the semiconductor device 1 is a semiconductor switching device that includes a MISFET (metal insulator semiconductor field effect transistor).

In this embodiment, the semiconductor device 1 includes a chip 2 including a monocrystal of a wide bandgap semiconductor and formed in a hexahedral shape (specifically, a rectangular parallelepiped shape). That is, the semiconductor device 1 is a “wide bandgap semiconductor device.” The chip 2 may also be referred to as a “semiconductor chip” or a “wide bandgap semiconductor chip.” The wide bandgap semiconductor is a semiconductor that has a bandgap exceeding a bandgap of Si (silicon). GaN (galliumnitride), SiC (silicon carbide), and C (diamond) can be given as examples of the wide bandgap semiconductor.

In this embodiment, the chip 2 is an “SiC chip” that includes, as an example of the wide bandgap semiconductor, an SiC monocrystal that is a hexagonal crystal. That is, the semiconductor device 1 is an “SiC semiconductor device.” The semiconductor device 1 may also be referred to as an “SiC-MISFET.” The SiC monocrystal that is a hexagonal crystal has multiple polytypes including a 2H (hexagonal)-SiC monocrystal, a 4H-SiC monocrystal, a 6H-SiC monocrystal, etc. In this embodiment, an example in which the chip 2 includes the 4H-SiC monocrystal is given, but the chip 2 may include another polytype instead.

The chip 2 has a first main surface 3 on one side, a second main surface 4 on the other side, and first to fourth side surfaces 5A to 5D connecting the first main surface 3 and the second main surface 4. The first main surface 3 and the second main surface 4 are each formed in a quadrangle shape in plan view as viewed from a normal direction Z thereto (hereinafter, simply referred to as “in plan view”). The normal direction Z is also a thickness direction of the chip 2. Preferably, the first main surface 3 and the second main surface 4 are each formed by a c-plane of the SiC monocrystal.

In this case, preferably, the first main surface 3 is formed by a silicon surface ((0001) surface) of the SiC monocrystal, and the second main surface 4 is formed by a carbon surface (000-1) surface) of the SiC monocrystal. The first main surface 3 and the second main surface 4 may each have an off angle inclined in a predetermined off direction at a predetermined angle with respect to the c-plane. The off direction is preferably an a-axis direction ([11-20] direction) of the SiC monocrystal. The off angle may exceed 0° and be not more than 10°. The off angle is preferably not more than 5°.

The first side surface 5A and the second side surface 5B extend in a first direction X along the first main surface 3 and are opposed in a second direction Y intersecting (specifically, orthogonal to) the first direction X. The third side surface 5C and the fourth side surface 5D extend in the second direction Y and are opposed in the first direction X. The first direction X may be an m-axis direction ([1-100] direction) of the SiC monocrystal and the second direction Y may be the a-axis direction of the SiC monocrystal. As a matter of course, the first direction X may be the a-axis direction of the SiC monocrystal and the second direction Y may be the m-axis direction of the SiC monocrystal instead.

The chip 2 may have a thickness of not less than 5 μm and not more than 200 μm. The thickness of the chip 2 may be set to a value belonging to any one range among not less than 5 μm and not more than 25 μm, not less than 25 μm and not more than 50 μm, not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, and not less than 175 μm and not more than 200 μm. The thickness of the chip 2 is preferably not more than 100 μm.

The first to fourth side surfaces 5A to 5D may each have a length of not less than 0.5 mm and not more than 20 mm in plan view. The length of each of the first to fourth side surfaces 5A to 5D may be set to a value belonging to any one range among not less than 0.5 mm and not more than 5 mm, not less than 5 mm and not more than 10 mm, not less than 10 mm and not more than 15 mm, and not less than 15 mm and not more than 20 mm. The length of each of the first to fourth side surfaces 5A to 5D is preferably not less than 5 mm.

The semiconductor device 1 includes a first semiconductor region 6 of an n-type that is formed in a region (surface layer portion) inside the chip 2 at the first main surface 3 side. The first semiconductor region 6 is formed in a layered shape extending along the first main surface 3 and is exposed from the first main surface 3 and the first to fourth side surfaces 5A to 5D. In this embodiment, the first semiconductor region 6 consists of an epitaxial layer (specifically, an SiC epitaxial layer). The first semiconductor region 6 may have a thickness of not less than 1 μm and not more than 50 μm. The thickness of the first semiconductor region 6 is preferably not less than 3 μm and not more than 30 μm. The thickness of the first semiconductor region 6 is particularly preferably not less than 5 μm and not more than 25 μm.

The semiconductor device 1 includes a second semiconductor region 7 of the n-type that is formed in a region (surface layer portion) inside the chip 2 at the second main surface 4 side. The second semiconductor region 7 is formed in a layered shape extending along the second main surface 4 and is exposed from the second main surface 4 and the first to fourth side surfaces 5A to 5D. The second semiconductor region 7 has a higher n-type impurity concentration than the first semiconductor region 6 and is electrically connected to the first semiconductor region 6.

In this embodiment, the second semiconductor region 7 consists of a semiconductor substrate (specifically, an SiC semiconductor substrate). That is, the chip 2 has a laminated structure including the semiconductor substrate and the epitaxial layer. The second semiconductor region 7 may have a thickness of not less than 1 μm and not more than 200 μm. The thickness of the second semiconductor region 7 may be not more than 150 μm, not more than 100 μm, not more than 50 μm, or not more than 40 μm. The thickness of the second semiconductor region 7 may be not less than 5 μm. The thickness of the second semiconductor region 7 is preferably not less than 10 μm. In this embodiment, the second semiconductor region 7 has the thickness that exceeds the thickness of the first semiconductor region 6.

The semiconductor device 1 includes an active surface 8 (active surface), an outer surface 9 (outer surface), and first to fourth connecting surfaces 10A to 10D (connecting surfaces) that are formed in the first main surface 3. The active surface 8, the outer surface 9, and the first to fourth connecting surfaces 10A to 10D demarcate an active mesa 11 in the first main surface 3. The active surface 8 may also be referred to as a “first surface portion,” the outer surface 9 may also be referred to as a “second surface portion,” and the first to fourth connecting surfaces 10A to 10D may also be referred to as “connecting surface portions.” The active surface 8, the outer surface 9, and the first to fourth connecting surfaces 10A to 10D (that is, the active mesa 11) may be considered as components of the chip 2 (the first main surface 3).

The active surface 8 is formed at an interval inward from a peripheral edge of the first main surface 3 (the first to fourth side surfaces 5A to 5D). The active surface 8 has a flat surface extending in the first direction X and the second direction Y. In this embodiment, the active surface 8 is formed by a c-plane (Si surface). In this embodiment, the active surface 8 is formed in a quadrangle shape having four sides parallel to the first to fourth side surfaces 5A to 5D in plan view.

The outer surface 9 is positioned outside the active surface 8 and is recessed in the thickness direction of the chip 2 (toward the second main surface 4 side) from the active surface 8. Specifically, the outer surface 9 is recessed to a depth less than the thickness of the first semiconductor region 6 such as to expose the first semiconductor region 6. The outer surface 9 extends in a band shape along the active surface 8 and is formed in an annular shape (specifically, a quadrangle annular shape) surrounding the active surface 8 in plan view.

The outer surface 9 has a flat surface extending in the first direction X and the second direction Y and is formed substantially parallel to the active surface 8. In this embodiment, the outer surface 9 is formed by a c-plane (Si surface). The outer surface 9 is continuous to the first to fourth side surfaces 5A to 5D. The outer surface 9 has an outer depth DO. The outer depth DO may be not less than 0.1 μm and not more than 5 μm. The outer depth DO is preferably not more than 2.5 μm.

The first to fourth connecting surfaces 10A to 10D extend in the normal direction Z and connect the active surface 8 and the outer surface 9. The first connecting surface 10A is positioned at the first side surface 5A side, the second connecting surface 10B is positioned at the second side surface 5B side, the third connecting surface 10C is positioned at the third side surface 5C side, and the fourth connecting surface 10D is positioned at the fourth side surface 5D side. The first connecting surface 10A and the second connecting surface 10B extend in the first direction X and are opposed in the second direction Y. The third connecting surface 10C and the fourth connecting surface 10D extend in the second direction Y and are opposed in the first direction X.

The first to fourth connecting surfaces 10A to 10D may extend substantially vertically between the active surface 8 and the outer surface 9 such as to demarcate the active mesa 11 of a quadrangle columnar shape. The first to fourth connecting surfaces 10A to 10D may be downwardly inclined obliquely from the active surface 8 toward the outer surface 9 such as to demarcate the active mesa 11 of a quadrangle pyramid shape instead. The semiconductor device 1 thus includes the active mesa 11 that is demarcated in a projecting shape in the first semiconductor region 6 at the first main surface 3. The active mesa 11 is formed only in the first semiconductor region 6 and is not formed in the second semiconductor region 7.

With reference to FIG. 4, the semiconductor device 1 includes an active region 12, an outer region 13, a peripheral edge region 14, and a terminal region 15. The active region 12 is provided in the active surface 8. Specifically, the active region 12 is provided in an inner portion of the active surface 8 at intervals from a peripheral edge of the active surface 8 (the first to fourth connecting surfaces 10A to 10D). In this embodiment, the active region 12 is provided in a quadrangle shape having four sides parallel to the first to fourth side surfaces 5A to 5D in plan view. The outer region 13 is provided in the outer surface 9. In this embodiment, the outer region 13 is provided in an annular shape (specifically, a quadrangle annular shape) surrounding the active surface 8 (active mesa 11) in plan view.

The peripheral edge region 14 is provided in the active surface 8 in a region between the active region 12 and the outer region 13. The peripheral edge region 14 is provided such as to sandwich the active region 12 from both sides in the first direction X and extends in a band shape in the second direction Y. The peripheral edge region 14 includes a first peripheral edge region 14A and a second peripheral edge region 14B. The first peripheral edge region 14A is provided at the third side surface 5C side (third connecting surface 10C side) with respect to the active region 12 and the second peripheral edge region 14B is provided at the fourth side surface 5D side (fourth connecting surface 10D side) with respect to the active region 12.

The terminal region 15 is provided in the active surface 8 in a region between the active region 12 and the outer region 13. The terminal region 15 provided such as to sandwich the active region 12 from both sides in the second direction Y and extends in a band shape in the first direction X. The terminal region 15 includes a first terminal region 15A and a second terminal region 15B. The first terminal region 15A is provided at the first side surface 5A side (first connecting surface 10A side) with respect to the active region 12 and the second terminal region 15B is provided at the second side surface 5B side (second connecting surface 10B side) with respect to the active region 12.

The semiconductor device 1 includes a main surface insulating film 16 that covers the first main surface 3. The main surface insulating film 16 selectively covers the active surface 8, the outer surface 9, and the first to fourth connecting surfaces 10A to 10D. The main surface insulating film 16 may include at least one among a silicon oxide film, a silicon nitride film, and silicon oxynitride film.

In this embodiment, the main surface insulating film 16 has a single layer structure consisting of the silicon oxide film. The main surface insulating film 16 particularly preferably includes the silicon oxide film that consists of an oxide of the chip 2. In this embodiment, the main surface insulating film 16 is continuous to the first to fourth side surfaces 5A to 5D. As a matter of course, a wall portion of the main surface insulating film 16 may be formed at an interval inward from a peripheral edge of the outer surface 9 and expose the first semiconductor region 6 from a peripheral edge portion of the outer surface 9.

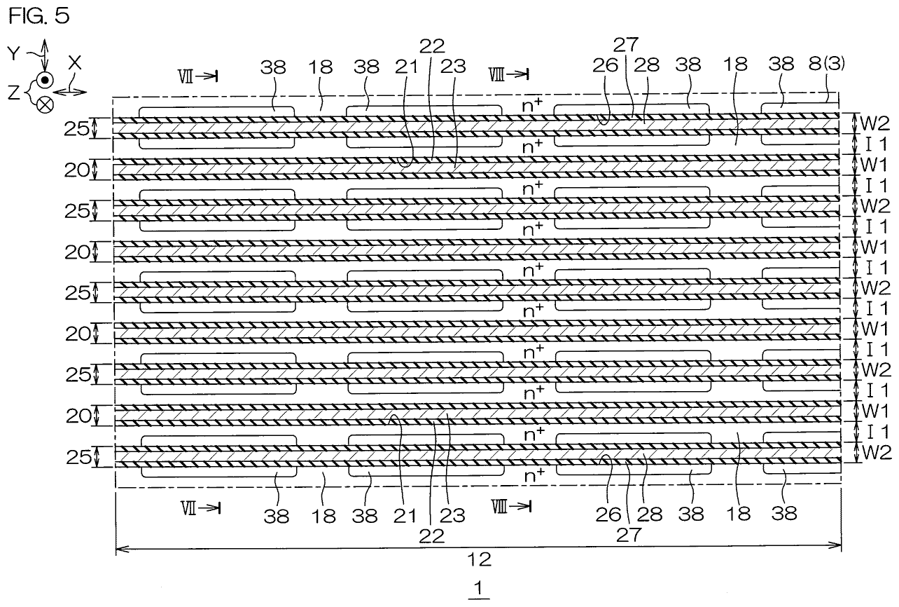

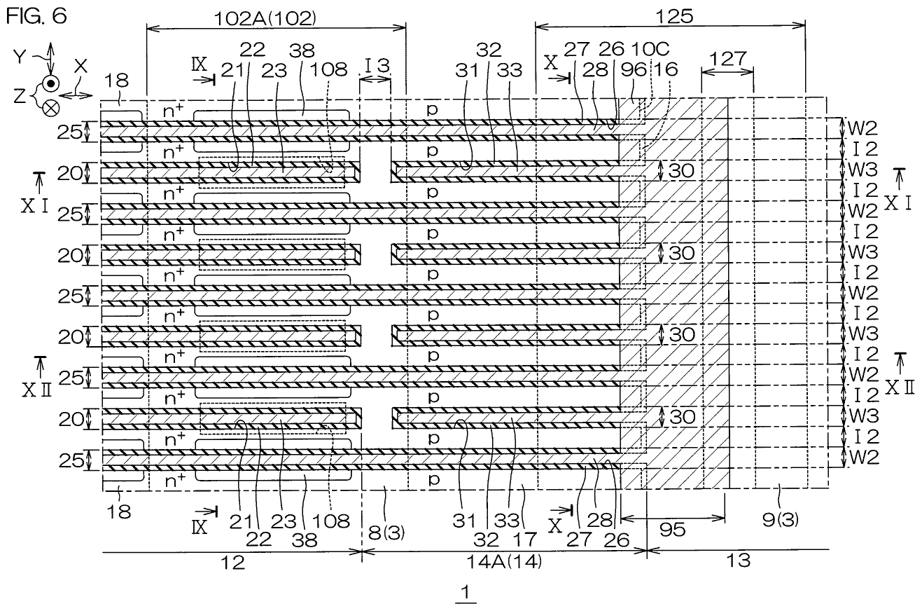

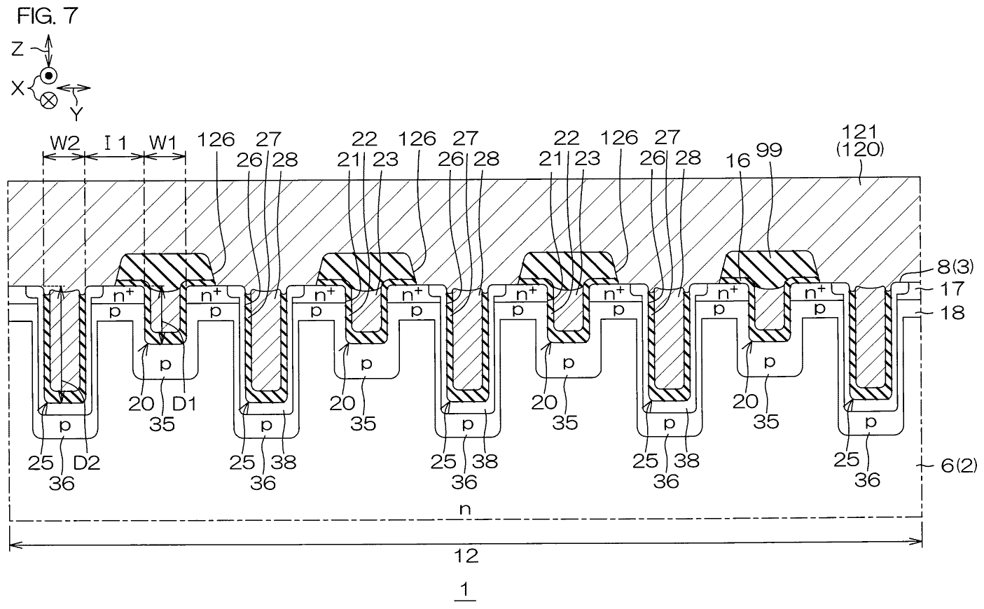

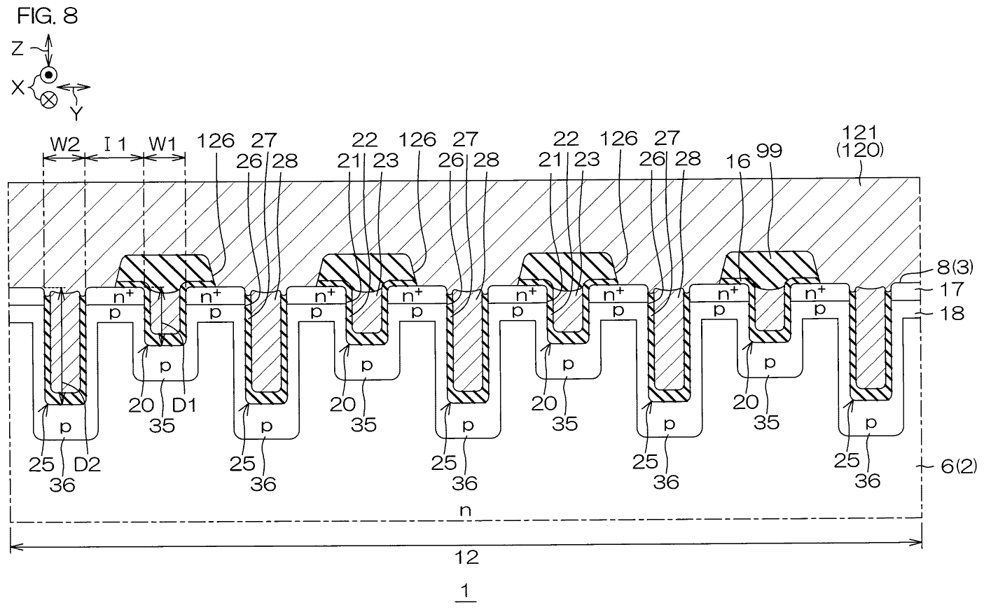

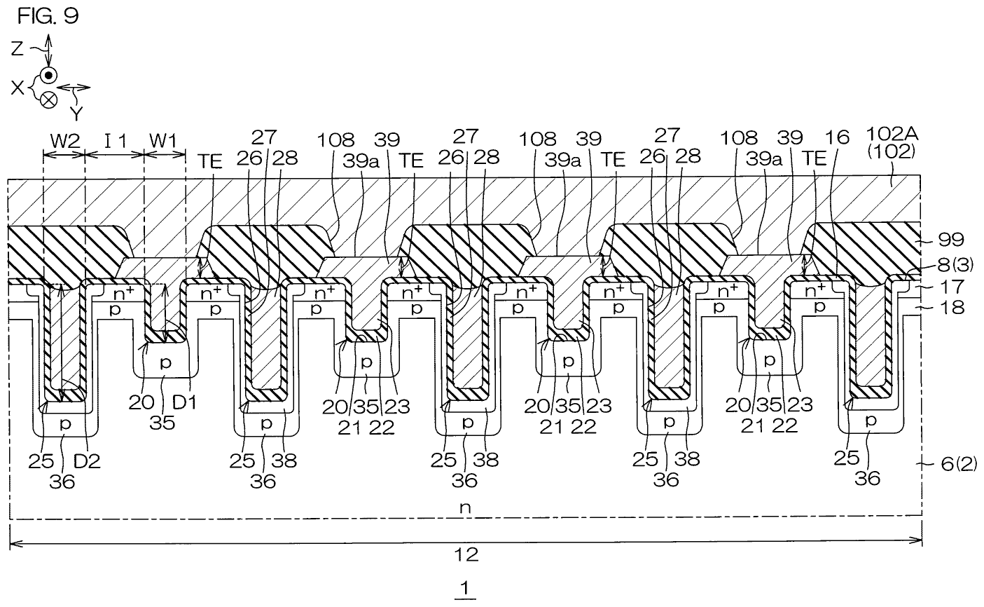

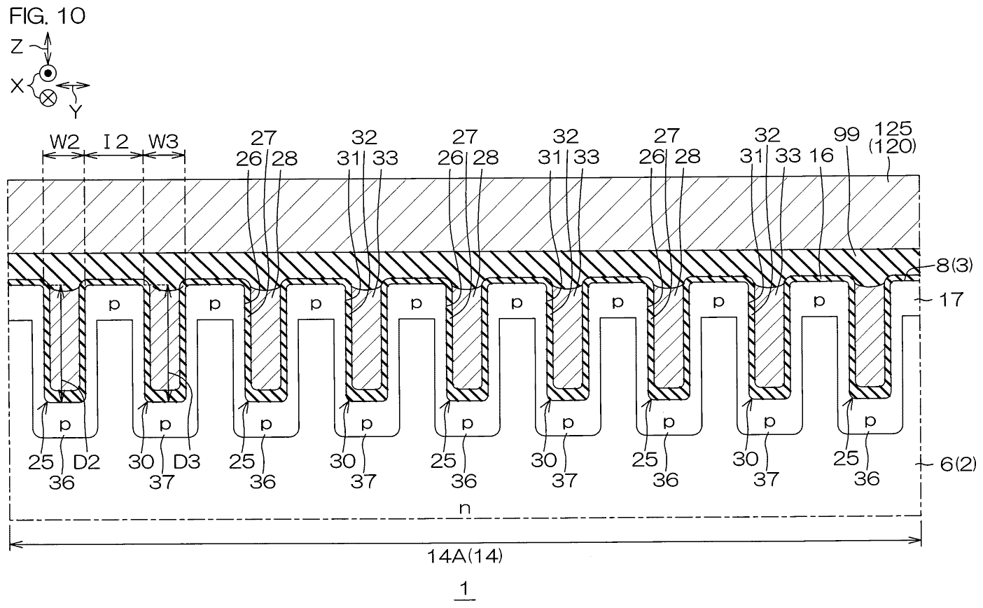

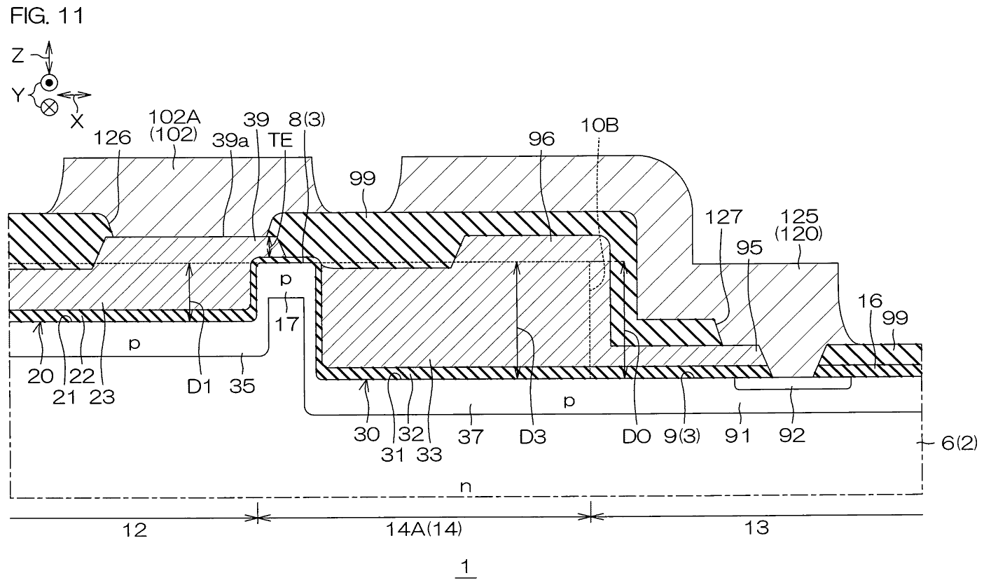

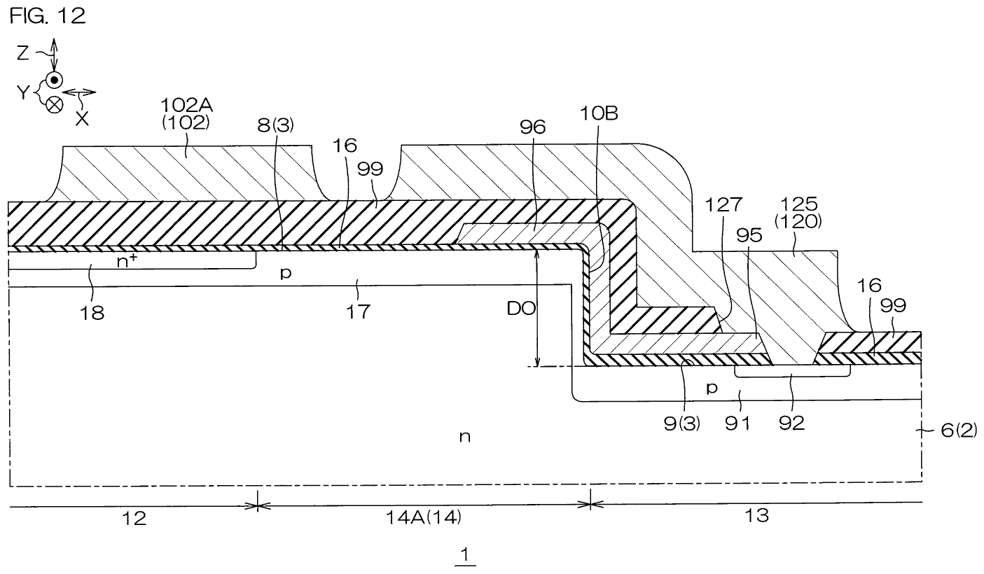

FIG. 5 is an enlarged plan view showing a layout of the active region 12. FIG. 6 is an enlarged plan view showing a layout of the peripheral edge region 14. FIG. 7 is a cross sectional view taken along line VII-VII shown in FIG. 5. FIG. 8 is a cross sectional view taken along line VIII-VIII shown in FIG. 5. FIG. 9 is a cross sectional view taken along line IX-IX shown in FIG. 6. FIG. 10 is a cross sectional view taken along line X-X shown in FIG. 6. FIG. 11 is a cross sectional view taken along line XI-XI shown in FIG. 6. FIG. 12 is a cross sectional view taken along line XII-XII shown in FIG. 6.

The layout at the first peripheral edge region 14A side is shown in FIG. 6. The layout at the second peripheral edge region 14B side is substantially the same as the layout at the first peripheral edge region 14A side and therefore, the layout at the first peripheral edge region 14A side shall mainly be described below. The layout at the second peripheral edge region 14B side is obtained by replacing the “third connecting surface 10C” in the description below by the “fourth connecting surface 10D.”

With reference to FIG. 5 to FIG. 12, the semiconductor device 1 includes a body region 17 of a p-type (second conductivity type) that is formed in a surface layer portion of the first main surface 3 (active surface 8). The body region 17 is formed at an interval to the active surface 8 side from a bottom portion of the first semiconductor region 6. The body region 17 is formed in a layered shape extending along the active surface 8. The body region 17 may be formed in a whole region of the active surface 8 and be exposed from the first to fourth connecting surfaces 10A to 10D.

The semiconductor device 1 includes a source region 18 of the n-type that is formed in the surface layer portion of the first main surface 3 (active surface 8) in the active region 12. Specifically, the source region 18 is formed in a surface layer portion of the body region 17 at an interval to the active surface 8 side from a bottom portion of the body region 17. The source region 18 is not formed in the peripheral edge region 14 and the terminal region 15.

As a matter of course, the source region 18 may be formed in the peripheral edge region 14 and the terminal region 15 within a range that would not affect control of channels. The source region 18 has a higher n-type impurity concentration than the first semiconductor region 6. The source region 18 forms MISFET channels with the first semiconductor region 6 inside the body region 17.

The semiconductor device 1 includes a plurality of trench gate structures 20 that are formed in the first main surface 3 (active surface 8) in the active region 12. A gate potential VG as a first potential is to be applied to the plurality of trench gate structures 20. The plurality of trench gate structures 20 control inversion and non-inversion of channels inside the body region 17. The plurality of trench gate structures 20 are each formed in a band shape extending in the first direction X and are aligned at intervals in the second direction Y in plan view.

In this embodiment, the plurality of trench gate structures 20 are arranged in the inner portion of the active surface 8 at intervals from the peripheral edge of the active surface 8. Specifically, the plurality of trench gate structures 20 are arranged at intervals in the first direction X and the second direction Y from the first to fourth connecting surfaces 10A to 10D.

The plurality of trench gate structures 20 demarcate the active region 12 in the inner portion of the active surface 8 and, together with the peripheral edge of the active surface 8, demarcate the peripheral edge region 14 and the terminal region 15. The plurality of trench gate structures 20 penetrate through the body region 17 and the source region 18 such as to reach the first semiconductor region 6. The plurality of trench gate structures 20 are formed at an interval to the active surface 8 side from the bottom portion of the first semiconductor region 6.

Hereinafter, the single trench gate structure 20 shall be described. The trench gate structure 20 has a first width W1 in the second direction Y and has a first depth D1 in the normal direction Z. The first width W1 may be not less than 0.1 μm and not more than 3 μm. The first width W1 is preferably not less than 0.5 μm and not more than 2 μm. The first depth D1 is less than the outer depth DO described above. The first depth D1 may be not less than 0.1 μm and not more than 3 μm. The first depth D1 is preferably not less than 0.5 μm and not more than 1.5 μm.

The trench gate structure 20 includes a gate trench 21, a gate insulating film 22, and a gate embedded electrode 23. The gate trench 21 is formed in the active surface 8 and demarcates a wall surface of the trench gate structure 20. The gate insulating film 22 covers a wall surface of the gate trench 21 and is connected to the main surface insulating film 16 on the active surface 8. The gate insulating film 22 may include at least one among a silicon oxide film, a silicon nitride film, and silicon oxynitride film.

In this embodiment, the gate insulating film 22 has a single layer structure consisting of the silicon oxide film. The gate insulating film 22 particularly preferably includes the silicon oxide film that consists of the oxide of the chip 2. The gate embedded electrode 23 is embedded in the gate trench 21 with the gate insulating film 22 interposed therebetween and opposes a channel with the gate insulating film 22 interposed therebetween. The gate embedded electrode 23 may contain a conductive polysilicon.

The semiconductor device 1 includes a plurality of first trench source structures 25 that are formed in the first main surface 3 (active surface 8) in the active region 12. A source potential VS as a second potential differing from the first potential is to be applied to the plurality of first trench source structures 25. The source potential VS may be a reference potential (for example, a ground potential) that serves as an operation reference.

The plurality of first trench source structures 25 are each arranged in a region between two adjacent trench gate structures 20. In plan view, the plurality of first trench source structures 25 are aligned alternately with the plurality of trench gate structures 20 in the second direction Y and are each formed in a band shape extending in the first direction X. In this embodiment, the plurality of first trench source structures 25 are drawn out from the active region 12 to the peripheral edge region 14. The plurality of first trench source structures 25 are exposed from at least one of either of the third connecting surface 10C and the fourth connecting surface 10D.

In this embodiment, the plurality of first trench source structures 25 penetrate through both of the third connecting surface 10C and the fourth connecting surface 10D and are exposed from both of the third connecting surface 10C and the fourth connecting surface 10D. The plurality of first trench source structures 25 oppose the trench gate structures 20 in the second direction Y in the active region 12 but do not oppose the trench gate structures 20 in the second direction Y in the peripheral edge region 14.

The plurality of first trench source structures 25 penetrate through the body region 17 and the source region 18 in the active region 12 and penetrate through the body region 17 in the peripheral edge region 14 such as to reach the first semiconductor region 6. The plurality of first trench source structures 25 are formed at an interval to the active surface 8 side from the bottom portion of the first semiconductor region 6.

Hereinafter, the single first trench source structure 25 shall be described. The first trench source structure 25 has a second width W2 in the second direction Y and has a second depth D2 in the normal direction Z. The second width W2 is preferably substantially equal to the first width W1 described above. The second width W2 may be not less than 0.1 μm and not more than 3 μm. The second width W2 is preferably not less than 0.5 μm and not more than 2 μm.

The second depth D2 is not less than the first depth D1. In this embodiment, the second depth D2 is greater than the first depth D1 described above. The second depth D2 is preferably not less than 1.5 times and not more than 3 times the first depth D1. In this embodiment, the second depth D2 is substantially equal to the outer depth DO described above. The second depth D2 may be not less than 0.1 μm and not more than 5 μm. The second depth D2 is particularly preferably not more than 2.5 μm.

The first trench source structure 25 is arranged at a first interval I1 from the trench gate structure 20 in the second direction Y. The first interval I1 is preferably not less than 0.5 times and not more than 2 times the first width W1 (second width W2). The first interval I1 is particularly preferably less than the first width W1 (second width W2). The first interval I1 may be not less than 0.1 μm and not more than 2.5 μm. The first interval I1 is preferably not less than 0.5 μm and not more than 1.5 μm.

The first trench source structure 25 includes a first source trench 26, a first source insulating film 27, and a first source embedded electrode 28. The first source trench 26 is formed in the active surface 8 and demarcates a wall surface of the first trench source structure 25. A side wall of the first source trench 26 is in communication with the third connecting surface 10C and the fourth connecting surface 10D. A bottom wall of the first source trench 26 is in communication with the outer surface 9.

The first source insulating film 27 covers a wall surface of the first source trench 26 and is connected to the main surface insulating film 16 on the active surface 8. The first source insulating film 27 is connected to the main surface insulating film 16 at a communication portion with the third connecting surface 10C, a communication portion with the fourth connecting surface 10D, and a communication portion with the outer surface 9. The first source insulating film 27 may include at least one among a silicon oxide film, a silicon nitride film, and silicon oxynitride film.

In this embodiment, the first source insulating film 27 has a single layer structure consisting of the silicon oxide film. The first source insulating film 27 particularly preferably includes the silicon oxide film that consists of the oxide of the chip 2. The first source embedded electrode 28 is embedded in the first source trench 26 with the first source insulating film 27 interposed therebetween. The first source embedded electrode 28 may contain a conductive polysilicon.

The semiconductor device 1 includes a plurality of second trench source structures 30 that are formed in the first main surface 3 (active surface 8) in the peripheral edge region 14. The source potential VS is to be applied to the plurality of second trench source structures 30. The plurality of second trench source structures 30 are arranged in a region between the peripheral edge of the active surface 8 (the third connecting surface 10C) and the plurality of trench gate structures 20. The plurality of second trench source structures 30 are each arranged in a region between two first trench source structures 25 that are adjacent in the second direction Y and oppose the plurality of trench gate structures 20 in one-to-one correspondence in the first direction X.

The plurality of second trench source structures 30 are each formed in a band shape extending in the first direction X in plan view. In this embodiment, the plurality of second trench source structures 30 penetrate through the third connecting surface 10C and are exposed from the third connecting surface 10C. The plurality of second trench source structures 30 penetrate through the body region 17 such as to reach the first semiconductor region 6. The plurality of second trench source structures 30 are formed at an interval to the active surface 8 side from the bottom portion of the first semiconductor region 6.

Hereinafter, the single second trench source structure 30 shall be described. The second trench source structure 30 has a third width W3 in the second direction Y and has a third depth D3 in the normal direction Z. The third width W3 is preferably substantially equal to the first width W1 described above. The third width W3 is preferably substantially equal to the second width W2 described above. The third width W3 may be not less than 0.1 μm and not more than 3 μm. The third width W3 is preferably not less than 0.5 μm and not more than 2 μm.

The third depth D3 is not less than the first depth D1 described above. In this embodiment, the third depth D3 is greater than the first depth D1. The third depth D3 is preferably not less than 1.5 times and not more than 3 times the first depth D1. In this embodiment, the third depth D3 is substantially equal to the second depth D2 described above. The third depth D3 is substantially equal to the outer depth DO described above. The third depth D3 may be not less than 0.1 μm and not more than 5 μm. The third depth D3 is particularly preferably not more than 2.5 μm.

The second trench source structure 30 is arranged at a second interval I2 from the first trench source structure 25 in the second direction Y. The second interval I2 is preferably not less than 0.5 times and not more than 2 times the second width W2 (third width W3). The second interval I2 is particularly preferably less than the second width W2 (third width W3). The second interval I2 is preferably substantially equal to the first interval I1 described above. The second interval I2 may be not less than 0.1 μm and not more than 2.5 μm. The second interval I2 is preferably not less than 0.5 μm and not more than 1.5 μm.

The second trench source structure 30 is arranged at a third interval I3 from the trench gate structure 20 in the first direction X. The third interval I3 is preferably not less than 0.5 times and not more than 2 times the first width W1 (third width W3). The third interval I3 is preferably not less than 0.5 times and not more than 2 times the first interval I1 (second interval I2). The third interval I3 is particularly preferably not more than 1.5 times the first interval I1 (second interval I2). The third interval I3 may be substantially equal to the first interval I1 (second interval I2). The third interval I3 may be not less than 0.1 μm and not more than 2.5 μm. The third interval I3 is preferably not less than 0.5 μm and not more than 1.5 μm.

The second trench source structure 30 includes a second source trench 31, a second source insulating film 32, and a second source embedded electrode 33. The second source trench 31 is formed in the active surface 8 and demarcates a wall surface of the second trench source structure 30. A side wall of the second source trench 31 is in communication with the third connecting surface 10C. A bottom wall of the second source trench 31 is in communication with the outer surface 9.

The second source insulating film 32 covers a wall surface of the second source trench 31 and is connected to the main surface insulating film 16 on the active surface 8. The second source insulating film 32 is connected to the main surface insulating film 16 at a communication portion with the third connecting surface 10C and a communication portion with the outer surface 9. The second source insulating film 32 may include at least one among a silicon oxide film, a silicon nitride film, and silicon oxynitride film.

In this embodiment, the second source insulating film 32 has a single layer structure consisting of the silicon oxide film. The second source insulating film 32 particularly preferably includes the silicon oxide film that consists of the oxide of the chip 2. The second source embedded electrode 33 is embedded in the second source trench 31 with the second source insulating film 32 interposed therebetween. The second source embedded electrode 33 may contain a conductive polysilicon.

The semiconductor device 1 includes a plurality of first well regions 35 of the p-type that are formed in regions in the active region 12 along the plurality of trench gate structures 20. In this embodiment, the first well regions 35 have a higher p-type impurity concentration than the body region 17. As a matter of course, the p-type impurity concentration of the first well regions 35 may instead be lower than that of the body region 17.

The plurality of first well regions 35 each cover the wall surface of the corresponding trench gate structure 20 at intervals from the first trench source structures 25 adjacent thereto and are electrically connected to the body region 17 in the surface layer portion of the active surface 8. The plurality of first well regions 35 are formed at an interval to the active surface 8 side from the bottom portion of the first semiconductor region 6 and oppose the second semiconductor region 7 with portions of the first semiconductor region 6 interposed therebetween. The plurality of first well regions 35 form pn junction portions with the first semiconductor region 6.

The semiconductor device 1 includes a plurality of second well regions 36 of the p-type that are formed in regions in the active region 12 and the peripheral edge region 14 along the plurality of first trench source structures 25. In this embodiment, the second well regions 36 have a higher p-type impurity concentration than the body region 17. As a matter of course, the p-type impurity concentration of the second well regions 36 may instead be lower than that of the body region 17. The p-type impurity concentration of the second well regions 36 is preferably substantially equal to the p-type impurity concentration of the first well regions 35.

The plurality of second well regions 36 each cover the wall surface of the corresponding first trench source structure 25 at intervals from the trench gate structures 20 adjacent thereto and are electrically connected to the body region 17 in the surface layer portion of the active surface 8. The plurality of second well regions 36 cover the wall surfaces of the corresponding first trench source structures 25 in the active region 12 and the peripheral edge region 14 and are exposed from the third connecting surface 10C and the fourth connecting surface 10D.

The plurality of second well regions 36 are formed at an interval to the active surface 8 side from the bottom portion of the first semiconductor region 6 and oppose the second semiconductor region 7 with portions of the first semiconductor region 6 interposed therebetween. Bottom portions of the plurality of second well regions 36 are positioned at the bottom portion side of the first semiconductor region 6 with respect to a depth position of bottom portions of the plurality of first well regions 35. The plurality of second well regions 36 form pn junction portions with the first semiconductor region 6.

The semiconductor device 1 includes a plurality of third well regions 37 of the p-type that are formed in regions in the peripheral edge region 14 along the plurality of second trench source structures 30. In this embodiment, the third well regions 37 have a higher p-type impurity concentration than the body region 17. As a matter of course, the p-type impurity concentration of the third well regions 37 may instead be lower than that of the body region 17. The p-type impurity concentration of the third well regions 37 is preferably substantially equal to the p-type impurity concentration of the first well regions 35 (second well regions 36).

The plurality of third well regions 37 each cover the wall surface of the corresponding second trench source structure 30 at intervals from the trench gate structure 20 and first trench source structures 25 adjacent thereto and are electrically connected to the body region 17 in the surface layer portion of the active surface 8. As a matter of course, the third well regions 37 may be made integral with the first well regions 35 in regions between the trench gate structures 20 and the second trench source structures 30. The plurality of third well regions 37 are exposed from the third connecting surface 10C.

The plurality of third well regions 37 are formed at an interval to the active surface 8 side from the bottom portion of the first semiconductor region 6 and oppose the second semiconductor region 7 with portions of the first semiconductor region 6 interposed therebetween. Bottom portions of the plurality of third well regions 37 are positioned at the bottom portion side of the first semiconductor region 6 with respect to the depth position of bottom portions of the plurality of first well regions 35. The bottom portions of the plurality of third well regions 37 are formed at a substantially equal depth to the bottom portions of the plurality of second well regions 36. The plurality of third well regions 37 form pn junction portions with the first semiconductor region 6.

The semiconductor device 1 includes a plurality of first contact regions 38 of the p-type that are formed in regions in the active region 12 along the plurality of first trench source structures 25. The first contact regions 38 have a higher p-type impurity concentration than the body region 17. In this embodiment, the p-type impurity concentration of the first contact regions 38 is higher than that of the second well regions 36.

The plurality of first contact regions 38 each cover the walls surface of the corresponding first trench source structure 25 inside the corresponding second well region 36. The plurality of first contact regions 38 are formed in multiple-to-one correspondence with respect to each first trench source structure 25. The plurality of first contact regions 38 are formed at intervals along the corresponding first trench source structure 25.

The plurality of first contact regions 38 are each drawn out onto the surface layer portion of the body region 17 from inside the corresponding second well region 36 and along the wall surface of the corresponding first trench source structure 25 and are exposed from the active surface 8. The plurality of first contact regions 38 are formed in the active region 12 but are not formed in the peripheral edge region 14. That is, the plurality of first contact regions 38 oppose the trench gate structures 20 in the second direction Y but do not oppose the second trench source structures 30 in the second direction Y. The first contact regions 38 are not formed inside the third well regions 37.

In this embodiment, the plurality of first contact regions 38 are each formed in a band shape extending in the first direction X in plan view. A length in the first direction X of the plurality of first contact regions 38 is preferably not less than the second width W2 described above. The length of the plurality of first contact regions 38 is preferably greater than a distance between two first contact regions 38 that are adjacent in the first direction X.

The plurality of first contact regions 38 arranged along one first trench source structure 25 oppose, in the second direction Y, the plurality of first contact regions 38 arranged along another first trench source structure 25. That is, in this embodiment, the plurality of first contact regions 38 are arrayed, as a whole, in a matrix at intervals in the first direction X and the second direction Y in plan view.

The plurality of first contact regions 38 arranged along the one first trench source structure 25 may be aligned shifted in the first direction X such as to oppose, in the second direction Y, regions between the plurality of first contact regions 38 arranged along the other first trench source structure 25. That is, the plurality of first contact regions 38 may be arrayed, as a whole, in a staggered arrangement at intervals in the first direction X and the second direction Y in plan view.

The semiconductor device 1 includes a plurality of gate connection electrode films 39 that, on the first main surface 3 (active surface 8) in the active region 12, respectively cover end portions of the plurality of trench gate structures 20. Specifically, the plurality of gate connection electrode films 39 are arranged on the main surface insulating film 16. The plurality of gate connection electrode films 39 each cover the end portion of the corresponding trench gate structure 20 at intervals from inner portions of the plurality of trench gate structures 20, from the plurality of first trench source structures 25, and from the plurality of second trench source structures 30.

The plurality of gate connection electrode films 39 are aligned alternately to the plurality of first trench source structures 25 in the second direction Y in plan view. In this embodiment, the plurality of gate connection electrode films 39 are each formed in a band shape extending in the first direction X. The plurality of gate connection electrode films 39 do not oppose the plurality of second trench source structures 30 in the second direction Y. Hereinafter, the single gate connection electrode film 39 shall be described.

The gate connection electrode film 39 is connected to the corresponding gate embedded electrode 23 at a portion covering the corresponding trench gate structure 20. In this embodiment, the gate connection electrode film 39 is formed integral to the corresponding gate embedded electrode 23. That is, the gate connection electrode film 39 consists of a portion at which a portion of the gate embedded electrode 23 is drawn out in a film shape onto the active surface 8 (main surface insulating film 16). As a matter of course, the gate connection electrode film 39 may instead be formed as a separate member from the gate embedded electrode 23.

The gate connection electrode film 39 has an electrode surface 39a that extends along the active surface 8. In this embodiment, the gate connection electrode film 39 is formed in a shape (a quadrangular pyramid shape) tapering toward the electrode surface 39a from the active surface 8 in cross-sectional view. The electrode surface 39a is preferably formed to be wider in the second direction Y than the trench gate structure 20. That is, the electrode surface 39a preferably has a portion opposing the trench gate structure 20 in the normal direction Z and a portion opposing a region (that is, the main surface insulating film 16) outside the trench gate structure 20 in the normal direction Z.

In this embodiment, the gate connection electrode film 39 contains a conductive polysilicon. The gate connection electrode film 39 has an electrode thickness TE. The electrode thickness TE is preferably not less than 0.5 times the first width W1 (second width W2) described above. The electrode thickness TE is preferably not more than the outer depth DO described above. The electrode thickness TE is preferably not more than the second depth D2 described above. The electrode thickness TE is particularly preferably less than the second depth D2 (outer depth DO).

The electrode thickness TE is preferably not more than the first depth D1 described above. The electrode thickness TE is particularly preferably less than the first depth D1. The electrode thickness TE may be not less than 0.05 μm and not more than 2.5 μm. The electrode thickness TE is preferably not less than 0.5 μm and not more than 1.5 μm. As a matter of course, the electrode thickness TE may be greater than the first depth D1. Also, the electrode thickness TE may be not less than the outer depth DO (second depth D2).

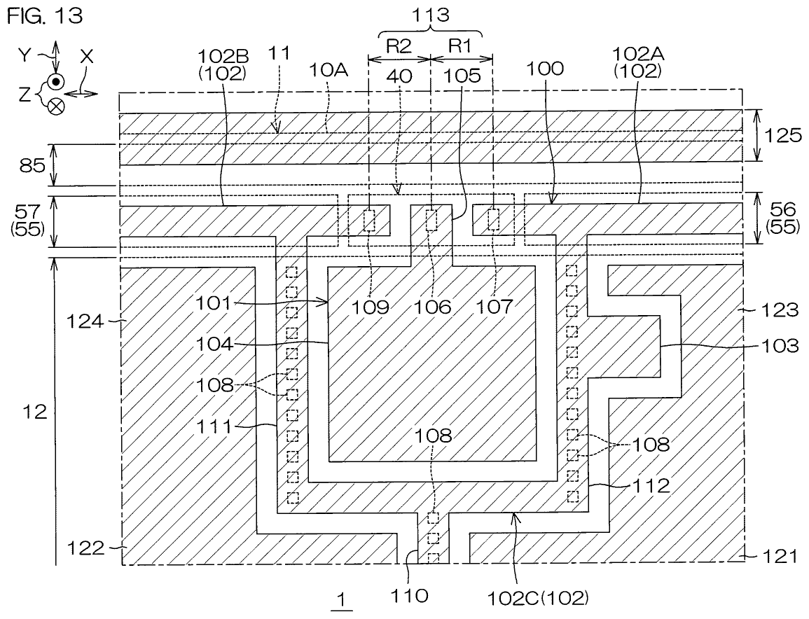

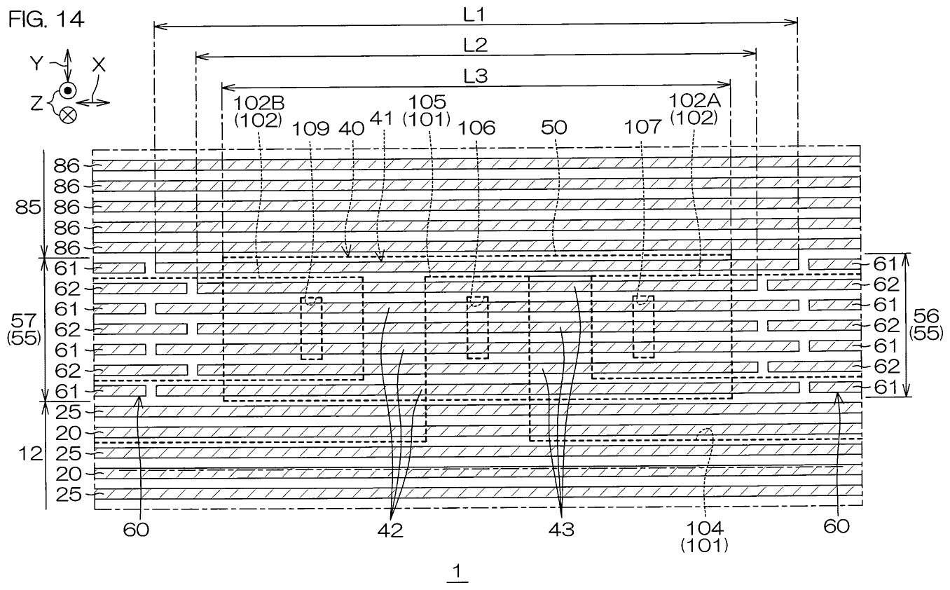

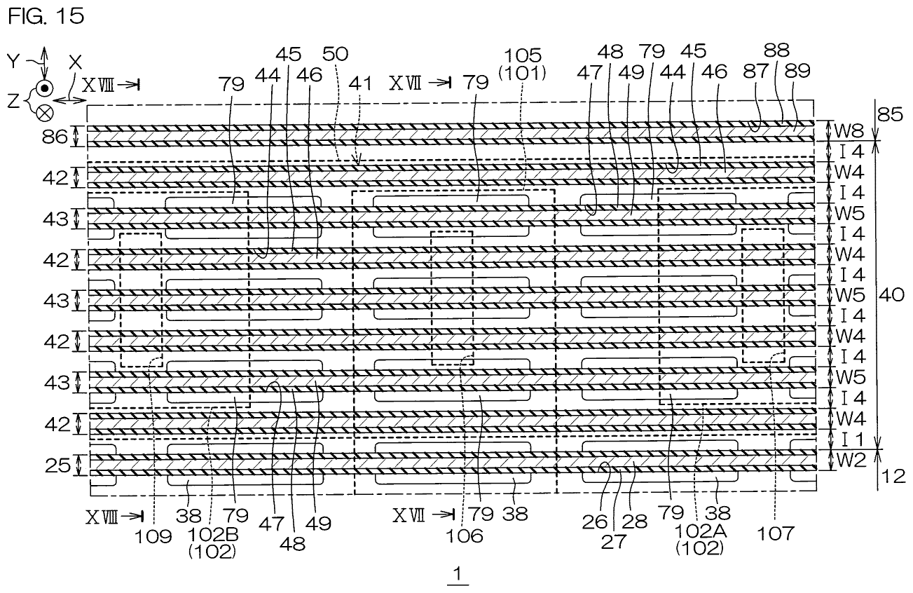

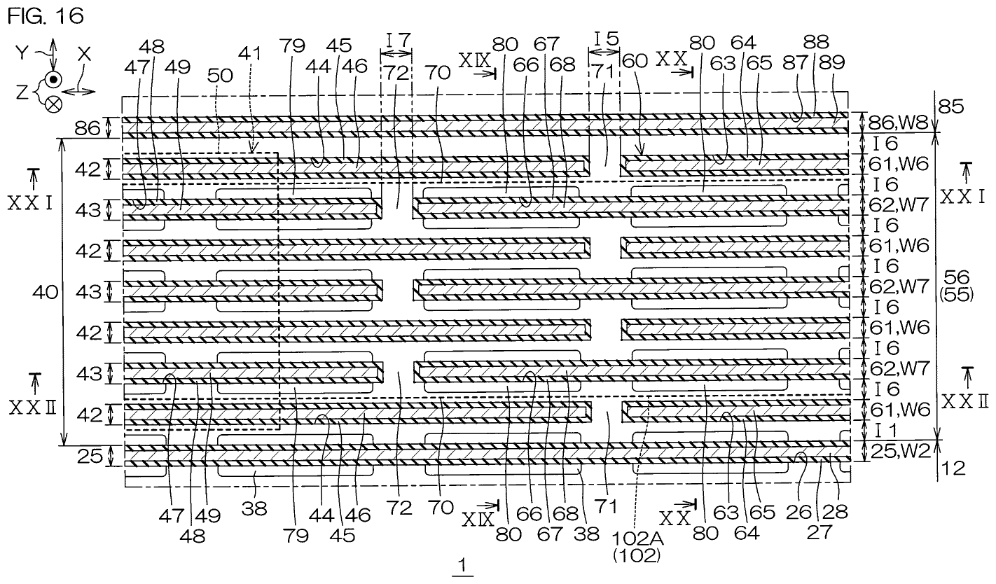

FIG. 13 is an enlarged plan view showing a layout of the terminal region 15 (first terminal region 15A). FIG. 14 is an enlarged plan view showing a layout of a gate resistor 40. FIG. 15 is an enlarged plan view showing an inner portion of the gate resistor 40. FIG. 16 is an enlarged plan view showing a peripheral edge portion of the gate resistor 40.

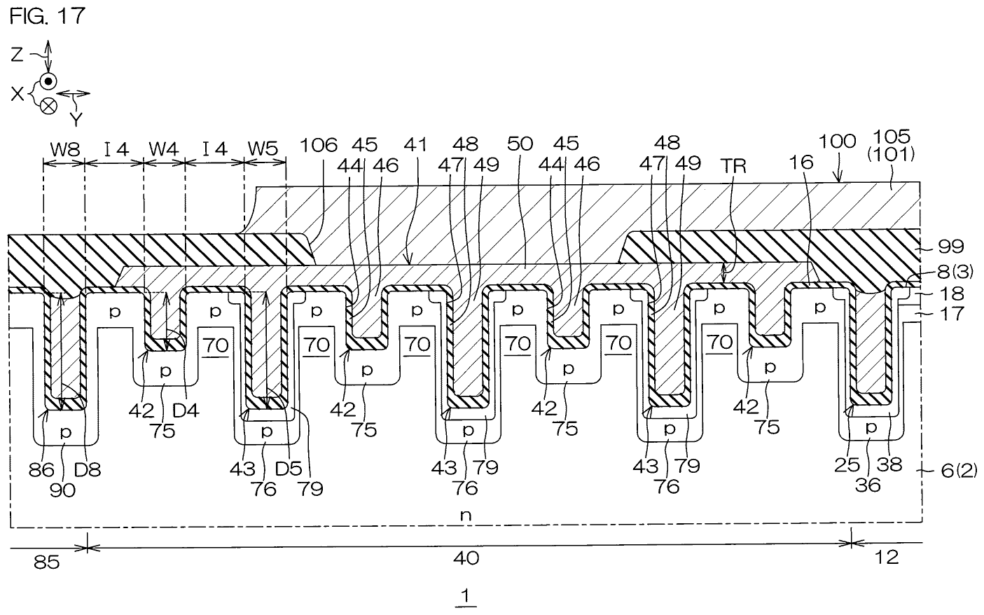

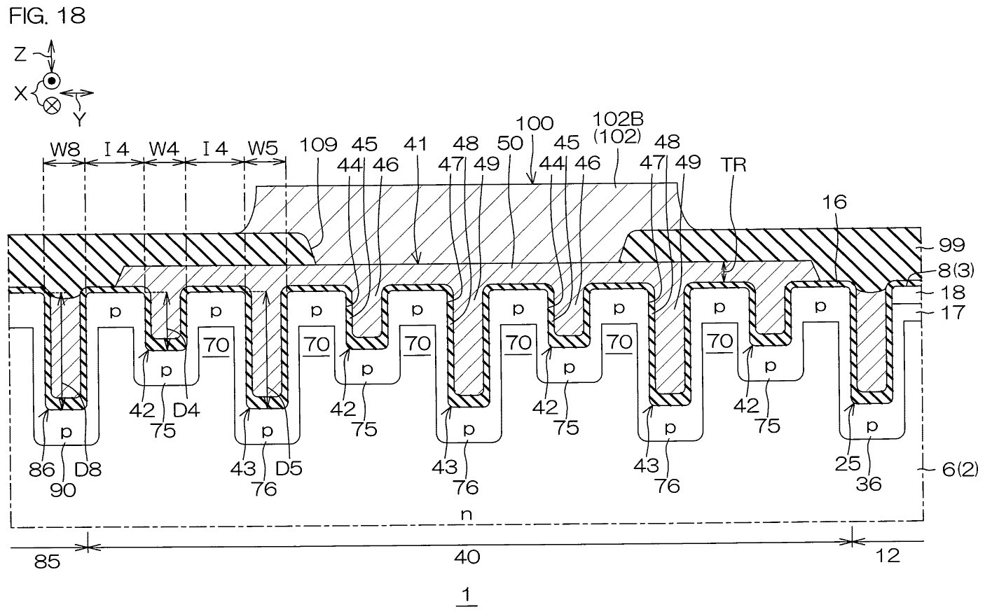

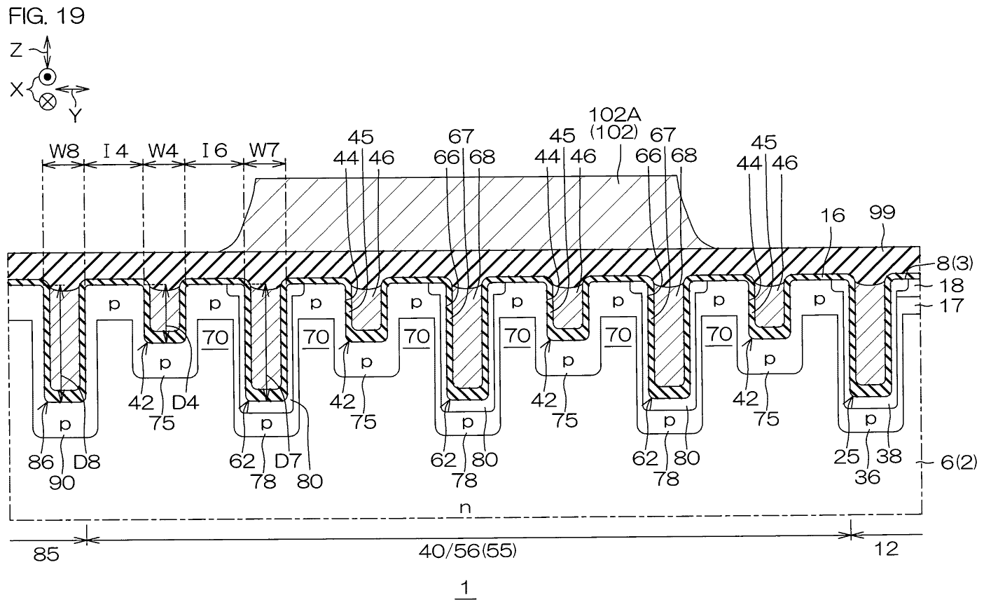

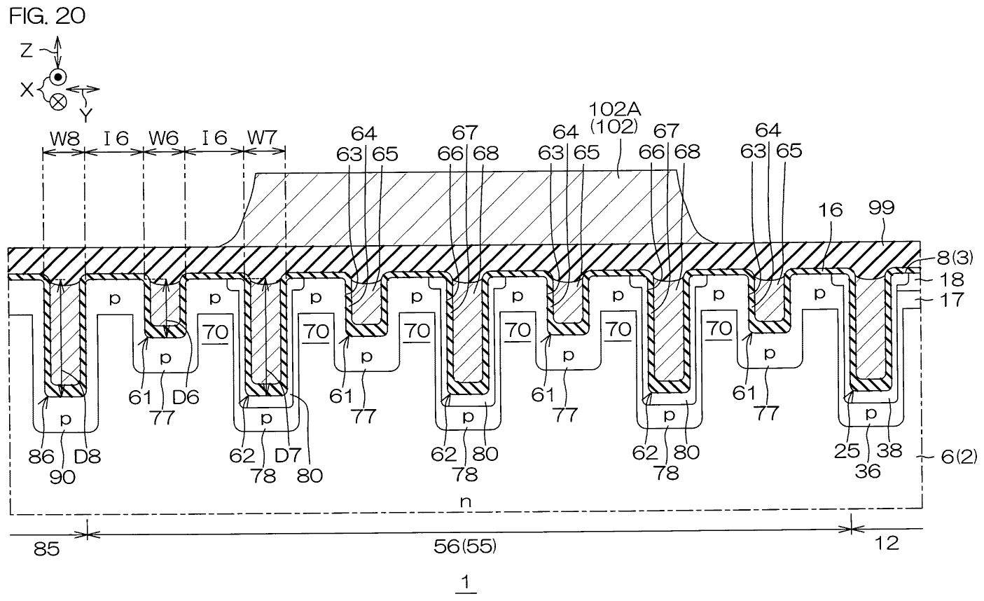

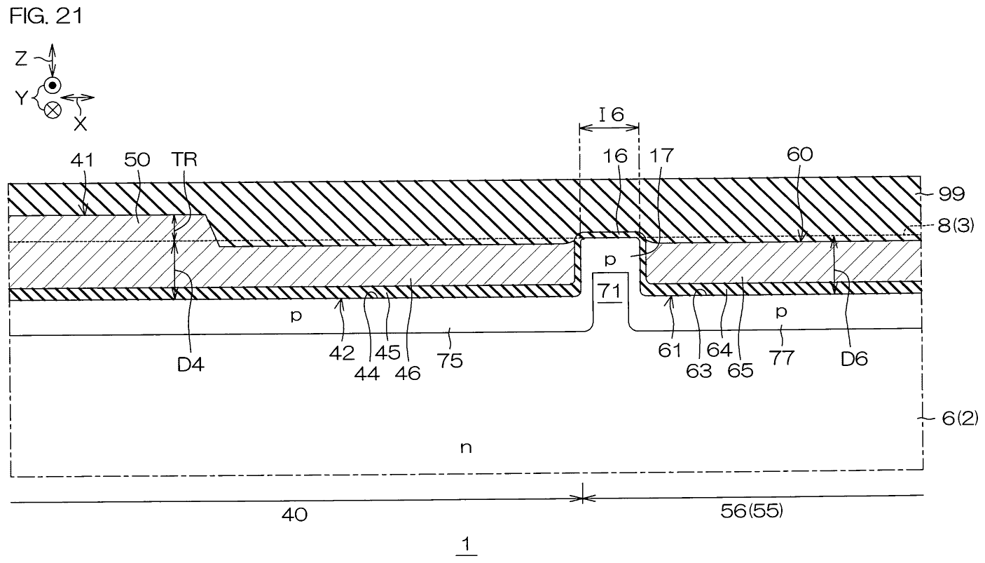

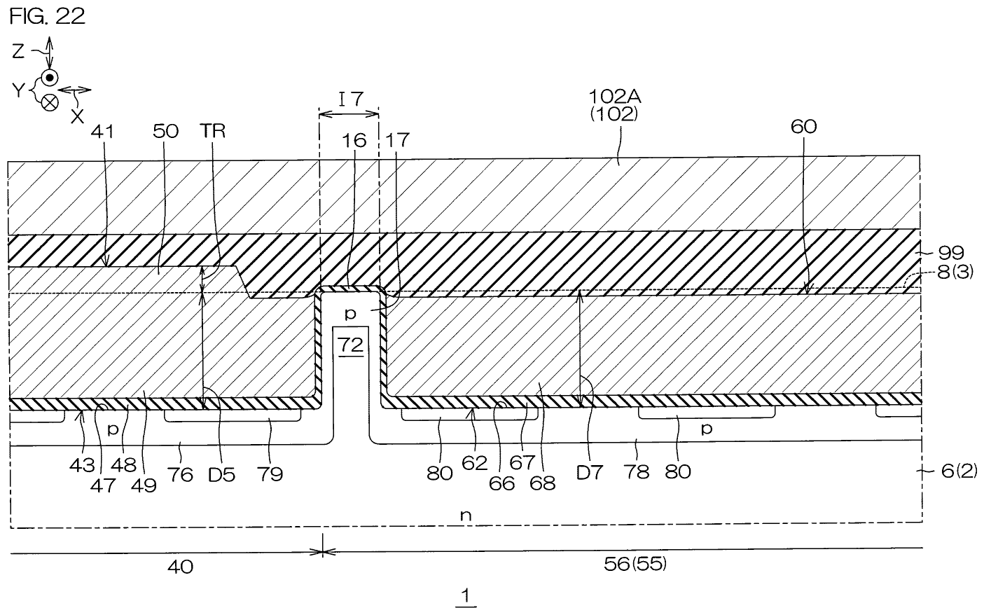

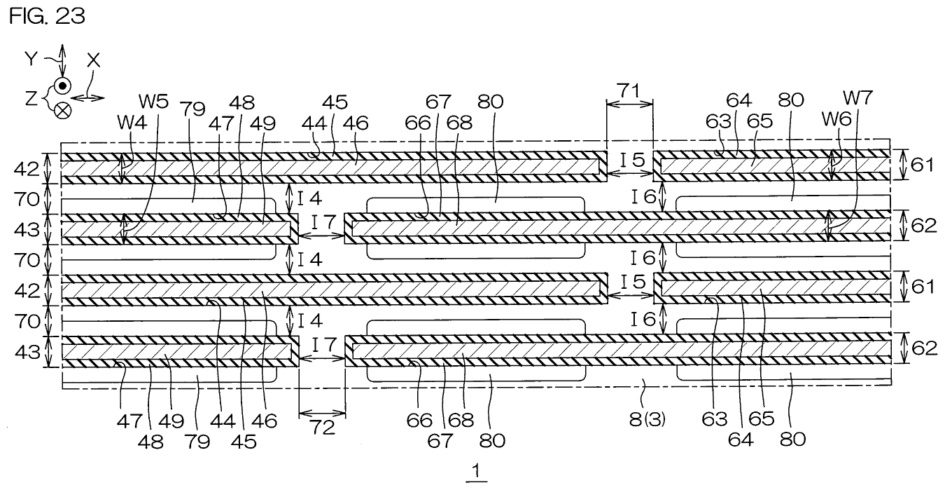

FIG. 17 is a cross sectional view taken along line XVII-XVII shown in FIG. 15. FIG. 18 is a cross sectional view taken along line XVIII-XVIII shown in FIG. 15. FIG. 19 is a cross sectional view taken along line XIX-XIX shown in FIG. 16. FIG. 20 is a cross sectional view taken along line XX-XX shown in FIG. 16. FIG. 21 is a cross sectional view taken along line XXI-XXI shown in FIG. 16. FIG. 22 is a cross sectional view taken along line XXII-XXII shown in FIG. 16. FIG. 23 is an enlarged plan view showing a principal part of the gate resistor 40.

With reference to FIG. 13 to FIG. 23, the semiconductor device 1 includes the gate resistor 40 that is formed in the first main surface 3 (active surface 8) in the first terminal region 15A. The gate resistor 40 is incorporated in the chip 2 (first terminal region 15A) as a resistor that is electrically connected to a gate (the trench gate structures 20) of the MISFET.

The gate resistor 40 is arranged in a region at the first side surface 5A side (first connecting surface 10A side) with respect to the active region 12 and opposes the active region 12 in the second direction Y. The gate resistor 40 is arranged at intervals in the first direction X from the peripheral edge region 14 such as not to oppose the peripheral edge region 14 in the second direction Y. In this embodiment, the gate resistor 40 is arranged between a central portion of the first side surface 5A (first connecting surface 10A) and the active region 12.

The gate resistor 40 includes at least one (in this embodiment, a plurality of a) trench resistor structure 41 formed in the first main surface 3 (active surface 8) in the first terminal region 15A. Although the gate potential VG as the first potential is to be applied to the plurality of trench resistor structures 41, the plurality of trench resistor structures 41 do not contribute to the control of the channels.

The plurality of trench resistor structures 41 are each formed in a band shape extending in the first direction X and are aligned at intervals in the second direction Y. The plurality of trench resistor structures 41 penetrate through the body region 17 such as to reach the first semiconductor region 6. The plurality of trench resistor structures 41 are formed at an interval to the active surface 8 side from the bottom portion of the first semiconductor region 6.

In this embodiment, the plurality of trench resistor structures 41 include a plurality of first trench resistor structures 42 and a plurality of second trench resistor structures 43. The plurality of first trench resistor structures 42 are formed in the active surface 8 in the first terminal region 15A at intervals from the peripheral edge of the active surface 8. The plurality of first trench resistor structures 42 are each formed in a band shape extending in the first direction X and are aligned at intervals in the second direction Y.

The plurality of first trench resistor structures 42 oppose the first trench source structures 25 in the second direction Y. The plurality of first trench resistor structures 42 are arranged at intervals in the first direction X from the second trench source structures 30 such as not to oppose the second trench source structures 30 in the second direction Y. The plurality of first trench resistor structures 42 penetrate through the body region 17 such as to reach the first semiconductor region 6. The plurality of first trench resistor structures 42 are formed at an interval to the active surface 8 side from the bottom portion of the first semiconductor region 6.

Hereinafter, the single first trench resistor structure 42 shall be described. The first trench resistor structure 42 has a first resistor length L1 in the first direction X. The first resistor length L1 is arbitrary and is adjusted as appropriate in accordance with a resistance value to be attained. The first trench resistor structure 42 has a fourth width W4 in the second direction Y and has a fourth depth D4 in the normal direction Z. The fourth width W4 is preferably substantially equal to the first width W₁ described above. The fourth width W4 may be not less than 0.1 μm and not more than 3 μm. The fourth width W4 is preferably not less than 0.5 μm and not more than 2 μm.

The fourth depth D4 is less than the second depth D2 described above. The fourth depth D4 is less than the outer depth DO described above. The fourth depth D4 is preferably substantially equal to the first depth D1 described above. The fourth depth D4 may be not less than 0.1 μm and not more than 3 μm. The fourth depth D4 is preferably not less than 0.5 μm and not more than 1.5 μm.

In this embodiment, the outermost first trench resistor structure 42 at the active region 12 side is arranged at the first interval I1 described above from the outermost first trench source structure 25 such as to be adjacent to the outermost first trench source structure 25 in the second direction Y. In this embodiment, the outermost first trench resistor structure 42 is formed at an interval in the first direction X from the outermost second trench source structures 30 such as not to oppose the outermost second trench source structures 30 in the second direction Y.

The first trench resistor structure 42 includes a first trench 44, a first insulating film 45, and a first embedded electrode 46. The first embedded electrode 46 may also be referred to as a “first embedded resistor.” The first trench 44 is formed in the active surface 8 and demarcates a wall surface of the first trench resistor structure 42. The first insulating film 45 covers a wall surface of the first trench 44 and is connected to the main surface insulating film 16 on the active surface 8. The first insulating film 45 may include at least one among a silicon oxide film, a silicon nitride film, and silicon oxynitride film.

In this embodiment, the first insulating film 45 has a single layer structure consisting of the silicon oxide film. The first insulating film 45 particularly preferably includes the silicon oxide film that consists of the oxide of the chip 2. The first embedded electrode 46 is embedded in the first trench 44 with the first insulating film 45 interposed therebetween. The first embedded electrode 46 may contain a conductive polysilicon.

The plurality of second trench resistor structures 43 are formed in the active surface 8 in the first terminal region 15A at intervals from the peripheral edge of the active surface 8. The plurality of second trench resistor structures 43 are each arranged in a region between two adjacent first trench resistor structures 42. The plurality of second trench resistor structures 43 are aligned alternately with the plurality of first trench resistor structures 42 in the second direction Y. The plurality of second trench resistor structures 43 are each formed in a band shape extending in the first direction X in plan view.

The plurality of second trench resistor structures 43 oppose the trench gate structures 20 and the first trench source structures 25 in the second direction Y. The plurality of second trench resistor structures 43 are arranged at intervals in the first direction X from the second trench source structures 30 such as not to oppose the second trench source structures 30 in the second direction Y. The plurality of second trench resistor structures 43 penetrate through the body region 17 such as to reach the first semiconductor region 6. The plurality of second trench resistor structures 43 are formed at an interval to the active surface 8 side from the bottom portion of the first semiconductor region 6.

Hereinafter, the single second trench resistor structure 43 shall be described. The second trench resistor structure 43 has a second resistor length L2 in the first direction X. The second resistor length L2 is arbitrary and is adjusted as appropriate in accordance with the resistance value to be attained. In this embodiment, the second resistor length L2 is less than the first resistor length L1 described above. That is, both end portions of the second trench resistor structure 43 are set back further inward than both end portions of the first trench resistor structure 42. As a matter of course, the second resistor length L2 may be substantially equal to the first resistor length L1. Also, the second resistor length L2 may be greater than the first resistor length L1.

The second trench resistor structure 43 has a fifth width W5 in the second direction Y and has a fifth depth D5 in the normal direction Z. The fifth width W5 is preferably substantially equal to the fourth width W4 described above. The fifth width W5 is preferably substantially equal to the second width W2 (first width W1) described above. The fifth width W5 may be not less than 0.1 μm and not more than 3 μm. The fifth width W5 is preferably not less than 0.5 μm and not more than 2 μm.

The fifth depth D5 is not less than the fourth depth D4 (first depth D1) described above. In this embodiment, the fifth depth D5 is greater than the fourth depth D4 (first depth D1). The fifth depth D5 is preferably not less than 1.5 times and not more than 3 times the fourth depth D4 (first depth D1). The fifth depth D5 is preferably substantially equal to the second depth D2 described above. The fifth depth D5 is substantially equal to the outer depth DO described above. The fifth depth D5 may be not less than 0.1 μm and not more than 5 μm. The fifth depth D5 is particularly preferably not more than 2.5 μm.

The second trench resistor structure 43 is arranged at a fourth interval I4 from the first trench resistor structure 42 in the second direction Y. The fourth interval I4 is preferably not less than 0.5 times and not more than 2 times the fourth width W4 (fifth width W5). The fourth interval I4 is particularly preferably less than the fourth width W4 (fifth width W5). The fourth interval I4 is preferably substantially equal to the first interval I1 described above. The fourth interval I4 may be not less than 0.1 μm and not more than 2.5 μm. The fourth interval I4 is preferably not less than 0.5 μm and not more than 1.5 μm.

The second trench resistor structure 43 includes a second trench 47, a second insulating film 48, and a second embedded electrode 49. The second embedded electrode 49 may also be referred to as a “first embedded resistor.” The second trench 47 is formed in the active surface 8 and demarcates a wall surface of the second trench resistor structure 43. The second insulating film 48 covers a wall surface of the second trench 47 and is connected to the main surface insulating film 16 on the active surface 8. The second insulating film 48 may include at least one among a silicon oxide film, a silicon nitride film, and silicon oxynitride film.

In this embodiment, the second insulating film 48 has a single layer structure consisting of the silicon oxide film. The second insulating film 48 particularly preferably includes the silicon oxide film that consists of the oxide of the chip 2. The second embedded electrode 49 is embedded in the second trench 47 with the second insulating film 48 interposed therebetween. The second embedded electrode 49 may contain a conductive polysilicon.

The gate resistor 40 includes a resistive film 50 that covers at least one (in this embodiment, the plurality) of the trench resistor structures 41 on the first main surface 3 (active surface 8). The resistive film 50 includes at least one among a conductive polysilicon film and an alloy crystal film. The alloy crystal film contains an alloy crystal consisting of a metal element and a nonmetal element. The alloy crystal film may include at least one among a CrSi film, a CrSiN film, a CrSiO film, a TaN film, and a TiN film. In this embodiment, the resistive film 50 contains a conductive polysilicon.

The resistive film 50 is arranged on the main surface insulating film 16 and has a portion covering the active surface 8 and a portion covering the plurality of trench resistor structures 41. In this embodiment, the resistive film 50 covers all trench resistor structures 41 in regard to a short direction (the second direction Y) of the plurality of trench resistor structures 41. The resistive film 50 is connected to the first embedded electrodes 46 and the second embedded electrodes 49 in the portion covering the plurality of trench resistor structures 41.

In this embodiment, the resistive film 50 is formed integral to the first embedded electrodes 46 and the second embedded electrodes 49. That is, the resistive film 50 consists of portions of the first embedded electrodes 46 and portions of the second embedded electrodes 49 that are drawn out as films onto the active surface 8 (main surface insulating film 16). As a matter of course, the resistive film 50 may be formed as a separate member from the first embedded electrodes 46 and the second embedded electrodes 49.

The resistive film 50 opposes the trench gate structures 20 and the first trench source structures 25 in the second direction Y. The resistive film 50 is arranged at intervals in the first direction X from the second trench source structures 30 such as not to oppose the second trench source structures 30 in the second direction Y. In this embodiment, the resistive film 50 is formed in a band shape extending in the first direction X in plan view. A planar shape of the resistive film 50 is arbitrary and is adjusted as appropriate in accordance with the resistance value to be attained.

The resistive film 50 preferably has a third resistor length L3 in the first direction X that is shorter than the first resistor length L1 of the first trench resistor structures 42 and the second resistor length L2 of the second trench resistor structures 43. In this case, the resistive film 50 preferably covers inner portions of the plurality of trench resistor structures 41 at intervals inward from both end portions of the plurality of trench resistor structures 41 in regard to a long direction (the first direction X) of the plurality of trench resistor structures 41. That is, the resistive film 50 preferably exposes both end portions of the plurality of first trench resistor structures 42 and both end portions of the plurality of second trench resistor structures 43.

By setting back the resistive film 50 inwardly with respect to both end portions of the plurality of trench resistor structures 41, the resistive film 50 can be suppressed from opposing the first main surface 3 in a region further to the peripheral edge side of the active surface 8 than both ends of the plurality of trench resistor structures 41. Forming of an undesirable potential difference (electric field) between the first main surface 3 and the resistive film 50 in a region outside both end portions of the plurality of trench resistor structures 41 is thus suppressed.

As a matter of course, the resistive film 50 may cover a whole region of the plurality of trench resistor structures 41. That is, the third resistor length L3 may be greater than the first resistor length L1. Also, the resistive film 50 may expose both end portions of the plurality of first trench resistor structures 42 and cover both end portions of the plurality of second trench resistor structures 43. That is, the third resistor length L3 may be smaller than the first resistor length L1 but greater than the second resistor length L2.

The resistive film 50 has a resistor thickness TR in the normal direction Z. The resistor thickness TR is adjusted as appropriate in accordance with the resistance value to be attained. That is, a resistance value of the resistive film 50 is adjusted by increase/decrease in the resistor thickness TR and increase/decrease in the third resistor length L3. The resistor thickness TR is preferably not less than 0.5 times the fourth width W4 (fifth width W5) described above.

By the resistor thickness TR satisfying this condition, it is made possible, in a case where a conductive polysilicon film that fills the first trenches 44 and the second trenches 47 and covers the first main surface 3 (active surface 8) is formed by a CVD method, to form the first embedded electrodes 46, the second embedded electrodes 49, and the resistive film 50 using a portion of the conductive polysilicon film. The resistor thickness TR is preferably not more than the outer depth DO described above. The resistor thickness TR is preferably not more than the fifth depth D5 (second depth D2) described above.

The resistor thickness TR is particularly preferably less than the fifth depth D5. The resistor thickness TR is preferably not more than the fourth depth D4 (first depth D1) described above. The resistor thickness TR is particularly preferably less than the fourth depth D4. The resistor thickness TR may be less than the electrode thickness TE described above. The resistor thickness TR may be greater than the electrode thickness TE. The resistor thickness TR may be substantially equal to the electrode thickness TE. The resistor thickness TR may be not less than 0.05 μm and not more than 2.5 μm. The resistor thickness TR is preferably not less than 0.5 μm and not more than 1.5 μm.

As a matter of course, the resistor thickness TR may be greater than the fourth depth D4. Also, the resistor thickness TR may be not less than the outer depth DO (fifth depth D5). Also, if the resistive film 50 consists of the alloy crystal film, the resistor thickness TR may be less than the fourth depth D4. In this case, the resistor thickness TR may be not less than 0.1 nm and not more than 100 nm.

With reference to FIG. 13 to FIG. 23, the semiconductor device 1 includes a dummy structure 55 that is formed in the first main surface 3 (active surface 8) in the first terminal region 15A. The dummy structure 55 is incorporated in the active surface 8 (first terminal region 15A) with one purpose being to relax a localized electric field concentration in a vicinity of the gate resistor 40 and improve a withstand voltage (for example, a breakdown voltage). Whether or not the dummy structure 55 is provided is arbitrary and a configuration not including the dummy structure 55 may be adopted instead.

The dummy structure 55 includes a first dummy structure 56 and a second dummy structure 57. The first dummy structure 56 is arranged in a region at the third side surface 5C side (third connecting surface 10C side) with respect to the gate resistor 40. The first dummy structure 56 opposes the gate resistor 40 in the first direction X and opposes the active region 12 and the first peripheral edge region 14A in the second direction Y. The second dummy structure 57 is arranged in a region at the fourth side surface 5D side (fourth connecting surface 10D side) with respect to the gate resistor 40.

The second dummy structure 57 opposes the first dummy structure 56 in the first direction X with the gate resistor 40 interposed therebetween and opposes the active region 12 and the second peripheral edge region 14B in the second direction Y. A layout of the second dummy structure 57 and a layout of the first dummy structure 56 are substantially the same and therefore, the arrangement of the first dummy structure 56 shall be described below. The layout of the second dummy structure 57 is obtained by replacing the “third connecting surface 10C” in the description below by the “fourth connecting surface 10D.”

The first dummy structure 56 includes at least one (in this embodiment, a plurality of a) dummy trench structure 60 that is formed in the first main surface 3 (active surface 8) in the first terminal region 15A. The source potential VS as the second potential is to be applied to the plurality of dummy trench structures 60. The plurality of dummy trench structures 60 are each formed in a band shape extending in the first direction X and are aligned at intervals in the second direction Y.

The plurality of dummy trench structures 60 oppose the plurality of trench resistor structures 41 in one-to-one correspondence in the first direction X. The plurality of dummy trench structures 60 oppose the first trench source structures 25 and the second trench source structures 30 in the second direction Y. The plurality of dummy trench structures 60 penetrate through the body region 17 such as to reach the first semiconductor region 6. In this embodiment, the plurality of dummy trench structures 60 penetrate through the third connecting surface 10C and are exposed from the third connecting surface 10C. The plurality of trench gate structures 20 are formed at an interval to the active surface 8 side from the bottom portion of the first semiconductor region 6.

In this embodiment, the plurality of dummy trench structures 60 include a plurality of first dummy trench structures 61 and a plurality of second dummy trench structures 62. The plurality of first dummy trench structures 61 are arranged in regions between the peripheral edge of the active surface 8 and the plurality of first trench resistor structures 42. The plurality of first dummy trench structures 61 are each formed in a band shape extending in the first direction X and are aligned at intervals in the second direction Y.

The plurality of first dummy trench structures 61 oppose the plurality of first trench resistor structures 42 in one-to-one correspondence in the first direction X. That is, the first trench resistor structures 42 to which the gate potential VG is to be applied and the first dummy trench structures 61 to which the source potential VS is to be applied are opposed in the first direction X. The plurality of first dummy trench structures 61 oppose the first trench source structures 25 and the second trench source structures 30 in the second direction Y.

In this embodiment, the plurality of first dummy trench structures 61 penetrate through the third connecting surface 10C and are exposed from the third connecting surface 10C. The plurality of first dummy trench structures 61 penetrate through the body region 17 such as to reach the first semiconductor region 6. The plurality of first dummy trench structures 61 are formed at an interval to the active surface 8 side from the bottom portion of the first semiconductor region 6.

Hereinafter, the single first dummy trench structure 61 shall be described. The first dummy trench structure 61 has a sixth width W6 in the second direction Y and has a sixth depth D6 in the normal direction Z. The sixth width W6 is preferably substantially equal to the fourth width W4 described above. The sixth width W6 is preferably substantially equal to the first width W1 described above. The sixth width W6 may be not less than 0.1 μm and not more than 3 μm. The sixth width W6 is preferably not less than 0.5 μm and not more than 2 μm.

The sixth depth D6 is less than the fifth depth D5 (second depth D2) described above. The sixth depth D6 is less than the outer depth DO described above. The sixth depth D6 is preferably substantially equal to the fourth depth D4 (first depth D1) described above. The sixth depth D6 may be not less than 0.1 μm and not more than 3 μm. The sixth depth D6 is preferably not less than 0.5 μm and not more than 1.5 μm.

The first dummy trench structure 61 is arranged at a fifth interval I5 from the first trench resistor structure 42 in the first direction X. The fifth interval I5 is preferably not less than 0.5 times and not more than 2 times the fourth width W4 (sixth width W6). The fifth interval I5 is preferably not less than 0.5 times and not more than 2 times the fourth interval I4 described above. The fifth interval I5 is particularly preferably not more than 1.5 times the fourth interval I4. The fifth interval I5 may be substantially equal to the fourth interval I4. The fifth interval I5 may be not less than 0.1 μm and not more than 2.5 μm. The fifth interval I5 is preferably not less than 0.5 μm and not more than 1.5 μm.

In this embodiment, the outermost first dummy trench structure 61 at the active region 12 side is arranged at the first interval I1 described above from the outermost first trench source structure 25 such as to be adjacent to the outermost first trench source structure 25 in the second direction Y.

The first dummy trench structure 61 includes a first dummy trench 63, a first dummy insulating film 64, and a first dummy embedded electrode 65. The first dummy trench 63 is formed in the active surface 8 and demarcates a wall surface of the first dummy trench structure 61. A side wall and a bottom wall of the first dummy trench 63 is in communication with the third connecting surface 10C.

The first dummy insulating film 64 covers a wall surface of the first dummy trench 63 and is connected to the main surface insulating film 16 on the active surface 8. The first dummy insulating film 64 is connected to the main surface insulating film 16 at a communication portion with the third connecting surface 10C. The first dummy insulating film 64 may include at least one among a silicon oxide film, a silicon nitride film, and silicon oxynitride film.

In this embodiment, the first dummy insulating film 64 has a single layer structure consisting of the silicon oxide film. The first dummy insulating film 64 particularly preferably includes the silicon oxide film that consists of the oxide of the chip 2. The first dummy embedded electrode 65 is embedded in the first dummy trench 63 with the first dummy insulating film 64 interposed therebetween. The first dummy embedded electrode 65 may contain a conductive polysilicon.

The plurality of second dummy trench structures 62 are arranged in regions between the peripheral edge of the active surface 8 and the plurality of second trench resistor structures 43. The plurality of second dummy trench structures 62 are each arranged in a region between two first dummy trench structures 61 that are adjacent in the second direction Y. The plurality of second dummy trench structures 62 are aligned alternately with the plurality of first dummy trench structures 61 in the second direction Y and oppose the plurality of second trench resistor structures 43 in one-to-one correspondence in the first direction X.

That is, the second trench resistor structures 43 to which the gate potential VG is to be applied and the second dummy trench structures 62 to which the source potential VS is to be applied are opposed in the first direction X. The plurality of second dummy trench structures 62 are each formed in a band shape extending in the first direction X in plan view.

The plurality of second dummy trench structures 62 oppose the first trench source structures 25 and the second trench source structures 30 in the second direction Y. The plurality of second dummy trench structures 62 have portions drawn out to end portion sides of the plurality of second trench resistor structures 43 with respect to the plurality of first trench resistor structures 42.

Specifically, the plurality of second dummy trench structures 62 are drawn out to the end portion sides of the plurality of second trench resistor structures 43 with respect to regions between the first trench resistor structures 42 and the first dummy trench structures 61. End portions of the plurality of second dummy trench structures 62 thereby oppose the first trench resistor structures 42 in the second direction Y. That is, the plurality of second dummy trench structures 62 have portions opposing the first trench resistor structures 42 in the second direction Y and have portions opposing the first dummy trench structures 61 in the second direction Y.

In this embodiment, the plurality of second dummy trench structures 62 penetrate through the third connecting surface 10C and are exposed from the third connecting surface 10C. The plurality of second dummy trench structures 62 penetrate through the body region 17 such as to reach the first semiconductor region 6. The plurality of second dummy trench structures 62 are formed at an interval to the active surface 8 side from the bottom portion of the first semiconductor region 6.

Hereinafter, the single second dummy trench structure 62 shall be described. The second dummy trench structure 62 has a seventh width W7 in the second direction Y and has a seventh depth D7 in the normal direction Z. The seventh width W7 is preferably substantially equal to the fifth width W5 described above. The seventh width W7 is preferably substantially equal to the second width W2 (first width W1) described above. The seventh width W7 may be not less than 0.1 μm and not more than 3 μm. The seventh width W7 is preferably not less than 0.5 μm and not more than 2 μm.

The seventh depth D7 is not less than the sixth depth D6 (fourth depth D4) described above. In this embodiment, the seventh depth D7 is greater than the sixth depth D6 (fourth depth D4). The seventh depth D7 is preferably not less than 1.5 times and not more than 3 times the sixth depth D6 (fourth depth D4). The seventh depth D7 is preferably substantially equal to the fifth depth D5 (second depth D2) described above. In this embodiment, the seventh depth D7 is substantially equal to the outer depth DO described above. The seventh depth D7 may be not less than 0.1 μm and not more than 5 μm. The seventh depth D7 is particularly preferably not more than 2.5 μm.

The second dummy trench structure 62 is arranged at a sixth interval I6 from the first dummy trench structure 61 in the second direction Y. The sixth interval I6 is preferably not less than 0.5 times and not more than 2 times the sixth width W6 (seventh width W7). The sixth interval I6 is particularly preferably less than the sixth width W6 (seventh width W7).

The sixth interval I6 is preferably substantially equal to the fourth interval I4 described above. The sixth interval I6 is preferably substantially equal to the first interval I1 described above. The sixth interval I6 may be not less than 0.1 μm and not more than 2.5 μm. The sixth interval 16 is preferably not less than 0.5 μm and not more than 1.5 μm.

The second dummy trench structure 62 is arranged at a seventh interval I7 from the second trench resistor structure 43 in the first direction X. The seventh interval 17 is preferably not less than 0.5 times and not more than 2 times the sixth width W6 (seventh width W7).

The seventh interval I7 is particularly preferably not more than 1.5 times the sixth interval I6 (fourth interval I4). The seventh interval I7 is preferably substantially equal to the fifth interval I5 described above. The seventh interval I7 may be substantially equal to the sixth interval 16 (fourth interval I4). The seventh interval I7 may be not less than 0.1 μm and not more than 2.5 μm. The seventh interval 17 is preferably not less than 0.5 μm and not more than 1.5 μm.

The second dummy trench structure 62 includes a second dummy trench 66, a second dummy insulating film 67, and a second dummy embedded electrode 68. The second dummy trench 66 is formed in the active surface 8 and demarcates a wall surface of the second dummy trench structure 62. A side wall of the second dummy trench 66 is in communication with the third connecting surface 10C. Also, a bottom wall of the second dummy trench 66 is in communication with the outer surface 9.

The second dummy insulating film 67 covers a wall surface of the second dummy trench 66 and is connected to the main surface insulating film 16 on the active surface 8. The second dummy insulating film 67 is connected to the main surface insulating film 16 at a communication portion with the third connecting surface 10C and a communication portion with the outer surface 9. The second dummy insulating film 67 may include at least one among a silicon oxide film, a silicon nitride film, and silicon oxynitride film.

In this embodiment, the second dummy insulating film 67 has a single layer structure consisting of the silicon oxide film. The second dummy insulating film 67 particularly preferably includes the silicon oxide film that consists of the oxide of the chip 2. The second dummy embedded electrode 68 is embedded in the second dummy trench 66 with the second dummy insulating film 67 interposed therebetween. The second dummy embedded electrode 68 may contain a conductive polysilicon.

With reference to FIG. 23, the semiconductor device 1 includes a plurality of main mesa portions 70, a plurality of first mesa portions 71, and a plurality of second mesa portions 72. Each main mesa portion 70 is demarcated in a region between a first trench resistor structure 42 and a second trench resistor structure 43 and a region between a first dummy trench structure 61 and a second dummy trench structure 62. Each main mesa portion 70 extends in a band shape in the first direction X. A width in the second direction Y of each main mesa portion 70 is defined by the fourth interval I4 and the sixth interval I6 described above.

Each first mesa portion 71 is demarcated in a region between a first trench resistor structure 42 and a first dummy trench structure 61 and is connected to main mesa portions 70. Each first mesa portion 71 is a region in which a voltage drop between the gate potential VG and the source potential VS occurs in the first direction X. A width in the first direction X of each first mesa portion 71 is defined by the fifth interval I5 described above.

In this embodiment, each first mesa portion 71 is shifted to the second dummy trench structure 62 side with respect to end portions of the second trench resistor structures 43 such as to oppose the second dummy trench structures 62 in the second direction Y but not oppose the second trench resistor structures 43 in the second direction Y. Each first mesa portion 71 is formed at an interval in the first direction X from a peripheral edge of the resistive film 50 and does not oppose the resistive film 50 in the normal direction Z.

Therefore, electrical interference of the resistive film 50 with respect to each first mesa portion 71 is suppressed and electrical interference of each first mesa portion 71 with respect to the resistive film 50 is suppressed. As a matter of course, when the resistive film 50 that is wider than the plurality of trench resistor structures 41 is formed, each first mesa portion 71 may oppose the resistive film 50 in the normal direction Z.

Each first mesa portion 71 demarcates, with one main mesa portion 70, a mesa of T-shape in plan view. In another aspect, each first mesa portion 71 demarcates, with two main mesa portions 70, a mesa of H-shape in plan view. In this embodiment, the plurality of first mesa portions 71 are formed on the same straight line along the second direction Y. As a matter of course, the plurality of first mesa portions 71 may be formed to be shifted with respect to each other in the first direction X such as not to be positioned on the same straight line along the second direction Y.

Each second mesa portion 72 is demarcated in a region between a second trench resistor structure 43 and a second dummy trench structure 62 and is connected to main mesa portions 70. Each second mesa portion 72 is a region in which a voltage drop between the gate potential VG and the source potential VS occurs in the first direction X. A width in the first direction X of each second mesa portion 72 is defined by the seventh interval I7 described above.

Each second mesa portion 72 is formed at an interval in the first direction X from the first mesa portions 71 such as not to oppose the first mesa portions 71 in the second direction Y. In this embodiment, each second mesa portion 72 is shifted to the first trench resistor structure 42 side with respect to end portions of the first dummy trench structures 61 such as to oppose the first trench resistor structures 42 in the second direction Y but not oppose the first dummy trench structures 61 in the second direction Y.

Each second mesa portion 72 is formed at an interval in the first direction X from the peripheral edge of the resistive film 50 in plan view and does not oppose the resistive film 50 in the normal direction Z. Therefore, electrical interference of the resistive film 50 with respect to each second mesa portion 72 is suppressed and electrical interference of each second mesa portion 72 with respect to the resistive film 50 is suppressed. As a matter of course, when the resistive film 50 that is wider than the plurality of trench resistor structures 41 is formed, each second mesa portion 72 may oppose the resistive film 50 in the normal direction Z.

Each second mesa portion 72 demarcates, with one main mesa portion 70, a mesa of T-shape in plan view. In another aspect, each second mesa portion 72 demarcates, with two main mesa portions 70, a mesa of H-shape in plan view. In this embodiment, the plurality of second mesa portions 72 are formed on the same straight line along the second direction Y.

As a matter of course, the plurality of second mesa portions 72 may be formed to be shifted with respect to each other in the first direction X such as not to be positioned on the same straight line along the second direction Y. Even in this case, the plurality of second mesa portions 72 are formed at an interval in the first direction X from the first mesa portions 71 such as not to oppose the first mesa portions 71 in the second direction Y.

The semiconductor device 1 includes a plurality of fourth well regions 75 of the p-type that are formed in regions in the first terminal region 15A along the plurality of first trench resistor structures 42. In this embodiment, the fourth well regions 75 have a higher p-type impurity concentration than the body region 17. As a matter of course, the p-type impurity concentration of the fourth well regions 75 may instead be lower than that of the body region 17. The p-type impurity concentration of the fourth well regions 75 is preferably substantially equal to the p-type impurity concentration of the first well regions 35.

The plurality of fourth well regions 75 each cover the wall surface of the corresponding first trench resistor structure 42 at intervals from the second trench resistor structures 43, the first dummy trench structures 61, and the second dummy trench structures 62 and are electrically connected to the body region 17 in the surface layer portion of the active surface 8.

Each fourth well region 75 includes a portion covering the wall surface of each first trench resistor structure 42 inside each first mesa portion 71 and opposes each first dummy trench structure 61 in the first direction X. In this embodiment, each fourth well region 75 has a portion opposing the second trench resistor structures 43 in the second direction Y and has a portion opposing the second dummy trench structures 62 in the second direction Y.

The plurality of fourth well regions 75 are formed at an interval to the active surface 8 side from the bottom portion of the first semiconductor region 6 and oppose the second semiconductor region 7 with portions of the first semiconductor region 6 interposed therebetween. Bottom portions of the plurality of fourth well regions 75 are positioned at the active surface 8 side with respect to the depth position of the bottom portions of the plurality of second well regions 36. The bottom portions of the plurality of fourth well regions 75 are formed at a substantially equal depth to the bottom portions of the plurality of first well regions 35. The plurality of fourth well regions 75 form pn junction portions with the first semiconductor region 6.

The semiconductor device 1 includes a plurality of fifth well regions 76 of the p-type that are formed in regions in the first terminal region 15A along the plurality of second trench resistor structures 43. In this embodiment, the fifth well regions 76 have a higher p-type impurity concentration than the body region 17. As a matter of course, the p-type impurity concentration of the fifth well regions 76 may instead be lower than that of the body region 17. The p-type impurity concentration of the fifth well regions 76 is preferably substantially equal to the p-type impurity concentration of the plurality of fourth well regions 75 (second well regions 36).

The plurality of fifth well regions 76 each cover the wall surface of the corresponding second trench resistor structure 43 at intervals from the first trench resistor structures 42, the first dummy trench structures 61, and the second dummy trench structures 62 and are electrically connected to the body region 17 in the surface layer portion of the active surface 8. Each fifth well region 76 includes a portion covering the wall surface of each second trench resistor structure 43 inside each second mesa portion 72 and opposes the second dummy trench structure 62 in the first direction X. In this embodiment, each fifth well region 76 opposes the first trench resistor structures 42 in the second direction Y but does not oppose the first dummy trench structures 61 in the second direction Y.

The plurality of fifth well regions 76 are formed at an interval to the active surface 8 side from the bottom portion of the first semiconductor region 6 and oppose the second semiconductor region 7 with portions of the first semiconductor region 6 interposed therebetween. Bottom portions of the plurality of fifth well regions 76 are positioned at the bottom portion side of the first semiconductor region 6 with respect to the depth position of the bottom portions of the plurality of fourth well regions 75 (first well regions 35). The bottom portions of the plurality of fifth well regions 76 are formed at a substantially equal depth to the bottom portions of the plurality of second well regions 36. The plurality of fifth well regions 76 form pn junction portions with the first semiconductor region 6.

The semiconductor device 1 includes a plurality of sixth well regions 77 of the p-type that are formed in regions in the first terminal region 15A along the plurality of first dummy trench structures 61. In this embodiment, the sixth well regions 77 have a higher p-type impurity concentration than the body region 17. As a matter of course, the p-type impurity concentration of the sixth well regions 77 may instead be lower than that of the body region 17. The p-type impurity concentration of the sixth well regions 77 is preferably substantially equal to the p-type impurity concentration of the fourth well regions 75 (first well regions 35).

The plurality of sixth well regions 77 each cover the wall surface of the corresponding first dummy trench structure 61 at intervals from the first trench resistor structures 42, the second trench resistor structures 43, and the second dummy trench structures 62 and are electrically connected to the body region 17 in the surface layer portion of the active surface 8. Each sixth well region 77 includes a portion covering the wall surface of each first dummy trench structure 61 inside each first mesa portion 71 and opposes the first trench resistor structure 42 in the first direction X.

Each sixth well region 77 may be formed at an interval from each fourth well region 75 inside each first mesa portion 71 or may be made integral to each fourth well region 75. Each sixth well region 77 opposes the second dummy trench structures 62 in the second direction Y but does not oppose the second trench resistor structure 43 in the second direction Y.

The plurality of sixth well regions 77 are formed at an interval to the active surface 8 side from the bottom portion of the first semiconductor region 6 and oppose the second semiconductor region 7 with portions of the first semiconductor region 6 interposed therebetween. Bottom portions of the plurality of sixth well regions 77 are positioned at the active surface 8 side with respect to the depth position of the bottom portions of the plurality of fifth well regions 76 (second well regions 36). The bottom portions of the plurality of sixth well regions 77 are formed at a substantially equal depth to the bottom portions of the plurality of fourth well regions 75 (first well regions 35). The plurality of sixth well regions 77 form pn junction portions with the first semiconductor region 6.

The semiconductor device 1 includes a plurality of seventh well regions 78 of the p-type that are formed in regions in the first terminal region 15A along the plurality of second dummy trench structures 62. In this embodiment, the seventh well regions 78 have a higher p-type impurity concentration than the body region 17. As a matter of course, the p-type impurity concentration of the seventh well regions 78 may instead be lower than that of the body region 17. The p-type impurity concentration of the seventh well regions 78 is preferably substantially equal to the p-type impurity concentration of the plurality of fifth well regions 76 (second well regions 36).

The plurality of seventh well regions 78 each cover the wall surface of the corresponding second dummy trench structure 62 at intervals from the first trench resistor structures 42, the second trench resistor structures 43, and the first dummy trench structures 61 and are electrically connected to the body region 17 in the surface layer portion of the active surface 8. Each seventh well region 78 includes a portion covering the wall surface of each second dummy trench structure 62 inside each second mesa portion 72 and opposes the second trench resistor structure 43 in the first direction X.

Each seventh well region 78 may be formed at an interval from each fifth well region 76 inside each second mesa portion 72 or may be made integral to each fifth well region 76. Each seventh well region 78 has a portion opposing the first dummy trench structures 61 in the second direction Y and has a portion opposing the first trench resistor structure 42 in the second direction Y.

The plurality of seventh well regions 78 are formed at an interval to the active surface 8 side from the bottom portion of the first semiconductor region 6 and oppose the second semiconductor region 7 with portions of the first semiconductor region 6 interposed therebetween. Bottom portions of the plurality of seventh well regions 78 are positioned at the bottom portion side of the first semiconductor region 6 with respect to the depth position of the bottom portions of the plurality of sixth well regions 77 (fourth well regions 75). The bottom portions of the plurality of seventh well regions 78 are formed at a substantially equal depth to the bottom portions of the plurality of fifth well regions 76 (second well regions 36). The plurality of seventh well regions 78 form pn junction portions with the first semiconductor region 6.

The semiconductor device 1 includes a plurality of second contact regions 79 of the p-type that are formed in regions in the first terminal region 15A along the plurality of second trench resistor structures 43. The second contact regions 79 have a higher p-type impurity concentration than the body region 17. The p-type impurity concentration of the second contact regions 79 is higher than that of the fifth well regions 76. The p-type impurity concentration of the second contact regions 79 is preferably substantially equal to the p-type impurity concentration of the first contact regions 38.

The plurality of second contact regions 79 each cover the walls surface of the corresponding second trench resistor structure 43 inside the corresponding fifth well region 76. The plurality of second contact regions 79 are formed in multiple-to-one correspondence with respect to each second trench resistor structure 43. The plurality of second contact regions 79 are formed at intervals along the corresponding second trench resistor structure 43. The plurality of second contact regions 79 are each drawn out onto the surface layer portion of the body region 17 from inside the corresponding fifth well region 76 and along the wall surface of the corresponding second trench resistor structure 43 and are exposed from the active surface 8.

In this embodiment, the plurality of second contact regions 79 are each formed in a band shape extending in the first direction X in plan view. A length in the first direction X of the plurality of second contact regions 79 is preferably not less than the fifth width W5 described above. The length of the plurality of second contact regions 79 is preferably greater than a distance between two second contact regions 79 that are adjacent in the first direction X. The length of the plurality of second contact regions 79 is preferably less than a distance between the first mesa portions 71 and the second mesa portions 72. The length of the plurality of second contact regions 79 is preferably substantially equal to the length of the plurality of first contact regions 38.

The plurality of second contact regions 79 include outermost second contact regions 79 each covering a region along an end portion of each second trench resistor structure 43. The outermost second contact regions 79 are preferably formed at an interval from the second mesa portions 72. That is, the outermost second contact regions 79 preferably oppose the first trench resistor structures 42 in the second direction Y but do not oppose the first dummy trench structure 61 in the second direction Y.

For example, in the first direction X, a distance between the second mesa portions 72 and the outermost second contact regions 79 may be less than the length of the second contact regions 79. The distance between the second mesa portions 72 and the outermost second contact regions 79 may be less than the fifth width W5 described above. The distance between the second mesa portions 72 and the outermost second contact regions 79 is particularly preferably less than the width of the second mesa portions 72 (the seventh interval I7).

The plurality of second contact regions 79 arranged along one second trench resistor structure 43 oppose, in the second direction Y, the plurality of second contact regions 79 arranged along another second trench resistor structure 43. That is, in this embodiment, the plurality of second contact regions 79 are arrayed, as a whole, in a matrix at intervals in the first direction X and the second direction Y in plan view. The plurality of second contact regions 79 may oppose the plurality of first contact regions 38 in the second direction Y. In this case, the plurality of second contact regions 79 may be arrayed in the matrix together with the plurality of first contact regions 38.

The plurality of second contact regions 79 arranged along the one second trench resistor structure 43 may be aligned shifted in the first direction X such as to oppose, in the second direction Y, regions between the plurality of second contact regions 79 arranged along the other second trench resistor structure 43. That is, the plurality of second contact regions 79 may be arrayed, as a whole, in a staggered arrangement at intervals in the first direction X and the second direction Y in plan view. The plurality of second contact regions 79 may oppose the regions between the plurality of first contact regions 38 in the second direction Y. In this case, the plurality of second contact regions 79 may be arrayed in the staggered arrangement together with the plurality of first contact regions 38.

The semiconductor device 1 includes a plurality of third contact regions 80 of the p-type that are formed in regions in the first terminal region 15A along the plurality of second dummy trench structures 62. The third contact regions 80 have a higher p-type impurity concentration than the body region 17. The p-type impurity concentration of the third contact regions 80 is higher than that of the seventh well regions 78. The p-type impurity concentration of the third contact regions 80 is preferably substantially equal to the p-type impurity concentration of the second contact regions 79 (first contact regions 38).

The plurality of third contact regions 80 each cover the walls surface of the corresponding second dummy trench structure 62 inside the corresponding seventh well region 78. The plurality of third contact regions 80 are formed in multiple-to-one correspondence with respect to each second dummy trench structure 62. The plurality of third contact regions 80 are formed at intervals along the corresponding second dummy trench structure 62. The plurality of third contact regions 80 are each drawn out onto the surface layer portion of the body region 17 from inside the corresponding seventh well region 78 and along the wall surface of the corresponding second dummy trench structure 62 and are exposed from the active surface 8.

In this embodiment, the plurality of third contact regions 80 are each formed in a band shape extending in the first direction X in plan view. A length in the first direction X of the plurality of third contact regions 80 is preferably not less than the seventh width W7 described above. The length of the plurality of third contact regions 80 is preferably greater than a distance between two third contact regions 80 that are adjacent in the first direction X. The length of the plurality of third contact regions 80 is preferably less than the distance between the first mesa portions 71 and the second mesa portions 72. The length of the plurality of third contact regions 80 is preferably substantially equal to the length of the plurality of second contact regions 79 (first contact regions 38).

The plurality of third contact regions 80 oppose the first dummy trench structures 61 in the second direction Y in a region at the third connecting surface 10C side with respect to the first mesa portions 71. The plurality of third contact regions 80 are formed at intervals along the respective second dummy trench structures 62 such that the first mesa portions 71 are each positioned between two mutually adjacent third contact regions 80. The plurality of third contact regions 80 are preferably formed at intervals in the first direction X from the first mesa portions 71 such as not to oppose the first mesa portions 71.

For example, in the first direction X, a distance between the first mesa portions 71 and the third contact regions 80 is preferably less than the length of the third contact regions 80. The distance between the first mesa portions 71 and the third contact regions 80 is preferably less than the seventh width W7 described above. The distance between the first mesa portions 71 and the third contact regions 80 is particularly preferably less than the width of the first mesa portions 71 (the fifth interval I5).

The plurality of third contact regions 80 include at least one (in this embodiment, one) outermost third contact region 80 formed in a range between the first mesa portions 71 and the second mesa portions 72. The outermost third contact region 80 opposes the first trench resistor structures 42 in the second direction Y. The outermost third contact region 80 together with the outermost second contact regions 79 sandwich the second mesa portions 72.

The outermost third contact region 80 is preferably formed at intervals in the first direction X from the first mesa portions 71 and the second mesa portions 72. That is, the outermost third contact region 80 preferably opposes the first trench resistor structures 42 in the second direction Y but does not oppose the first dummy trench structures 61 in the second direction Y.

For example, in the first direction X, a distance between the second mesa portions 72 and the third contact regions 80 is preferably less than the length of the third contact regions 80. The distance between the second mesa portions 72 and the third contact regions 80 is preferably less than the seventh width W7 described above.

A distance between the second mesa portions 72 and the outermost third contact region 80 is particularly preferably less than the width of the second mesa portions 72 (the seventh interval I7). A distance between the outermost second contact regions 79 and the outermost third contact region 80 that are adjacent with the second mesa portions 72 interposed therebetween is preferably substantially equal to a distance between two adjacent third contact regions 80 that are adjacent with the first mesa portions 71 interposed therebetween.

The plurality of third contact regions 80 arranged along one second dummy trench structure 62 oppose, in the second direction Y, the plurality of third contact regions 80 arranged along another second dummy trench structure 62. That is, in this embodiment, the plurality of third contact regions 80 are arrayed, as a whole, in a matrix at intervals in the first direction X and the second direction Y in plan view. In this case, the plurality of third contact regions 80 may be arrayed in the matrix together with the plurality of second contact regions 79. Also, the plurality of third contact regions 80 may be arrayed in the matrix together with the plurality of first contact regions 38.

The plurality of third contact regions 80 arranged along the one second dummy trench structure 62 may be aligned shifted in the first direction X such as to oppose, in the second direction Y, regions between the plurality of third contact regions 80 arranged along the other second dummy trench structure 62. That is, the plurality of third contact regions 80 may be arrayed, as a whole, in a staggered arrangement at intervals in the first direction X and the second direction Y in plan view. In this case, the plurality of third contact regions 80 may be arrayed in the staggered arrangement together with the plurality of second contact regions 79. Also, the plurality of third contact regions 80 may be arrayed in the staggered arrangement together with the plurality of first contact regions 38.

With reference to FIG. 13, the semiconductor device 1 includes a terminal dummy structure 85 that is formed in the first main surface 3 (active surface 8) in the first terminal region 15A. The terminal dummy structure 85 is incorporated in the active surface 8 (first terminal region 15A) with one purpose being to relax the localized electric field concentration in the vicinity of the gate resistor 40 and improve the withstand voltage (for example, the breakdown voltage). Whether or not the terminal dummy structure 85 is provided is arbitrary and a configuration not including the terminal dummy structure 85 may be adopted instead.

The terminal dummy structure 85 is arranged in a region at the first side surface 5A side (first connecting surface 10A side) with respect to the gate resistor 40. The terminal dummy structure 85 is formed in a terminal edge portion of the active surface 8. The terminal dummy structure 85 opposes the gate resistor 40 and the dummy structure 55 in the second direction Y. The terminal dummy structure 85 opposes the active region 12 in the second direction Y with the gate resistor 40 interposed therebetween, opposes the first peripheral edge region 14A in the second direction Y with the first dummy structure 56 interposed therebetween, and opposes the second peripheral edge region 14B in the second direction Y with the second dummy structure 57 interposed therebetween.

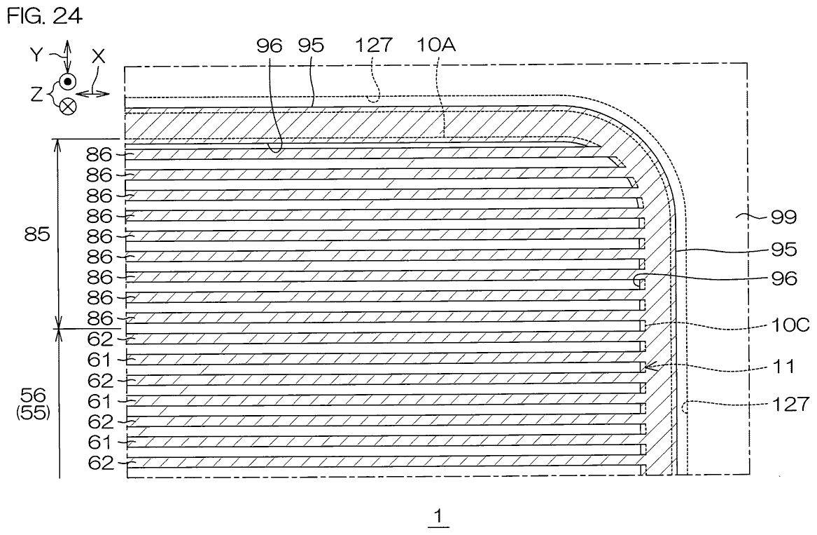

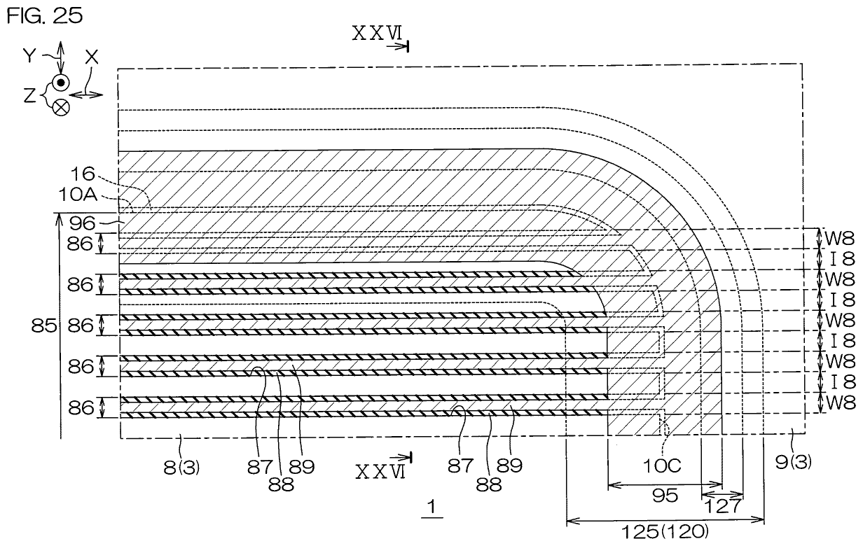

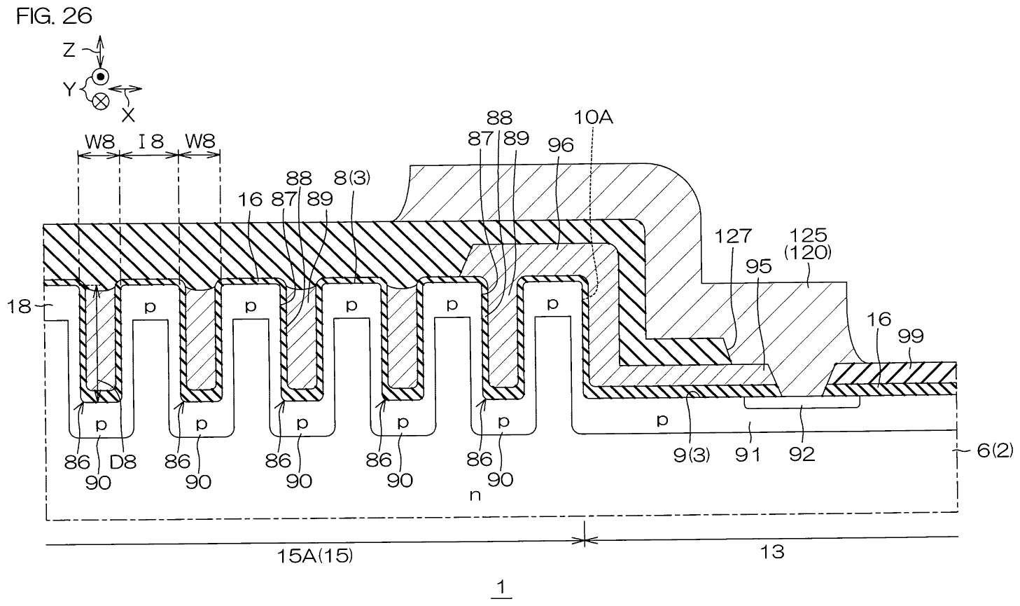

Hereinafter, the terminal dummy structure 85 shall be described specifically with reference to FIG. 24 to FIG. 26. FIG. 24 is an enlarged plan view showing a layout of the terminal dummy structure 85. FIG. 25 is a more enlarged plan view showing a layout of the terminal dummy structure 85. FIG. 26 is a cross sectional view taken along line XXVI-XXVI shown in FIG. 25.

With reference to FIG. 24 to FIG. 26, the terminal dummy structure 85 includes at least one (in this embodiment, a plurality of a) trench terminal structure 86 that is formed in the first terminal region 15A. The source potential VS as the second potential is to be applied to the plurality of trench terminal structures 86. The plurality of trench terminal structures 86 are each formed in a band shape extending in the first direction X and are aligned at intervals in the second direction Y. The plurality of trench terminal structures 86 oppose the second trench resistor structures 43 and the second dummy trench structures 62 in the second direction Y.

The plurality of trench terminal structures 86 are exposed from at least one of either of the third connecting surface 10C and the fourth connecting surface 10D. In this embodiment, the trench terminal structures 86 penetrate through both the third connecting surface 10C and the fourth connecting surface 10D and are exposed from both the third connecting surface 10C and the fourth connecting surface 10D. The plurality of trench terminal structures 86 penetrate through the body region 17 such as to reach the first semiconductor region 6. The plurality of trench terminal structures 86 are formed at an interval to the active surface 8 side from the bottom portion of the first semiconductor region 6.

Hereinafter, the single trench terminal structure 86 shall be described. The trench terminal structure 86 has an eighth width W8 in the second direction Y and has an eighth depth D8 in the normal direction Z. The eighth width W8 is preferably substantially equal to the fifth width W5 (second width W2) described above. The eighth width W8 may be not less than 0.1 μm and not more than 3 μm. The eighth width W8 is preferably not less than 0.5 μm and not more than 2 μm.

The eighth depth D8 is not less than the fourth depth D4 (first depth D1) described above. In this embodiment, the eighth depth D8 is greater than the fourth depth D4 (first depth D1). The eighth depth D8 is preferably not less than 1.5 times and not more than 3 times the fourth depth D4 (first depth D1). In this embodiment, the eighth depth D8 is substantially equal to the fifth depth D5 (second depth D2) described above. The eighth depth D8 is substantially equal to the outer depth DO described above. The eighth depth D8 may be not less than 0.1 μm and not more than 5 μm. The eighth depth D8 is particularly preferably not more than 2.5 μm.

The plurality of trench terminal structures 86 are arranged at an eighth interval I8 from each other in the second direction Y. The eighth interval I8 is preferably not less than 0.5 times and not more than 2 times the eighth width W8. The eighth interval I8 is particularly preferably less than the eighth width W8. The eighth width W8 is preferably substantially equal to the fourth interval I4 (first interval I1) described above. The eighth width W8 may be not less than 0.1 μm and not more than 2.5 μm. The eighth interval I8 is preferably not less than 0.5 μm and not more than 1.5 μm.

In this embodiment, the outermost trench terminal structure 86 at the gate resistor 40 side is arranged at the fourth interval I4 described above from the outermost second trench resistor structure 43 such as to be adjacent to the outermost second trench resistor structure 43 in the second direction Y. Also, in this embodiment, the outermost trench terminal structure 86 is arranged at the sixth interval I6 described above from the outermost second dummy trench structures 62 such as to be adjacent to the outermost second dummy trench structures 62 in the second direction Y.

The trench terminal structure 86 includes a terminal trench 87, a terminal insulating film 88, and a terminal embedded electrode 89. The terminal trench 87 is formed in the active surface 8 and demarcates a wall surface of the trench terminal structure 86. A side wall of the terminal trench 87 is in communication with the third connecting surface 10C. A bottom wall of the terminal trench 87 is in communication with the outer surface 9.

The terminal insulating film 88 covers a wall surface of the terminal trench 87 and is connected to the main surface insulating film 16 on the active surface 8. The terminal insulating film 88 is connected to the main surface insulating film 16 at a communication portion with the third connecting surface 10C and a communication portion with the outer surface 9. The terminal insulating film 88 may include at least one among a silicon oxide film, a silicon nitride film, and silicon oxynitride film.

In this embodiment, the terminal insulating film 88 has a single layer structure consisting of the silicon oxide film. The terminal insulating film 88 particularly preferably includes the silicon oxide film that consists of the oxide of the chip 2. The terminal embedded electrode 89 is embedded in the terminal trench 87 with the terminal insulating film 88 interposed therebetween. The terminal embedded electrode 89 may contain a conductive polysilicon.

The semiconductor device 1 includes a plurality of eighth well regions 90 of the p-type that are formed in regions in the first terminal region 15A along the plurality of trench terminal structures 86. In this embodiment, the eighth well regions 90 have a higher p-type impurity concentration than the body region 17. As a matter of course, the p-type impurity concentration of the eighth well regions 90 may instead be lower than that of the body region 17. The p-type impurity concentration of the eighth well regions 90 is preferably substantially equal to the p-type impurity concentration of the plurality of second well regions 36 (first well regions 35).

The plurality of eighth well regions 90 each cover the wall surface of the corresponding trench terminal structure 86 at intervals from adjacent trench terminal structures 86 and are electrically connected to the body region 17 in the surface layer portion of the active surface 8. The plurality of eighth well regions 90 each extend in a band shape along the corresponding trench terminal structure 86 in plan view and are exposed from the third connecting surface 10C and the fourth connecting surface 10D.

The plurality of eighth well regions 90 are formed at an interval to the active surface 8 side from the bottom portion of the first semiconductor region 6 and oppose the second semiconductor region 7 with portions of the first semiconductor region 6 interposed therebetween. Bottom portions of the plurality of eighth well regions 90 are positioned at the bottom portion side of the first semiconductor region 6 with respect to the depth position of the bottom portions of the plurality of first well regions 35. The bottom portions of the plurality of eighth well regions 90 are formed at a substantially equal depth to the bottom portions of the plurality of second well regions 36. The plurality of eighth well regions 90 form pn junction portions with the first semiconductor region 6.

With reference again to FIG. 4, the semiconductor device 1 includes the dummy structure 55 and the terminal dummy structure 85 that are formed in the first main surface 3 (active surface 8) in the second terminal region 15B. The semiconductor device 1 does not include a gate resistor 40 in the second terminal region 15B. The dummy structure 55 at the second terminal region 15B side is arranged in a region at the fourth side surface 5D side (fourth connecting surface 10D side) with respect to the active region 12 and opposes the active region 12 and the peripheral edge region 14 in the second direction Y.

As with the first dummy structure 56 at the first terminal region 15A side, the dummy structure 55 at the second terminal region 15B side includes a plurality of dummy trench structures 60 (a plurality of first dummy trench structures 61 and a plurality of second dummy trench structures 62). The plurality of dummy trench structures 60 at the second terminal region 15B side penetrate through both the third connecting surface 10C and the fourth connecting surface 10D and are exposed from both the third connecting surface 10C and the fourth connecting surface 10D. Besides the above, the arrangement of the dummy structure 55 at the second terminal region 15B side is the same as the arrangement of the dummy structure 55 (first dummy structure 56) at the first terminal region 15A side.

The terminal dummy structure 85 at the second terminal region 15B side has the same arrangement as the terminal dummy structure 85 at the first terminal region 15A side. In regard to other descriptions of the terminal dummy structure 85 at the second terminal region 15B side, the descriptions of the terminal dummy structure 85 at the first terminal region 15A side apply.

Although specific illustration shall be omitted, the semiconductor device 1 includes a plurality of sixth well regions 77, a plurality of seventh well regions 78, a plurality of second contact regions 79, and a plurality of eighth well regions 90 in the second terminal region 15B as well. In regard to descriptions of the sixth well regions 77, the seventh well regions 78, the second contact regions 79, and the eighth well regions 90 at the second terminal region 15B side, the descriptions of the sixth well regions 77, the seventh well regions 78, the second contact regions 79, and the eighth well regions 90 at the first terminal region 15A side apply.

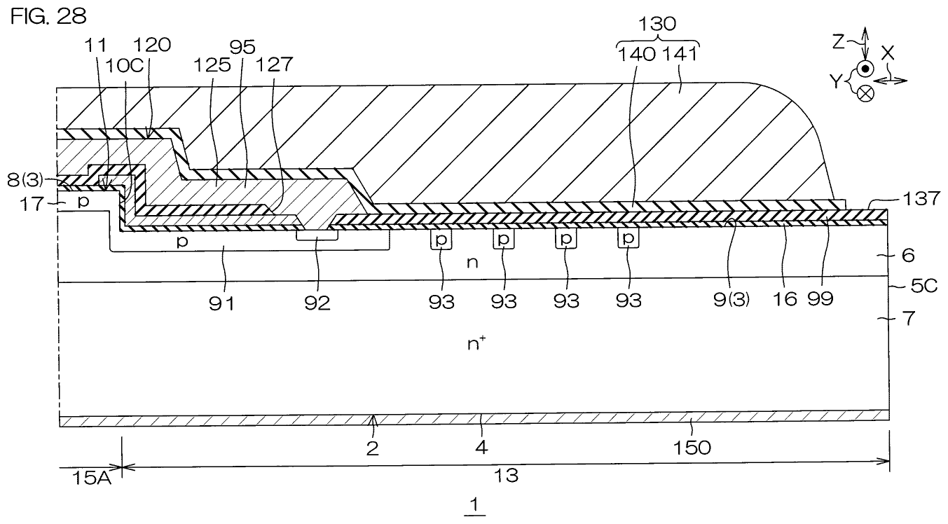

Next, a structure of the outer region 13 shall be described with reference to the cross sectional view of FIG. 28. With reference to FIG. 28, the semiconductor device 1 includes an outer well region 91 of the p-type that is formed in a surface layer portion of the outer surface 9. The outer well region 91 has a lower p-type impurity concentration than the first contact regions 38.

In this embodiment, the p-type impurity concentration of the outer well region 91 is higher than that of the body region 17. As a matter of course, the p-type impurity concentration of the outer well region 91 may instead be lower than that of the body region 17. The outer well region 91 preferably has the p-type impurity concentration that is substantially equal to that of the first well regions 35 (second well regions 36).

In plan view, the outer well region 91 is formed at an interval to the active surface 8 side from the peripheral edge (first to fourth side surfaces 5A to 5D) of the outer surface 9 and extends in a band shape along the active surface 8. In this embodiment, the outer well region 91 is formed in an annular shape (specifically, a quadrangle annular shape) surrounding the active surface 8 in plan view. The outer well region 91 extends toward surface layer portions of the first to fourth connecting surfaces 10A to 10D from the surface layer portion of the outer surface 9 and covers the first to fourth connecting surfaces 10A to 10D.

The outer well region 91 is electrically connected to the body region 17 in the surface layer portion of the active surface 8. The outer well region 91 is connected to the second well regions 36 in the communication portions of the third connecting surface 10C (fourth connecting surface 10D) and the first trench source structures 25. The outer well region 91 is connected to the third well regions 37 in the communication portions of the third connecting surface 10C (fourth connecting surface 10D) and the second trench source structures 30.

The outer well region 91 is connected to the sixth well regions 77 in the communication portions of the third connecting surface 10C (fourth connecting surface 10D) and the first dummy trench structures 61. The outer well region 91 is connected to the seventh well regions 78 in the communication portions of the third connecting surface 10C (fourth connecting surface 10D) and the second dummy trench structures 62. The outer well region 91 is connected to the eighth well regions 90 in the communication portions of the third connecting surface 10C (fourth connecting surface 10D) and the trench terminal structures 86.

The outer well region 91 is formed at an interval to the outer surface 9 side from the bottom portion of the first semiconductor region 6 and opposes the second semiconductor region 7 with a portion of the first semiconductor region 6 interposed therebetween. The outer well region 91 is positioned further to the bottom portion side of the first semiconductor region 6 than the bottom walls of the first trench source structures 25 (second trench resistor structures 43). A bottom portion of the outer well region 91 is positioned further to the bottom portion side of the first semiconductor region 6 than the bottom portions of the first contact regions 38. The bottom portion of the outer well region 91 is preferably formed at substantially the same depth position as the bottom portions of the second well regions 36. The outer well region 91 forms a pn junction portion with the first semiconductor region 6.

The semiconductor device 1 includes an outer contact region 92 of the p-type that is formed in a surface layer portion of the outer well region 91. The outer contact region 92 has a higher p-type impurity concentration than the body region 17. The p-type impurity concentration of the outer contact region 92 is higher than that of the outer well region 91. The p-type impurity concentration of the outer contact region 92 is preferably substantially equal to the p-type impurity concentration of the first contact regions 38 (second contact regions 79).

The outer contact region 92 is formed in the surface layer portion of the outer well region 91 at intervals from the peripheral edge (first to fourth connecting surfaces 10A to 10D) of the active surface 8 and the peripheral edge (first to fourth side surfaces 5A to 5D) of the outer surface 9 in plan view and is formed in a band shape extending along the active surface 8. In this embodiment, the outer contact region 92 is formed in an annular shape (specifically, a quadrangle annular shape) surrounding the active surface 8 in plan view.

The outer contact region 92 is formed at an interval to the outer surface 9 side from the bottom portion of the outer well region 91 and opposes the first semiconductor region 6 with a portion of the outer well region 91 interposed therebetween. The outer contact region 92 is positioned further to the bottom portion side of the first semiconductor region 6 than the bottom walls of the first trench source structures 25 (second trench resistor structures 43). A bottom portion of the outer contact region 92 is preferably formed at substantially the same depth position as the bottom portions of the first contact regions 38 (second contact regions 79).

The semiconductor device 1 includes at least one (preferably not less than two and not more than twenty of a) field region 93 of the p-type formed in a region in the surface layer portion of the outer surface 9 between the peripheral edge of the outer surface 9 and the outer well region 91. In this embodiment, the semiconductor device 1 includes four field regions 93. The plurality of field regions 93 are formed in an electrically floating state and relaxes an electric field inside the chip 2 at the outer surface 9.

A number, width, depth, p-type impurity concentration, etc., of the field regions 93 are arbitrary and can take on various values in accordance with the electric field to be relaxed. The field regions 93 may have a lower p-type impurity concentration than the outer contact region 92. The field regions 93 may have a higher p-type impurity concentration than the outer well region 91. The field regions 93 may have a lower p-type impurity concentration than the outer well region 91.

The plurality of field regions 93 are aligned at intervals to the peripheral edge side of the outer surface 9 from the outer well region 91 side. The plurality of field regions 93 are formed in band shapes extending along the active surface 8 in plan view. In this embodiment, the plurality of field regions 93 are formed in annular shapes (specifically, quadrangle annular shapes) surrounding the active surface 8 in plan view.

The plurality of field regions 93 are formed at an interval to the outer surface 9 side from the bottom portion of the first semiconductor region 6 and oppose the second semiconductor region 7 with portions of the first semiconductor region 6 interposed therebetween. The plurality of field regions 93 are positioned further to the bottom portion side of the first semiconductor region 6 than the bottom walls of the first trench source structures 25. Bottom portions of the plurality of field regions 93 are positioned further to the bottom portion side of the first semiconductor region 6 than the bottom portions of the first contact regions 38. The bottom portions of the plurality of field regions 93 may be formed at substantially the same depth position as the bottom portions of the second well regions 36.

The semiconductor device 1 includes a side wall wiring 95 that is formed on the outer surface 9 such as to cover at least one among the first to fourth connecting surfaces 10A to 10D. Specifically, the side wall wiring 95 is arranged on the main surface insulating film 16. The side wall wiring 95 also functions as a side wall structure that moderates a level difference formed between the active surface 8 and the outer surface 9.

The side wall wiring 95 is preferably formed in a band shape extending along at least one of either of the third connecting surface 10C and the fourth connecting surface 10D. In this embodiment, the side wall wiring 95 is formed in an annular shape (specifically, a quadrangle annular shape) extending along the first to fourth connecting surfaces 10A to 10D such as to surround the active surface 8. Portions of the side wall wiring 95 covering four corners of the active surface 8 are formed in shapes curving toward the outer surface 9 side.

The side wall wiring 95 includes a portion extending in a film shape along the outer surface 9 and a portion extending in a film shape along the first to fourth connecting surfaces 10A to 10D. A portion of the side wall wiring 95 positioned on the outer surface 9 may cover the outer surface 9 in a region at the outer surface 9 side with respect to the active surface 8. The portion of the side wall wiring 95 positioned on the outer surface 9 may have a thickness less than a thickness of the active mesa 11 (the outer depth DO).

On the outer surface 9, the side wall wiring 95 opposes the outer well region 91 with the main surface insulating film 16 interposed therebetween. The side wall wiring 95 may oppose the outer contact region 92 with the main surface insulating film 16 interposed therebetween. In this embodiment, the side wall wiring 95 is formed at intervals to the active surface 8 side from the field regions 93 in plan view.

On the first to fourth connecting surfaces 10A to 10D, the side wall wiring 95 opposes the second well regions 36, the third well regions 37, the sixth well regions 77, the seventh well regions 78, the eighth well regions 90, and the outer well region 91 with the main surface insulating film 16 interposed therebetween. In this embodiment, the side wall wiring 95 also opposes the body region 17 with the main surface insulating film 16 interposed therebetween.

On the first to fourth connecting surfaces 10A to 10D, the side wall wiring 95 covers exposed portions of the first trench source structures 25, exposed portions of the second trench source structures 30, exposed portions of the first dummy trench structure 61, exposed portions of the second dummy trench structures 62, and exposed portions of the trench terminal structures 86.

The side wall wiring 95 is thereby electrically connected to the first trench source structures 25, the second trench source structures 30, the first dummy trench structures 61, the second dummy trench structures 62, and the trench terminal structures 86. That is, the side wall wiring 95 applies the source potential VS to the connection objects from the outer surface 9 side.

The side wall wiring 95 has an overlap portion 96 that overlaps onto an edge portion of the active surface 8 from at least one among the first to fourth connecting surfaces 10A to 10D. The overlap portion 96 covers the active surface 8 in a film shape in plan view and is formed in a band shape extending along the edge portion of the active surface 8. In this embodiment, the overlap portion 96 is formed in an annular shape (specifically, a quadrangle annular shape) surrounding the inner portion of the active surface 8 in plan view.

On the active surface 8, the overlap portion 96 is electrically connected to the first trench source structures 25, the second trench source structures 30, the first dummy trench structures 61, the second dummy trench structures 62, and the trench terminal structures 86.

In this embodiment, the side wall wiring 95 contains a conductive polysilicon and is formed integral to the first source embedded electrodes 28, the second source embedded electrodes 33, the first dummy embedded electrodes 65, the second dummy embedded electrodes 68, and the terminal embedded electrodes 89. As a matter of course, the side wall wiring 95 may instead be formed as a separate member from the first source embedded electrodes 28, the second source embedded electrodes 33, the first dummy embedded electrodes 65, the second dummy embedded electrodes 68, and the terminal embedded electrodes 89.

The semiconductor device 1 includes an interlayer insulating film 99 that covers the main surface insulating film 16. The interlayer insulating film 99 covers the active surface 8, the outer surface 9, and the first to fourth connecting surfaces 10A to 10D with the main surface insulating film 16 interposed therebetween. On the active surface 8, the interlayer insulating film 99 covers the trench gate structures 20, the first trench source structures 25, the second trench source structures 30, the first trench resistor structures 42, the second trench resistor structures 43, the first dummy trench structures 61, the second dummy trench structures 62, and the trench terminal structures 86.

In the first terminal region 15A, the interlayer insulating film 99 covers the resistive film 50 and covers the plurality of trench resistor structures 41 with the resistive film 50 interposed therebetween. On the outer surface 9, the interlayer insulating film 99 covers the outer well region 91, the outer contact region 92, and the plurality of field regions 93 with the main surface insulating film 16 interposed therebetween. On the first to fourth connecting surfaces 10A to 10D, the interlayer insulating film 99 covers the side wall wiring 95.

In this embodiment, the interlayer insulating film 99 is continuous to the first to fourth side surfaces 5A to 5D. As a matter of course, a wall portion of the interlayer insulating film 99 may be formed at an interval from the peripheral edge of the outer surface 9 and expose the first semiconductor region 6 from the peripheral edge portion of the outer surface 9 instead. The interlayer insulating film 99 may include at least one among a silicon oxide film, a silicon nitride film, and silicon oxynitride film. In this embodiment, the interlayer insulating film 99 includes the silicon oxide film.

With reference to FIG. 1 to FIG. 13, the semiconductor device 1 includes the gate electrode 100 that is arranged on the interlayer insulating film 99. The gate electrode 100 has a lower resistance value than a resistance value of the gate resistor 40. Specifically, the gate electrode 100 has a lower resistance value than a resistance value of the trench resistor structures 41. Also, the gate electrode 100 has lower resistance value than the resistance value of the resistive film 50.

The gate electrode 100 is preferably thicker than the resistive film 50. The gate electrode 100 is preferably thicker than the interlayer insulating film 99. The gate electrode 100 may have a thickness of not less than 0.5 μm and not more than 10 μm. The thickness of the gate electrode 100 is preferably not less than 1 μm and not more than 5 μm.

The gate electrode 100 may include at least one type among a Ti film, a TiN film, a W film, an Al film, a Cu film, an Al alloy film, a Cu alloy film and a conductive polysilicon film. The gate electrode 100 may include at least one among a pure Cu film (a Cu film with a purity of not less than 99%), a pure Al film (an Al film with a purity of not less than 99%), an AlCu alloy film, an AlSi alloy film and an AlSiCu alloy film. In this embodiment, the gate electrode 100 has a laminated structure that includes a Ti film and an Al alloy film (in this embodiment, an AlSiCu alloy film) laminated in that order from the chip 2 side. The gate electrode 100 may also be referred to as a “gate metal.”

In this embodiment, the gate electrode 100 includes a gate pad 101, a gate wiring 102, and a gate subpad 103. The gate potential VG is to be applied from an exterior to the gate pad 101. In this embodiment, the gate pad 101 is arranged in a region along a central portion of the first connecting surface 10A in plan view.

In this embodiment, the gate pad 101 is arranged on the inner portion of the active surface 8 at an interval from the peripheral edge of the active surface 8 and is not arranged on the outer surface 9. The gate pad 101 is arranged in a region overlapping with the active region 12 and the first terminal region 15A in plan view. In the active region 12, the gate pad 101 covers a plurality of the trench gate structures 20 and a plurality of the first trench source structures 25 with the interlayer insulating film 99 interposed therebetween.

The gate pad 101 is arranged in a region overlapping with the gate resistor 40 in plan view. In this embodiment, the gate pad 101 is formed at intervals from the dummy structure 55 and the terminal dummy structure 85 in plan view. As a matter of course, the gate pad 101 may instead be arranged in a region overlapping with one of either or both of the dummy structure 55 and the terminal dummy structure 85 in plan view.

In the first terminal region 15A, the gate pad 101 penetrates through the interlayer insulating film 99 and is connected to the gate resistor 40. Specifically, the gate pad 101 penetrates through the interlayer insulating film 99 and is connected to the resistive film 50. In this embodiment, the gate pad 101 penetrates through the interlayer insulating film 99 and is connected to a central portion of the resistive film 50.

The gate pad 101 opposes one or a plurality (in this embodiment, a plurality) of the trench resistor structures 41 with the resistive film 50 interposed therebetween. In this embodiment, the gate pad 101 opposes a plurality of the first trench resistor structures 42 and a plurality of the second trench resistor structures 43 with the resistive film 50 interposed therebetween.

In this embodiment, the gate pad 101 includes a pad main body portion 104 and a drawer portion 105. The pad main body portion 104 is a portion to which the gate potential VG is to be applied from the exterior. In this embodiment, the pad main body portion 104 is arranged on a portion of the interlayer insulating film 99 covering the active region 12 and opposes the gate resistor 40 in the second direction Y in plan view.

The pad main body portion 104 covers the plurality of trench gate structures 20 and the plurality of first trench source structures 25 with the interlayer insulating film 99 interposed therebetween. In this embodiment, the pad main body portion 104 is formed to be wider than the gate resistor 40 (the trench gate structures 20) in the first direction X.

In this embodiment, the pad main body portion 104 is formed in a quadrangle shape in plan view. The pad main body portion 104 preferably has a planar area of not more than 25% of the first main surface 3. The planar area of the pad main body portion 104 is preferably not more than 10% of the first main surface 3.

The drawer portion 105 is a portion that electrically connects the pad main body portion 104 to the gate resistor 40. The drawer portion 105 is drawn out in a band shape from the pad main body portion 104 onto a portion of the interlayer insulating film 99 covering the gate resistor 40. In this embodiment, the drawer portion 105 is formed to be narrower than the pad main body portion 104 in the first direction X. Specifically, the drawer portion 105 is formed to be narrower than the gate resistor 40 (the trench gate structures 20) in the first direction X.

The drawer portion 105 is connected to the gate resistor 40 via a first resistor opening 106 formed in the interlayer insulating film 99. Specifically, the drawer portion 105 is connected to the resistive film 50 inside the first resistor opening 106. That is, the drawer portion 105 is electrically connected to the plurality of trench resistor structures 41 via the resistive film 50.

The pad main body portion 104 is thereby electrically connected to the plurality of trench resistor structures 41 and the resistive film 50 via the drawer portion 105. The drawer portion 105 opposes one or a plurality (in this embodiment, a plurality) of the trench resistor structures 41 with the resistive film 50 interposed therebetween. In this embodiment, the drawer portion 105 opposes a plurality of the first trench resistor structures 42 and the plurality of second trench resistor structures 43 with the resistive film 50 interposed therebetween.

The gate wiring 102 is selectively routed from the first terminal region 15A toward the active region 12 such as to transmit the gate potential VG, applied to the gate pad 101, to the plurality of trench gate structures 20. In this embodiment, the gate wiring 102 is arranged on the inner portion of the active surface 8 at an interval from the peripheral edge of the active surface 8 and is not arranged on the outer surface 9.

In this embodiment, the gate wiring 102 in the first terminal region 15A is arranged on the interlayer insulating film 99 at an interval from the gate pad 101. The gate wiring 102 penetrates through the interlayer insulating film 99 at different positions from the gate pad 101 and is electrically connected to the gate resistor 40. Specifically, the gate wiring 102 penetrates through the interlayer insulating film 99 and is connected to the resistive film 50. Thereby, the gate wiring 102 is electrically connected to the gate pad 101 via the plurality of trench resistor structures 41 and the resistive film 50.

The gate wiring 102 opposes one or a plurality (in this embodiment, a plurality) of the trench resistor structures 41 with the resistive film 50 interposed therebetween. In this embodiment, the gate wiring 102 opposes a plurality of the first trench resistor structures 42 and a plurality of the second trench resistor structures 43 with the resistive film 50 interposed therebetween. In the active region 12, the gate wiring 102 extends in a line shape such as to intersect (specifically, be orthogonal to) the plurality of trench gate structures 20, penetrates through the interlayer insulating film 99, and is electrically connected to the plurality of trench gate structures 20.

In this embodiment, the gate wiring 102 includes a first gate wiring 102A, a second gate wiring 102B, and a third gate wiring 102C. The first gate wiring 102A is arranged in a region at the third connecting surface 10C side with respect to the gate pad 101 and extends in the line shape along the first connecting surface 10A and the third connecting surface 10C. The first gate wiring 102A is electrically connected to the gate pad 101 in the first terminal region 15A via the gate resistor 40 and is electrically connected to the plurality of trench gate structures 20 in the active region 12.

Specifically, in the first terminal region 15A, the first gate wiring 102A extends in the line shape in the first direction X such as to cover the gate resistor 40 and the dummy structure 55 (first dummy structure 56). The first gate wiring 102A is arranged on a portion of the interlayer insulating film 99 covering the gate resistor 40 at an interval from the gate pad 101.

The first gate wiring 102A is connected to the gate resistor 40 via a second resistor opening 107 that is formed in the interlayer insulating film 99 at an interval from the first resistor opening 106. The first gate wiring 102A is connected to a region at one end portion side (third connecting surface 10C side) of the gate resistor 40 at an interval from the connection position of the gate pad 101.

The first gate wiring 102A is connected to the resistive film 50 inside the second resistor opening 107. That is, the first gate wiring 102A is electrically connected to the plurality of trench resistor structures 41 via the resistive film 50. The first gate wiring 102A opposes one or a plurality (in this embodiment, a plurality) of the trench resistor structures 41 with the resistive film 50 interposed therebetween. In this embodiment, the first gate wiring 102A a plurality of the first trench resistor structures 42 and a plurality of the second trench resistor structures 43 with the resistive film 50 interposed therebetween.

In the active region 12, the first gate wiring 102A extends in the line shape in the second direction Y such as to intersect (specifically, be orthogonal to) the plurality of trench gate structures 20. The first gate wiring 102A is electrically connected to the plurality of gate connection electrode films 39 via a plurality of gate openings 108 formed in the interlayer insulating film 99. The first gate wiring 102A is thereby electrically connected to the plurality of trench gate structures 20 via the plurality of gate connection electrode films 39.

A connection height position of the first gate wiring 102A with respect to the gate connection electrode films 39 may be substantially equal to a connection height position of the first gate wiring 102A with respect to the resistive film 50. As a matter of course, the connection height position of the first gate wiring 102A with respect to the gate connection electrode films 39 may be positioned further to the active surface 8 side than a connection height position of the first gate wiring 102A with respect to the resistive film 50. Also, the connection height position of the first gate wiring 102A with respect to the gate connection electrode films 39 may be positioned further upward than the connection height position of the first gate wiring 102A with respect to the resistive film 50.

The second gate wiring 102B is arranged in a region at the fourth connecting surface 10D side with respect to the gate pad 101 and extends in the line shape along the first connecting surface 10A and the fourth connecting surface 10D. The second gate wiring 102B is electrically connected to the gate pad 101 in the first terminal region 15A via the gate resistor 40 and is electrically connected to the plurality of trench gate structures 20 in the active region 12. In this embodiment, the second gate wiring 102B is electrically connected to the plurality of trench gate structures 20 that are electrically connected to the first gate wiring 102A.

Specifically, in the first terminal region 15A, the second gate wiring 102B extends in the line shape in the first direction X such as to cover the gate resistor 40 and the dummy structure 55 (second dummy structure 57). The second gate wiring 102B is arranged on a portion of the interlayer insulating film 99 covering the gate resistor 40 at an interval from the gate pad 101.

The second gate wiring 102B is connected to the gate resistor 40 via a third resistor opening 109 that is formed in the interlayer insulating film 99 at intervals from the first resistor opening 106 and the second resistor opening 107. The second gate wiring 102B is connected to a region at another end portion side (fourth connecting surface 10D side) of the gate resistor 40 at an interval from the connection position of the gate pad 101.

The second gate wiring 102B is connected to the resistive film 50 inside the third resistor opening 109. That is, the second gate wiring 102B is electrically connected to the plurality of trench resistor structures 41 via the resistive film 50. The second gate wiring 102B opposes one or a plurality (in this embodiment, a plurality) of the trench resistor structures 41 with the resistive film 50 interposed therebetween. In this embodiment, the second gate wiring 102B opposes a plurality of the first trench resistor structures 42 and a plurality of the second trench resistor structures 43 with the resistive film 50 interposed therebetween.

In the active region 12, the second gate wiring 102B extends in the line shape in the second direction Y such as to intersect (specifically, be orthogonal to) the plurality of trench gate structures 20. The second gate wiring 102B is electrically connected to the plurality of gate connection electrode films 39 via a plurality of gate openings 108 formed in the interlayer insulating film 99. The second gate wiring 102B is thereby electrically connected to the plurality of trench gate structures 20 via the plurality of gate connection electrode films 39.

A connection height position of the second gate wiring 102B with respect to the gate connection electrode films 39 may be substantially equal to a connection height position of the second gate wiring 102B with respect to the resistive film 50. As a matter of course, the connection height position of the second gate wiring 102B with respect to the gate connection electrode films 39 may be positioned further to the active surface 8 side than the connection height position of the second gate wiring 102B with respect to the resistive film 50. Also, the connection height position of the second gate wiring 102B with respect to the gate connection electrode films 39 may be positioned further upward than the connection height position of the second gate wiring 102B with respect to the resistive film 50.

The third gate wiring 102C is arranged in a region at the second connecting surface 10B side with respect to the gate pad 101 and extends in the line shape along the second direction Y in a region between the gate pad 101 and the second connecting surface 10B. In this embodiment, the third gate wiring 102C is electrically connected to the first gate wiring 102A and the second gate wiring 102B in the first terminal region 15A and is electrically connected to the plurality of trench gate structures 20 in the active region 12.

That is, the third gate wiring 102C is electrically connected to the gate resistor 40 via the first gate wiring 102A and is electrically connected to the gate resistor 40 via the second gate wiring 102B. A portion of the first gate wiring 102A connected to the gate resistor 40 and a portion of the second gate wiring 102B connected to the gate resistor 40 may be regarded to be portions of the third gate wiring 102C. In this embodiment, the third gate wiring 102C is electrically connected to the plurality of trench gate structures 20 that are electrically connected to the first gate wiring 102A and the second gate wiring 102B in the active region 12.

The third gate wiring 102C includes a line portion 110, a first branch portion 111, and a second branch portion 112. The line portion 110 extends in the line shape along the second direction Y in the region between the gate pad 101 and the second connecting surface 10B. The line portion 110 has a first end portion at the gate pad 101 side and a second end portion at the second connecting surface 10B side. The first end portion is formed at an interval to the second connecting surface 10B side from the gate pad 101. The second end portion is formed at an interval to the gate pad 101 side from the second connecting surface 10B.

The line portion 110 is electrically connected to the plurality of trench gate structures 20 via a plurality of gate openings 108 formed in the interlayer insulating film 99. A plurality of gate connection electrode films 39 that cover inner portions of the plurality of trench gate structures 20 may be formed. In this case, the line portion 110 is electrically connected to the plurality of trench gate structures 20 via the plurality of gate connection electrode films 39.

In this case, a connection height position of the line portion 110 with respect to the gate connection electrode films 39 may be substantially equal to the connection height position of the first gate wiring 102A (second gate wiring 102B) with respect to the resistive film 50. As a matter of course, the connection height position of the line portion 110 with respect to the gate connection electrode films 39 may be positioned further to the active surface 8 side than the connection height position of the second gate wiring 102B with respect to the resistive film 50. Also, the connection height position of the line portion 110 with respect to the gate connection electrode films 39 may be positioned further upward than the connection height position of the second gate wiring 102B with respect to the resistive film 50.

The first branch portion 111 connects the line portion 110 and the first gate wiring 102A. The first branch portion 111 is drawn out to one side (the third connecting surface 10C side) from the first end portion of the line portion 110 and extends in a band shape along the gate pad 101. The first branch portion 111 is connected to a portion of the first gate wiring 102A covering the dummy structure 55 (first dummy structure 56).

As a matter of course, the first branch portion 111 may be connected to a portion of the first gate wiring 102A covering the gate resistor 40. At its portion extending in the second direction Y, the first branch portion 111 is electrically connected to the plurality of trench gate structures 20 via a plurality of gate openings 108 formed in the interlayer insulating film 99. The first branch portion 111 may be electrically connected to the plurality of trench gate structures 20 via a plurality of gate connection electrode films 39.

The second branch portion 112 connects the line portion 110 and the second gate wiring 102B. The second branch portion 112 is drawn out to the other side (the fourth connecting surface 10D side) from the first end portion of the line portion 110 and extends in a band shape along the peripheral edge of the gate pad 101. The second branch portion 112 opposes the first branch portion 111 in the first direction X with the gate pad 101 interposed therebetween. The second branch portion 112 is connected to a portion of the second gate wiring 102B covering the dummy structure 55 (second dummy structure 57).

As a matter of course, the second branch portion 112 may be connected to a portion of the second gate wiring 102B covering the gate resistor 40. At its portion extending in the second direction Y, the second branch portion 112 is electrically connected to the plurality of trench gate structures 20 via a plurality of gate openings 108 formed in the interlayer insulating film 99. The second branch portion 112 may be electrically connected to the plurality of trench gate structures 20 via a plurality of gate connection electrode films 39.

The gate subpad 103 is arranged on the interlayer insulating film 99 such as to be electrically connected to the gate pad 101 via the gate resistor 40. In this embodiment, the gate subpad 103 is arranged at an interval to the third connecting surface 10C side from the gate pad 101 and opposes the gate pad 101 in the first direction X.

The gate subpad 103 is arranged at an interval from the first terminal region 15A on the portion of the interlayer insulating film 99 covering the active region 12 in plan view. The gate subpad 103 opposes the dummy structure 55 (first dummy structure 56) in the second direction Y in plan view.

The gate subpad 103 is formed to be narrower than the gate pad 101 and formed to be wider than the gate wiring 102. The gate subpad 103 opposes a plurality of the trench gate structures 20 and a plurality of the first trench source structures 25 with the interlayer insulating film 99 interposed therebetween. In this embodiment, the gate subpad 103 is electrically connected to the gate wiring 102. In this embodiment, the gate subpad 103 is connected to the third gate wiring 102C (first branch portion 111). The gate subpad 103 suffices to be connected to at least one among the first to third gate wirings 102A to 102C and an arrangement location of the gate subpad 103 is arbitrary.

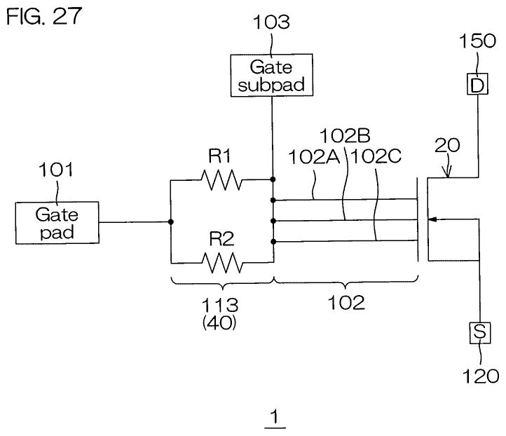

Hereinafter, a connection configuration of the gate electrode 100 and the gate resistor 40 shall be described with reference to FIG. 27 in addition to FIG. 13. FIG. 27 is an electric circuit diagram showing the connection configuration of the gate electrode 100 and the gate resistor 40. In FIG. 27, the trench gate structures 20 are indicated by a circuit symbol that represents a MISFET.

With reference to FIG. 13 and FIG. 27, the gate wiring 102 is electrically connected to the gate pad 101 via the gate resistor 40. In this embodiment, the gate resistor 40 includes a resistor parallel circuit 113 constituted of a first resistor portion R1 and a second resistor portion R2. The first resistor portion R1 is formed by a portion of the gate resistor 40 positioned between a connection portion of the gate pad 101 and a connection portion of the first gate wiring 102A. On the other hand, the second resistor portion R2 is formed by a portion of the gate resistor 40 positioned between the connection portion of the gate pad 101 and a connection portion of the second gate wiring 102B.

That is, the first gate wiring 102A is electrically connected to the gate pad 101 via the first resistor portion R1 and the second gate wiring 102B is electrically connected to the gate pad 101 via the second resistor portion R2. A resistance value of the first resistor portion R1 is adjusted by increasing/decreasing a distance between the connection portion of the gate pad 101 and the connection portion of the first gate wiring 102A.

A resistance value of the second resistor portion R2 is adjusted by increasing/decreasing a distance between the connection portion of the gate pad 101 and the connection portion of the second gate wiring 102B. The resistance value of the second resistor portion R2 may be not less than the resistance value of the first resistor portion R1 or may be less than the resistance value of the first resistor portion R1 or may be substantially equal to the resistance value of the first resistor portion R1.

In this embodiment, the second gate wiring 102B is electrically connected to the trench gate structures 20 that are electrically connected to the first gate wiring 102A. Therefore, the second resistor portion R2 is connected in parallel to the first resistor portion R1 and the resistor parallel circuit 113 is thereby formed. In this embodiment, the third gate wiring 102C is electrically connected to the trench gate structures 20 that are electrically connected to the first gate wiring 102A and the second gate wiring 102B.

The single gate wiring 102 that includes the first to third gate wirings 102A to 102C is thus electrically connected to the resistor parallel circuit 113 and the trench gate structures 20. The resistance value of the gate resistor 40 (that is, a resistance value between the gate pad 101 and the gate wiring 102) is measured indirectly by measuring a resistance value between the gate pad 101 and the gate subpad 103.

The gate resistor 40 delays a switching speed during a switching operation and suppresses a surge current. That is, the gate resistor 40 suppresses noise due to the surge current. Since the gate resistor 40 is formed in the first main surface 3 (active surface 8), it is not externally connected to the semiconductor device 1. Thus, by the gate resistor 40 being incorporated in the first main surface 3, the number of components mounted on a circuit substrate is reduced.

Since the gate resistor 40 includes the trench resistor structures 41 that are incorporated in the thickness direction of the chip 2, an occupying area of the gate resistor 40 with respect to the first main surface 3 is restricted. Reduction of an area of the active region 12 due to introduction of the gate resistor 40 is thus suppressed. In particular, the gate resistor 40 is arranged in the terminal region 15 and therefore the reduction of the arear of the active region 12 is suppressed appropriately.

In this embodiment, the gate resistor 40 has the arrangement that is similar to the arrangement at the active region 12 side. Therefore, electrical influence of the gate resistor 40 on the active region 12 is suppressed and electrical influence of the active region 12 on the gate resistor 40 is suppressed. Thereby, fluctuations in electrical characteristics at the active region 12 side are suppressed and fluctuations in electrical characteristics at the gate resistor 40 side are suppressed.

The gate resistor 40 does not necessarily have to have the resistor parallel circuit 113 that includes the first resistor portion R1 and the second resistor portion R2. The gate resistor 40 may thus consist of just the first resistor portion R1 or the second resistor portion R2. Such a configuration is attained by changing the connection configuration of the gate wiring 102 with respect to the gate resistor 40.

For example, if the gate resistor 40 is to consist of just the first resistor portion R1, it suffices to electrically cut off the gate wiring 102 (second gate wiring 102B) from the gate resistor 40. Also, if the gate resistor 40 is to consist of just the second resistor portion R2, it suffices to electrically cut off the gate wiring 102 (first gate wiring 102A) from the gate resistor 40. The gate wiring 102 does not have to include all of the first to third gate wirings 102A to 102C at the same time and suffices to include at least one among the first to third gate wirings 102A to 102C.

With reference to FIG. 1 to FIG. 13, the semiconductor device 1 includes a source electrode 120 that is arranged on the interlayer insulating film 99 at intervals from the gate electrode 100. The source electrode 120 has a lower resistance value than the resistance value of the gate resistor 40. The source electrode 120 is preferably thicker than the resistive film 50. The source electrode 120 is preferably thicker than the interlayer insulating film 99. The source electrode 120 may have a thickness of not less than 0.5 μm and not more than 10 μm. The thickness of the source electrode 120 is preferably not less than 1 μm and not more than 5 μm. The thickness of the source electrode 120 is preferably substantially equal to the thickness of the gate electrode 100.

The source electrode 120 may include at least one type among a Ti film, a TiN film, a W film, an Al film, a Cu film, an Al alloy film, a Cu alloy film and a conductive polysilicon film. The source electrode 120 may include at least one among a pure Cu film (a Cu film with a purity of not less than 99%), a pure Al film (an Al film with a purity of not less than 99%), an AlCu alloy film, an AlSi alloy film and an AlSiCu alloy film. In this embodiment, the source electrode 120 has a laminated structure that includes a Ti film and an Al alloy film (in this embodiment, an AlSiCu alloy film) laminated in that order from the chip 2 side. The source electrode 120 may also be referred to as a “source metal.”

In this embodiment, the source electrode 120 includes a first source pad 121, a second source pad 122, a first source subpad 123, a second source subpad 124, and a source wiring 125. The source potential VS for a main source is to be applied from the exterior to the first source pad 121. The first source pad 121 is arranged in a region between the first gate wiring 102A and the third gate wiring 102C on the portion of the interlayer insulating film 99 covering the active region 12.

In this embodiment, the first source pad 121 covers the active region 12 at intervals from the peripheral edge region 14 and the terminal region 15 in plan view. As a matter of course, the first source pad 121 may instead be arranged in a region overlapping with one of either or both of the peripheral edge region 14 and the terminal region 15 in plan view.

The first source pad 121 opposes the plurality of trench gate structures 20 with the interlayer insulating film 99 interposed therebetween. The first source pad 121 is electrically connected to the plurality of first trench source structures 25, the source region 18, and the plurality of first contact regions 38 via a plurality of source openings 126 formed in the interlayer insulating film 99. The first source pad 121 preferably has a larger planar area than a planar area of the gate pad 101.

The source potential VS for the main source is to be applied from the exterior to the second source pad 122. The second source pad 122 is arranged in a region between the second gate wiring 102B and the third gate wiring 102C on the portion of the interlayer insulating film 99 covering the active region 12.

In this embodiment, the second source pad 122 covers the active region 12 at intervals from the peripheral edge region 14 and the terminal region 15 in plan view. As a matter of course, the second source pad 122 may instead be arranged in a region overlapping with one of either or both of the peripheral edge region 14 and the terminal region 15 in plan view. The second source pad 122 opposes the plurality of trench gate structures 20 with the interlayer insulating film 99 interposed therebetween.

The second source pad 122 is electrically connected to the plurality of first trench source structures 25, the source region 18, and the plurality of first contact regions 38 via a plurality of source openings 126 formed in the interlayer insulating film 99. The second source pad 122 preferably has a larger planar area than the planar area of the gate pad 101. If the third gate wiring 102C is not formed, the second source pad 122 may be formed integral to the first source pad 121.

The source potential VS for a source sense is to be applied from the exterior to the first source subpad 123. In this embodiment, the first source subpad 123 is arranged in a region between the gate pad 101 and the first gate wiring 102A (third connecting surface 10C) on the portion of the interlayer insulating film 99 covering the active region 12.

The first source subpad 123 has a planar area less than the planar area of the first source pad 121 and is formed integral to the first source pad 121. The planar area of the first source subpad 123 is preferably greater than a planar area of the gate subpad 103. The planar area of the first source subpad 123 is particularly preferably greater than the planar area of the gate pad 101.

The first source subpad 123 covers the active region 12 at intervals from the peripheral edge region 14 and the terminal region 15 in plan view. As a matter of course, the first source subpad 123 may instead be arranged in a region overlapping with one of either or both of the peripheral edge region 14 and the terminal region 15 in plan view.

The first source subpad 123 opposes the plurality of trench gate structures 20 with the interlayer insulating film 99 interposed therebetween. The first source subpad 123 is electrically connected to the plurality of first trench source structures 25, the source region 18, and the plurality of first contact regions 38 via a plurality of source openings 126 formed in the interlayer insulating film 99.

The source potential VS for the source sense is to be applied from the exterior to the second source subpad 124. In this embodiment, the second source subpad 124 is arranged in a region between the gate pad 101 and the second gate wiring 102B (fourth connecting surface 10D) on the portion of the interlayer insulating film 99 covering the active region 12.

In this embodiment, the second source subpad 124 has a planar area less than the planar area of the second source pad 122 and is formed integral to the second source pad 122. The planar area of the second source subpad 124 is preferably greater than the planar area of the gate subpad 103. The planar area of the second source subpad 124 is particularly preferably greater than the planar area of the gate pad 101.

The second source subpad 124 covers the active region 12 at intervals from the peripheral edge region 14 and the terminal region 15 in plan view. As a matter of course, the second source subpad 124 may instead be arranged in a region overlapping with one of either or both of the peripheral edge region 14 and the terminal region 15 in plan view. The second source subpad 124 opposes the plurality of trench gate structures 20 with the interlayer insulating film 99 interposed therebetween. The second source subpad 124 is electrically connected to the plurality of first trench source structures 25, the source region 18, and the plurality of first contact regions 38 via a plurality of source openings 126 formed in the interlayer insulating film 99.

A total planar area of the first source pad 121, the second source pad 122, the first source subpad 123, and the second source subpad 124 is preferably not less than 50% and not more than 90% of the planar area of the first main surface 3. The total planar area is particularly preferably not less than 75% of the planar area of the first main surface 3.

The source wiring 125 transmits the source potential VS applied to the first source pad 121 and the second source pad 122 to other regions. In this embodiment, the source wiring 125 is drawn out from the first source pad 121 and the second source pad 122 such as to be positioned further to the outer region 13 side than the gate wiring 102.

The source wiring 125 is drawn out to the outer surface 9 side from the active surface 8 side and through the first to fourth connecting surfaces 10A to 10D. The source wiring 125 is formed in a band shape extending along the first to fourth connecting surfaces 10A to 10D. That is, the source wiring 125 opposes the side wall wiring 95 with the interlayer insulating film 99 interposed therebetween. In this embodiment, the source wiring 125 is formed in an annular shape (specifically, a quadrangle annular shape) extending along the first to fourth connecting surfaces 10A to 10D and surrounds the gate wiring 102.

The source wiring 125 is electrically connected to the side wall wiring 95 and the outer contact region 92 via an outer opening 127 formed in the interlayer insulating film 99. The outer opening 127 is formed in a band shape or an annular shape extending along the side wall wiring 95 and the outer contact region 92. The source potential VS applied to the source wiring 125 is transmitted via the side wall wiring 95 to the first trench source structures 25, the second trench source structures 30, the first dummy trench structures 61, the second dummy trench structures 62, and the trench terminal structures 86.

The semiconductor device 1 includes an upper insulating film 130 that selectively covers the gate electrode 100, the source electrode 120, and the interlayer insulating film 99 on the first main surface 3. The upper insulating film 130 includes a gate pad opening 131 exposing an inner portion of the gate pad 101 and a gate subpad opening 132 exposing an inner portion of the gate subpad 103.

The upper insulating film 130 covers a peripheral edge portion of the gate pad 101, a peripheral edge portion of the gate subpad 103, and a whole region of the gate wiring 102. The gate pad opening 131 is formed in a quadrangle shape in plan view. The gate subpad opening 132 is formed in a quadrangle shape in plan view. The gate subpad opening 132 has a smaller planar area than a planar area of the gate pad opening 131.

The upper insulating film 130 includes a first source pad opening 133 exposing an inner portion of the first source pad 121, a second source pad opening 134 exposing an inner portion of the second source pad 122, a first source subpad opening 135 exposing an inner portion of the first source subpad 123, and a second source subpad opening 136 exposing an inner portion of the second source subpad 124. The upper insulating film 130 covers a peripheral edge portion of the first source pad 121, a peripheral edge portion of the second source pad 122, a peripheral edge portion of the first source subpad 123, a peripheral edge portion of the second source subpad 124, and a whole region of the source wiring 125.

The first source pad opening 133 is formed in a quadrangle shape in plan view. The first source pad opening 133 has a planar area greater than the planar area of the gate subpad opening 132. The planar area of the first source pad opening 133 is preferably greater than the planar area of the gate pad opening 131.

The second source pad opening 134 is formed in a quadrangle shape in plan view. The second source pad opening 134 has a planar area greater than the planar area of the gate subpad opening 132. The planar area of the second source pad opening 134 is preferably greater than the planar area of the gate pad opening 131. The planar area of the second source pad opening 134 is preferably substantially equal to the planar area of the first source pad opening 133.

The first source subpad opening 135 is formed in a quadrangle shape in plan view. The first source subpad opening 135 has a planar area smaller than the planar area of the first source pad opening 133. The planar area of the first source subpad opening 135 is preferably greater than the planar area of the gate subpad opening 132. In this embodiment, the planar area of the first source subpad opening 135 is greater than the planar area of the gate pad opening 131. As a matter of course, the planar area of the first source subpad opening 135 may be less than the planar area of the gate pad opening 131.

The second source subpad opening 136 is formed in a quadrangle shape in plan view. The second source subpad opening 136 has a planar area smaller than the planar area of the second source pad opening 134. The planar area of the second source subpad opening 136 is preferably greater than the planar area of the gate subpad opening 132.

In this embodiment, the planar area of the second source subpad opening 136 is greater than the planar area of the gate pad opening 131. As a matter of course, the planar area of the second source subpad opening 136 may be less than the planar area of the gate pad opening 131. The planar area of the second source subpad opening 136 is preferably substantially equal to the planar area of the first source subpad opening 135.

The upper insulating film 130 is formed at an interval inward from a peripheral edge of the chip 2 (the first to fourth side surfaces 5A to 5D) and, with the peripheral edge of the chip 2, demarcates a dicing street 137. The dicing street 137 is formed in a band shape extending along the peripheral edge of the chip 2 in plan view. In this embodiment, the dicing street 137 is formed in an annular shape (specifically, a quadrangle annular shape) surrounding the active surface 8 in plan view. In this embodiment, the dicing street 137 exposes the interlayer insulating film 99.

As a matter of course if the main surface insulating film 16 and the interlayer insulating film 99 expose the outer surface 9, the dicing street 137 may also expose the outer surface 9. The dicing street 137 may have a width of not less than 1 μm and not more than 200 μm. The width of the dicing street 137 is a width in a direction orthogonal to an extension direction of the dicing street 137. The width of the dicing street 137 is preferably not less than 5 μm and not more than 50 μm.

The upper insulating film 130 preferably has a thickness exceeding the thickness of the gate electrode 100 and the thickness of the source electrode 120. The thickness of the upper insulating film 130 is preferably less than the thickness of the chip 2. The thickness of the upper insulating film 130 may be not less than 3 μm and not more than 35 μm. The thickness of the upper insulating film 130 is preferably not more than 25 μm.

In this embodiment, the upper insulating film 130 has a laminated structure including an inorganic insulating film 140 and an organic insulating film 141 that are laminated in that order from the chip 2 side. The upper insulating film 130 suffices to include at least one of the inorganic insulating film 140 and the organic insulating film 141 and does not necessarily have to include the inorganic insulating film 140 and the organic insulating film 141 at the same time.

The inorganic insulating film 140 selectively covers the gate electrode 100, the source electrode 120, and the interlayer insulating film 99 and demarcates a portion of the gate pad opening 131, a portion of the gate subpad opening 132, a portion of the first source pad opening 133, a portion of the second source pad opening 134, a portion of the first source subpad opening 135, a portion of the second source subpad opening 136, and a portion of the dicing street 137.

The inorganic insulating film 140 may include at least one among a silicon oxide film, a silicon nitride film, and silicon oxynitride film. The inorganic insulating film 140 preferably contains an insulating material different from the interlayer insulating film 99. The inorganic insulating film 140 preferably includes the silicon nitride film. The inorganic insulating film 140 preferably has a thickness less than a thickness of the interlayer insulating film 99. The thickness of the inorganic insulating film 140 may be not less than 0.1 μm and not more than 5 μm.

The organic insulating film 141 selectively covers the inorganic insulating film 140 and demarcates a portion of the gate pad opening 131, a portion of the gate subpad opening 132, a portion of the first source pad opening 133, a portion of the second source pad opening 134, a portion of the first source subpad opening 135, a portion of the second source subpad opening 136, and a portion of the dicing street 137.

The organic insulating film 141 may expose the inorganic insulating film 140 at a wall surface of the gate pad opening 131. The organic insulating film 141 may expose the inorganic insulating film 140 at a wall surface of the gate subpad opening 132. The organic insulating film 141 may expose the inorganic insulating film 140 at a wall surface of the first source pad opening 133. The organic insulating film 141 may expose the inorganic insulating film 140 at a wall surface of the second source pad opening 134.

The organic insulating film 141 may expose the inorganic insulating film 140 at a wall surface of the first source subpad opening 135. The organic insulating film 141 may expose the inorganic insulating film 140 at a wall surface of the second source subpad opening 136. The organic insulating film 141 may expose the inorganic insulating film 140 at a wall surface of the dicing street 137. As a matter of course, the organic insulating film 141 may cover a whole region of the inorganic insulating film 140 such as not to expose the inorganic insulating film 140.

The organic insulating film 141 preferably consists of a resin film other than a thermosetting resin. The organic insulating film 141 may consist of a translucent resin or a transparent resin. The organic insulating film 141 may consist of a photosensitive resin of a negative type or a positive type. The organic insulating film 141 preferably consists of a polyimide film, a polyamide film or a polybenzoxazole film. In this embodiment, the organic insulating film 141 includes the polybenzoxazole film.

The organic insulating film 141 preferably has a thickness exceeding the thickness of the inorganic insulating film 140. The thickness of the organic insulating film 141 preferably exceeds the thickness of the interlayer insulating film 99. The thickness of the organic insulating film 141 particularly preferably exceeds the thickness of the gate electrode 100 and the thickness of the source electrode 120. The thickness of the organic insulating film 141 may be not less than 3 μm and not more than 30 μm. The thickness of the organic insulating film 141 is preferably not more than 20 μm.

The semiconductor device 1 includes a drain electrode 150 that covers the second main surface 4. The drain electrode 150 forms an ohmic contact with the second semiconductor region 7 exposed from the second main surface 4. The drain electrode 150 may cover a whole region of the second main surface 4 such as to be continuous with the peripheral edge of the chip 2 (the first to fourth side surfaces 5A to 5D). A breakdown voltage that can be applied between the source electrode 120 and the drain electrode 150 (between the first main surface 3 and the second main surface 4) may be not less than 500 V and not more than 3000 V.

As described above, the semiconductor device 1 includes the chip 2, the gate resistor 40, the gate pad 101, and the gate wiring 102. The chip 2 has the first main surface 3. The gate resistor 40 includes the trench resistor structures 41 formed in the first main surface 3. The gate pad 101 has a resistance value lower than the trench resistor structures 41 and is arranged on the first main surface 3 such as to be electrically connected to the trench resistor structures 41. The gate wiring 102 has a resistance value lower than the trench resistor structures 41 and is arranged on the first main surface 3 such as to be electrically connected to the gate pad 101 via the trench resistor structures 41.

According to this structure, since the trench resistor structures 41 are incorporated inside the chip 2 in a region between the gate pad 101 and the gate wiring 102, the occupying area of the gate resistor 40 with respect to the first main surface 3 can be restricted. The resistance value of the gate resistor 40 is adjusted by adjusting the depth and the length of the trench resistor structures 41. Therefore, increase in the occupying area of the gate resistor 40 with respect to the first main surface 3 can be suppressed. The semiconductor device 1 having a novel layout that contributes to size reduction in the arrangement including the gate resistor 40 can thus be provided.

In such a structure, the gate pad 101 preferably has a portion that is positioned directly above the trench resistor structures 41. According to this structure, since the gate resistor 40 is arranged in a region directly below the gate pad 101, the increase in the occupying area of the gate resistor 40 with respect to the first main surface 3 can be suppressed. Also, the gate wiring 102 preferably has a portion that is positioned directly above the trench resistor structures 41. According to this structure, since the gate resistor 40 is arranged in a region directly below the gate wiring 102, the increase in the occupying area of the gate resistor 40 with respect to the first main surface 3 can be suppressed.

The trench resistor structures 41 preferably do not contribute to the control of the channels. According to this structure, malfunction due to the trench resistor structures 41 can be suppressed appropriately. The gate resistor 40 preferably includes the resistive film 50 that covers the trench resistor structures 41. According to this structure, the resistance value of the gate resistor 40 can be adjusted using both the trench resistor structures 41 and the resistive film 50.

In this case, the gate pad 101 is preferably electrically connected to the trench resistor structures 41 via the resistive film 50. According to this structure, the gate pad 101 can be electrically connected to the trench resistor structures 41 appropriately by the resistive film 50. The gate pad 101 preferably has a portion opposing the trench resistor structures 41 with the resistive film 50 interposed therebetween.

The gate wiring 102 is preferably electrically connected to the trench resistor structures 41 via the resistive film 50. According to this structure, the gate wiring 102 can be electrically connected to the trench resistor structures 41 appropriately by the resistive film 50. In this case, the gate wiring 102 preferably has a portion opposing the trench resistor structures 41 with the resistive film 50 interposed therebetween.

The resistive film 50 may have a portion covering the first main surface 3 and a portion covering the trench resistor structures 41. According to this structure, the resistance value of the resistive film 50 can be adjusted using a region on the first main surface 3 and a region on the trench resistor structures 41. Also, influence due to an alignment error of the gate pad 101 with respect to the resistive film 50 and influence due to an alignment error of the gate wiring 102 can be reduced. In this case, the gate pad 101 may have a portion opposing the first main surface 3 with the resistive film 50 interposed therebetween. Also, the gate wiring 102 may have a portion opposing the first main surface 3 with the resistive film 50 interposed therebetween.

The semiconductor device 1 may include the interlayer insulating film 99 that covers the resistive film 50. In this case, the gate pad 101 preferably penetrates through the interlayer insulating film 99 and is connected to the resistive film 50. Also, the gate wiring 102 preferably penetrates through the interlayer insulating film 99 and is connected to the resistive film 50.

Preferably, the plurality of trench resistor structures 41 are formed in the first main surface 3. According to this structure, the resistance value of the gate resistor 40 can be adjusted using the plurality of trench resistor structures 41. The plurality of trench resistor structures 41 preferably include the first trench resistor structures 42 and the second trench resistor structures 43 that are deeper than the first trench resistor structures 42.

According to this structure, the resistance value of the gate resistor 40 can be adjusted using the first trench resistor structures 42 and the second trench resistor structures 43 that have mutually different depths. In particular, by the second trench resistor structures 43, making of the gate resistor 40 high in resistance in the thickness direction of the chip 2 can be achieved. Therefore, for example, in a case where the resistive film 50 is to be provided, reduction of film thickness of the resistive film 50 can be achieved as well.

The semiconductor device 1 preferably includes the active region 12, the outer region 13, and the terminal region 15. The active region 12 is provided in an inner portion of the first main surface 3. The outer region 13 is provided in a peripheral edge portion of the first main surface 3. The terminal region 15 is provided between the active region 12 and the outer region 13. In such a layout, the trench resistor structures 41 are preferably formed in the terminal region 15. According to this layout, reduction of the area of the active region 12 in accompaniment with the introduction of the gate resistor 40 can be suppressed appropriately.

In this case, the gate pad 101 is preferably electrically connected to the trench resistor structures 41 in the terminal region 15. Also, the gate wiring 102 is preferably electrically connected to the gate pad 101 via the trench resistor structures 41 in the terminal region 15.

The semiconductor device 1 preferably includes the trench gate structures 20 that are formed in the first main surface 3 in the active region 12. In this case, the gate wiring 102 is preferably electrically connected to the trench gate structures 20 in the active region 12. According to this structure, the gate resistor 40 (the trench resistor structures 41) can be interposed electrically between the gate pad 101 and the trench gate structures 20.

The semiconductor device 1 may include the first trench source structures 25 that are formed in the first main surface 3 such as to be adjacent to the trench gate structures 20 in the active region 12 and to which the source potential VS is to be applied. In this case, the first trench source structures 25 may be formed to be deeper than the trench gate structures 20. In such a structure, the plurality of trench resistor structures 41 preferably include the first trench resistor structures 42 that are formed comparatively shallow in correspondence to the trench gate structures 20 and the second trench resistor structures 43 that are formed comparatively deep in correspondence to the first trench source structures 25.

According to this structure, since corresponding structures are formed in the active region 12 and the terminal region 15, respectively, bias of electric field between the active region 12 and the terminal region 15 can be suppressed. Therefore, the electrical influence of the gate resistor 40 on the active region 12 is suppressed and the electrical influence of the active region 12 on the gate resistor 40 is suppressed. In this case, the first trench resistor structures 42 preferably have the depth substantially equal to that of the trench gate structures 20. Also, the second trench resistor structures 43 have the depth substantially equal to that of the first trench source structures 25.

The semiconductor device 1 preferably further includes the dummy trench structures 60 that are formed in the first main surface 3 such as to be adjacent to the trench resistor structures 41 in the terminal region 15. The dummy trench structures 60 preferably do not contribute to the control of the channels. According to this structure, malfunction due to the trench resistor structures 41 can be suppressed appropriately.

The source potential VS is preferably applied to the dummy trench structures 60. According to this structure, an electric field in a region in a vicinity of the trench resistor structures 41 can be relaxed by the dummy trench structures 60. In this case, the plurality of dummy trench structures 60 are preferably formed in the first main surface 3. According to this structure, the electric field in the vicinity of the trench resistor structures 41 can be relaxed in the terminal region 15 by the plurality of dummy trench structures 60.

The plurality of dummy trench structures 60 preferably include the first dummy trench structures 61 and the second dummy trench structures 62 that are deeper than the first dummy trench structures 61. According to this structure, the electric field in the vicinity of the trench resistor structures 41 can be relaxed by the first dummy trench structures 61 and the second dummy trench structures 62.

Such a structure is particularly effective when the first trench source structures 25 that are deeper than the trench gate structures 20 are formed in the active region 12. Also, such a structure is particularly effective when the second trench resistor structures 43 that are deeper than the first trench resistor structures 42 are formed in the terminal region 15.

The semiconductor device 1 may include the active mesa 11 that is demarcated in the first main surface 3 by the active surface 8 formed at the inner portion of the first main surface 3, the outer surface 9 formed at the peripheral edge portion of the first main surface 3 such as to be recessed in the thickness direction of the chip 2 from the active surface 8, and the first to fourth connecting surfaces 10A to 10D connecting the active surface 8 and the outer surface 9. In this case, the active region 12 is provided in the active surface 8, the outer region 13 is provided in the outer surface 9, and the terminal region 15 is provided in the active surface 8.

The semiconductor device 1 preferably includes the first semiconductor region 6 of the n-type that is formed in the surface layer portion of the first main surface 3. In this case, the trench resistor structures 41 are formed in the first main surface 3 such as to be positioned inside the first semiconductor region 6.

In such a structure, the semiconductor device 1 preferably includes the fourth well regions 75 (fifth well regions 76) of the p-type that are formed in the regions along the trench resistor structures 41 inside the first semiconductor region 6 such as to form pn junction portions with the first semiconductor region 6. According to this structure, the withstand voltage (for example, the breakdown voltage) can be improved by depletion layers spreading with the fourth well regions 75 (fifth well regions 76) as starting points.

The semiconductor device 1 may include the gate subpad 103 that has the lower resistance value than the trench resistor structures 41 and is arranged on the first main surface 3 such as to be electrically connected to the gate pad 101 via the trench resistor structures 41.

According to this structure, the resistance value between the gate pad 101 and the gate wiring 102 can be measured indirectly by measuring the resistance value between the gate pad 101 and the gate subpad 103. Preferably, the gate subpad 103 is formed narrower than the gate pad 101 and formed wider than the gate wiring 102. The gate subpad 103 may be connected to the gate wiring 102.

The semiconductor device 1 may include the outer well region 91 of the p-type that is formed in the surface layer portion of the first main surface 3 in the outer region 13. According to this structure, an electric field in the outer region 13 can be relaxed by the outer well region 91. The semiconductor device 1 may include at least one of the field regions 93 of the p-type that are formed in the surface layer portion of the first main surface 3 in the outer region 13. According to this structure, the electric field in the outer region 13 can be relaxed by the field regions 93.

In another aspect, the semiconductor device 1 includes the chip 2, the first trench resistor structures 42 (first groove structures), the first dummy trench structures 61 (second groove structures), the second trench resistor structures 43 (third groove structures), the second dummy trench structures 62 (fourth groove structures), the first mesa portions 71, and the second mesa portions 72. The chip 2 has the first main surface 3. The first trench resistor structures 42 are formed in the first main surface 3. The first dummy trench structures 61 are formed in the first main surface 3 such as to be adjacent to the first trench resistor structures 42 in the first direction X.

The second trench resistor structures 43 are formed in the first main surface 3 such as to be adjacent to the first trench resistor structures 42 in the second direction Y orthogonal to the first direction X. The second dummy trench structures 62 are formed in the first main surface 3 such as to be adjacent to the second trench resistor structures 43 in the first direction X. The first mesa portions 71 are demarcated in the regions between the first trench resistor structures 42 and the first dummy trench structures 61. The second mesa portions 72 are demarcated to be shifted in the first direction X with respect to the first mesa portions 71 in the regions between the second trench resistor structures 43 and the second dummy trench structures 62.

According to this structure, an electric field to be generated in the second mesa portions 72 can be suppressed from interfering with an electric field to be generated in the first mesa portions 71. Electric field concentration with respect to the first mesa portions 71 and electric field concentration with respect to the second mesa portions 72 can thereby be suppressed. The semiconductor device 1 having a novel layout by which the withstand voltage (for example, a breakdown voltage) can be improved can thus be provided.

Such a structure is particularly effective in a case where an electric field due to a potential difference between the first dummy trench structures 61 and the first trench resistor structures 42 is generated in the first mesa portions 71 and an electric field due to a potential difference between the second dummy trench structures 62 and the second trench resistor structures 43 is generated in the second mesa portions 72. Therefore, a potential differing from that at the first trench resistor structures 42 may be applied to the first dummy trench structures 61 and a potential differing from that at the second trench resistor structures 43 may be applied to the second dummy trench structures 62.

The first potential may be applied to the first trench resistor structures 42 and the second trench resistor structures 43 and, the second potential differing from the first potential may be applied to the first dummy trench structures 61 and the second dummy trench structures 62. The first potential may be the gate potential VG and the second potential may be the source potential VS.

The second dummy trench structures 62 are preferably formed in the first main surface 3 such as to be adjacent to the first dummy trench structures 61 in the second direction Y. The second trench resistor structures 43 may be formed deeper than the first trench resistor structures 42. In this case, the second dummy trench structures 62 are preferably formed deeper than the first dummy trench structures 61.

According to this structure, bias of electric field due to the difference in depth between the first trench resistor structures 42 and the second trench resistor structures 43 can be relaxed. In this case, the first dummy trench structures 61 are preferably formed at a substantially equal depth to the first trench resistor structures 42. Also, the second dummy trench structures 62 are formed at a substantially equal depth to the second trench resistor structures 43.

The semiconductor device 1 includes the main mesa portions 70 that are demarcated between the first trench resistor structures 42 and the second trench resistor structures 43. In this case, the first mesa portions 71 and the second mesa portions 72 are connected to the main mesa portions 70. The width in the first direction X of the first mesa portions 71 is preferably not less than 0.5 times and not more than 2 times the width of the main mesa portion 70 in the second direction Y. Also, the width in the first direction X of the second mesa portions 72 is preferably not less than 0.5 times and not more than 2 times the width of the main mesa portion 70 in the second direction Y.

The first trench resistor structures 42 preferably each extend in the band shape in the first direction X. The second trench resistor structures 43 preferably each extend in the band shape in the first direction X. The first dummy trench structures 61 preferably each extend in the band shape in the first direction X. The second dummy trench structures 62 preferably each extend in the band shape in the first direction X.

The semiconductor device 1 may include the active mesa 11 that is demarcated in the first main surface 3 by the active surface 8 formed at the inner portion of the first main surface 3, the outer surface 9 formed at the peripheral edge portion of the first main surface 3 such as to be recessed in the thickness direction of the chip 2 from the active surface 8, and the first to fourth connecting surfaces 10A to 10D connecting the active surface 8 and the outer surface 9. In this case, the first trench resistor structures 42, the second trench resistor structures 43, the first dummy trench structures 61, and the second dummy trench structures 62 are preferably formed in the active surface 8.

The first trench resistor structures 42 and the second trench resistor structures 43 are preferably formed in the active surface 8 at intervals from the first to fourth connecting surfaces 10A to 10D. The first dummy trench structures 61 may be formed in the active surface 8 such as to be exposed from the third connecting surface 10C (fourth connecting surface 10D). Also, the second dummy trench structures 62 may be formed in the active surface 8 such as to be exposed from the third connecting surface 10C (fourth connecting surface 10D).

The semiconductor device 1 may include a side wall structure that is arranged on the outer surface 9 such as to cover at least one of the first to fourth connecting surfaces 10A to 10D. In this case, the side wall structure preferably consists of the side wall wiring 95 that is electrically connected to the first dummy trench structures 61 and the second dummy trench structures 62. According to this structure, the potential differing from the potential applied to the first trench resistor structures 42 and the second trench resistor structures 43 can be applied from the outer surface 9 side to the first dummy trench structures 61 and the second dummy trench structures 62 by the side wall wiring 95.

The semiconductor device 1 may include the first semiconductor region 6 of the n-type that is formed in the surface layer portion of the first main surface 3. The semiconductor device 1 may include the body region 17 of the p-type that is formed in a surface layer portion of the first semiconductor region 6. In this case, the first trench resistor structures 42, the second trench resistor structures 43, the first dummy trench structures 61, and the second dummy trench structures 62 preferably penetrate through the body region 17 such as to reach the first semiconductor region 6.

The first trench resistor structures 42 and the second trench resistor structures 43 preferably do not contribute to the control of the channels. According to this structure, malfunction due to the first trench resistor structures 42 and the second trench resistor structures 43 can be suppressed appropriately. The first dummy trench structures 61 and the second dummy trench structures 62 preferably do not contribute to the control of the channels. According to this structure, according to this structure, malfunction due to the first dummy trench structures 61 and the second dummy trench structures 62 can be suppressed appropriately.

The semiconductor device 1 may include the second contact regions 79 of the p-type that are formed in the regions inside the first semiconductor region 6 along the second trench resistor structures 43. In this case, the second contact regions 79 are preferably formed in the regions along the second trench resistor structures 43 at intervals from the second mesa portions 72.

The second contact regions 79 are particularly preferably formed to be shifted in the first direction X with respect to the first mesa portions 71. In this case, the second contact regions 79 preferably do not oppose the first mesa portions 71 in the second direction Y. According to this structure, an electric field associated with the first mesa portions 71 and an electric field associated with the second mesa portions 72 can be relaxed appropriately.

The semiconductor device 1 may include the third contact regions 80 of the p-type that are formed in the regions inside the first semiconductor region 6 along the second dummy trench structures 62. In this case, the third contact regions 80 are preferably formed in the regions along the second dummy trench structures 62 at intervals from the second mesa portions 72. The third contact regions 80 are particularly preferably formed to be shifted in the first direction X with respect to the first mesa portions 71. In this case, the third contact regions 80 preferably do not oppose the first mesa portions 71 in the second direction Y.

The chip 2 preferably includes the monocrystal of the wide bandgap semiconductor. The monocrystal of the wide bandgap semiconductor is effective in terms of improving electrical characteristics. Also, with the monocrystal of the wide bandgap semiconductor, by a comparatively high hardness, thinning of the chip 2 and increase in planar area of the chip 2 can be achieved while suppressing deformation of the chip 2.

The thinning of the chip 2 and the expansion of the planar area of the chip 2 are also effective in terms of improving the electrical characteristics. For example, the chip 2 may have the first main surface 3 having an area of not less than 1 mm square in plan view. For example, the chip 2 may have a thickness of not more than 200 μm. The chip 2 preferably has the thickness of not more than 100 μm in cross-sectional view.

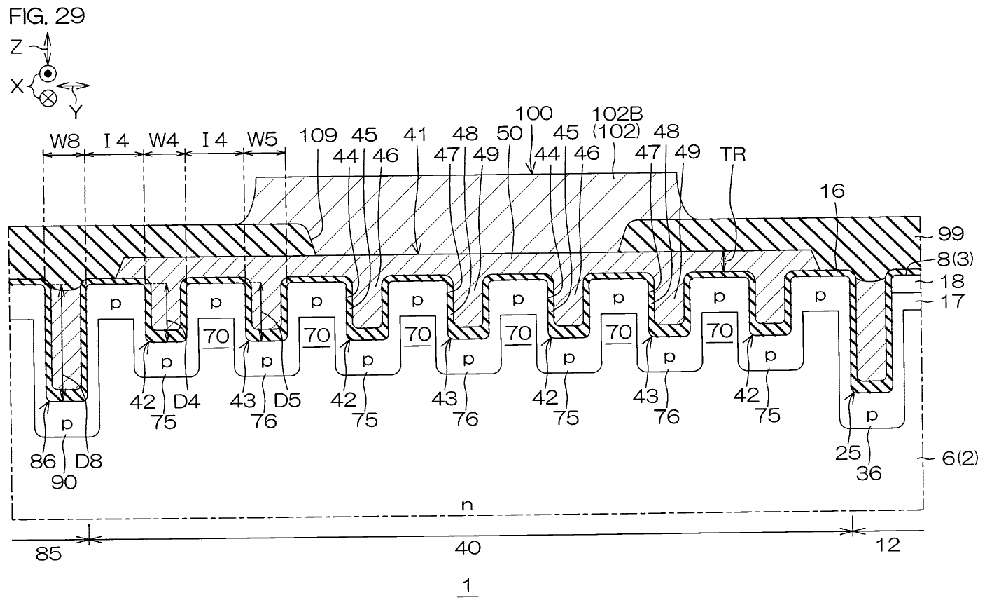

Hereinafter, various modification examples applied to the embodiment shall be described with reference to FIG. 29 to FIG. 34. FIG. 29 is a cross sectional view showing the trench resistor structures 41 according to a first modification example. The trench resistor structures 41 according to the embodiment described above include the second trench resistor structures 43 having the fifth depth D5 greater than the fourth depth D4 (first depth D1) of the first trench resistor structures 42. On the other hand, the trench resistor structures 41 according to the first modification example include the second trench resistor structures 43 having the fifth depth D5 that is substantially equal to the fourth depth D4 of the first trench resistor structures 42.

That is, the trench resistor structures 41 according to the first modification example has a structure that can be regarded as including just a plurality of the first trench resistor structures 42 and not including the plurality of the second trench resistor structures 43. Although the second contact regions 79 are not formed in the regions along the second trench resistor structures 43 in this example, the second contact regions 79 may be formed in the regions along the second trench resistor structures 43.

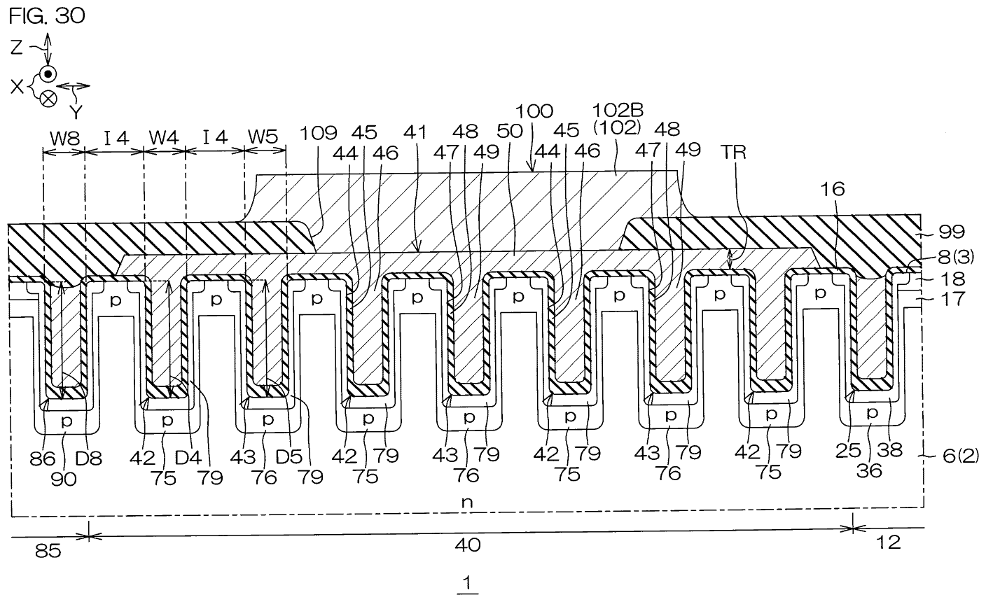

FIG. 30 is a cross sectional view showing the trench resistor structures 41 according to a second modification example. The trench resistor structures 41 according to the embodiment described above include the first trench resistor structures 42 having the fourth depth D4 substantially equal to the first depth D1 of the trench gate structures 20. On the other hand, the trench resistor structures 41 according to the second modification example include the first trench resistor structures 42 having the fourth depth D4 that is substantially equal to the second depth D2 of the first trench source structures 25.

That is, the trench resistor structures 41 according to the second modification example has a structure that can be regarded as including just a plurality of the second trench resistor structures 43 and not including the plurality of first trench resistor structures 42. Although the second contact regions 79 are formed in the regions along the first trench resistor structures 42 in this example, the second contact regions 79 do not have to be formed in the regions along the first trench resistor structures 42.

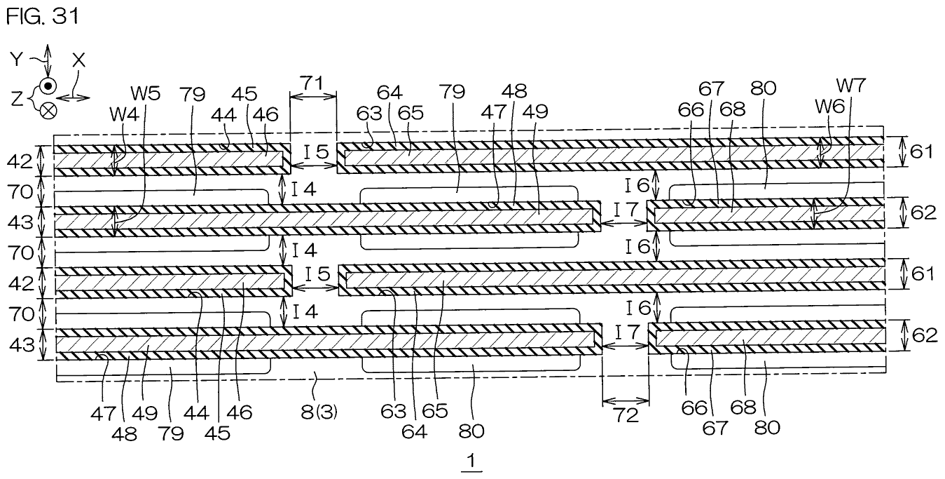

FIG. 31 is an enlarged plan view showing the trench resistor structures 41 according to a third modification example. The trench resistor structures 41 according to the embodiment described above include the second trench resistor structures 43 having both end portions that are set back inward with respect to both end portions of the first trench resistor structures 42. On the other hand, the trench resistor structures 41 according to the third modification example include the second trench resistor structures 43 having the second resistor length L2 that is longer than the first resistor length L1. Both end portions of the second trench resistor structures 43 protrude further to the outer surface 9 side than both end portions of the first trench resistor structures 42.

As in the embodiment described above, the resistive film 50 has the third resistor length L3 in the first direction X that is shorter than the first resistor length L1 of the first trench resistor structures 42 and the second resistor length L2 of the second trench resistor structures 43. As a matter of course, the resistive film 50 may cover the whole region of the plurality of trench resistor structures 41.

That is, the third resistor length L3 may be greater than the second resistor length L2. Also, the resistive film 50 may cover both end portions of the plurality of first trench resistor structures 42 and expose both end portions of the plurality of second trench resistor structures 43. That is, the third resistor length L3 may be greater than the first resistor length L1 and smaller than the second resistor length L2.

In this example, the first dummy trench structures 61 each have a portion that is drawn out to an end portion side of the first trench resistor structures 42 with respect to end portions of the second trench resistor structures 43. Thereby, end portions of the first dummy trench structures 61 oppose the first trench resistor structures 42 in the first direction X and oppose the second trench resistor structures 43 in the second direction Y. On the other hand, the second dummy trench structures 62 are each arranged in a region between two first dummy trench structures 61 that are adjacent in the second direction Y and oppose the second trench resistor structures 43 in the first direction X and oppose the first dummy trench structures 61 in the second direction Y.

In this example, each first mesa portion 71 is shifted to the second trench resistor structure 43 side with respect to end portions of the second dummy trench structures 62 such as to oppose the second trench resistor structures 43 in the second direction Y and not to oppose the second dummy trench structures 62 in the second direction Y. Each first mesa portion 71 is formed at an interval in the first direction X from the peripheral edge of the resistive film 50 and does not oppose the resistive film 50 in the normal direction Z.

Therefore, electrical interference of the resistive film 50 on each first mesa portion 71 is suppressed and electrical interference of each first mesa portion 71 on the resistive film 50 is suppressed. As a matter of course, if the resistive film 50 that is wider than the plurality of trench resistor structures 41 is formed, each first mesa portion 71 may oppose the resistive film 50 in the normal direction Z.

Each first mesa portion 71 demarcates, with a main mesa portion 70, a mesa of T-shape in plan view. In another aspect, each first mesa portion 71 demarcates, with two main mesa portions 70, a mesa of H-shape in plan view. In this embodiment, the plurality of first mesa portions 71 are formed on the same straight line along the second direction Y. As a matter of course, the plurality of first mesa portions 71 may be formed to be shifted with respect to each other in the first direction X such as not to be positioned on the same straight line along the second direction Y.

On the other hand, in this example, each second mesa portion 72 is shifted to the first dummy trench structure 61 side with respect to the end portions of the first trench resistor structures 42 such as to oppose the first dummy trench structures 61 in the second direction Y and not to oppose the first trench resistor structures 42 in the second direction Y. Each second mesa portion 72 is formed at an interval in the first direction X from the peripheral edge of the resistive film 50 and does not oppose the resistive film 50 in the normal direction Z in plan view.

Therefore, electrical interference of the resistive film 50 with respect to each second mesa portion 72 is suppressed and electrical interference of each second mesa portion 72 with respect to the resistive film 50 is suppressed. As a matter of course, when the resistive film 50 that is wider than the plurality of trench resistor structures 41 is formed, each second mesa portion 72 may oppose the resistive film 50 in the normal direction Z.

Each second mesa portion 72 demarcates, with one main mesa portion 70, a mesa of T-shape in plan view. In another aspect, each second mesa portion 72 demarcates, with two main mesa portions 70, a mesa of H-shape in plan view. In this embodiment, the plurality of second mesa portions 72 are formed on the same straight line along the second direction Y.

As a matter of course, the plurality of second mesa portions 72 may be formed to be shifted with respect to each other in the first direction X such as not to be positioned on the same straight line along the second direction Y. Even in this case, the plurality of second mesa portions 72 are formed at an interval in the first direction X from the first mesa portions 71 such as not to oppose the first mesa portions 71 in the second direction Y.

As in the embodiment, the plurality of second contact regions 79 are formed at intervals in the regions along the respective second trench resistor structures 43. The plurality of second contact regions 79 are formed at intervals along the respective second trench resistor structures 43 such that a first mesa portion 71 is positioned between two mutually adjacent second contact regions 79. In this example, the plurality of second contact regions 79 are formed at intervals in the first direction X from the first mesa portions 71 such as not to oppose the first mesa portions 71.

For example, in the first direction X, a distance between the first mesa portions 71 and the second contact regions 79 is preferably less than the length of the second contact regions 79. The distance between the first mesa portions 71 and the second contact regions 79 is preferably less than the fifth width W5 of the second trench resistor structures 43. The distance between the first mesa portions 71 and the second contact regions 79 is particularly preferably less than the width of the first mesa portions 71 (the fifth interval I5).

The plurality of second contact regions 79 include at least one (in this example, one) outermost second contact region 79 formed in a range between the first mesa portions 71 and the second mesa portions 72. The outermost second contact region 79 opposes the first dummy trench structures 61 in the second direction Y.

The outermost second contact region 79 is preferably formed at intervals in the first direction X from the first mesa portions 71 and the second mesa portions 72. That is, the outermost second contact region 79 preferably opposes the first dummy trench structures 61 in the second direction Y but does not oppose the first trench resistor structures 42 in the second direction Y.

For example, in the first direction X, a distance between the second mesa portions 72 and the outermost second contact region 79 is preferably less than the length of the outermost second contact region 79. The distance between the second mesa portions 72 and the outermost second contact region 79 is preferably less than the fifth width W5 of the second trench resistor structures 43. The distance between the second mesa portions 72 and the outermost second contact region 79 is particularly preferably less than the width of the second mesa portions 72 (the seventh interval I7).

As in the embodiment, the plurality of third contact regions 80 are formed at intervals in the regions along the respective second dummy trench structures 62. In this embodiment, the plurality of third contact regions 80 oppose the first dummy trench structures 61 in the second direction Y but do not oppose the first trench resistor structures 42 in the second direction Y.

The plurality of third contact regions 80 include outermost third contact regions 80 each covering a region along an end portion of the second dummy trench structure 62. The outermost third contact regions 80 are formed such as to sandwich the second mesa portions 72 with the outermost second contact region 79. The outermost third contact regions 80 are preferably formed at an interval in the first direction X from the second mesa portions 72.

For example, in the first direction X, a distance between the second mesa portions 72 and the outermost third contact regions 80 may be less than the length of the outermost third contact regions 80. The distance between the second mesa portions 72 and the outermost third contact regions 80 is particularly preferably less than the seventh width W7 of the dummy trench structures 60.

The distance between the second mesa portions 72 and the outermost third contact regions 80 is particularly preferably less than the width of the second mesa portions 72 (the seventh interval I7). A distance between the outermost second contact region 79 that is adjacent with the second mesa portions 72 interposed therebetween and the outermost third contact region 80 is preferably substantially equal to a distance between two second contact regions 79 that are adjacent with the first mesa portions 71 interposed therebetween.

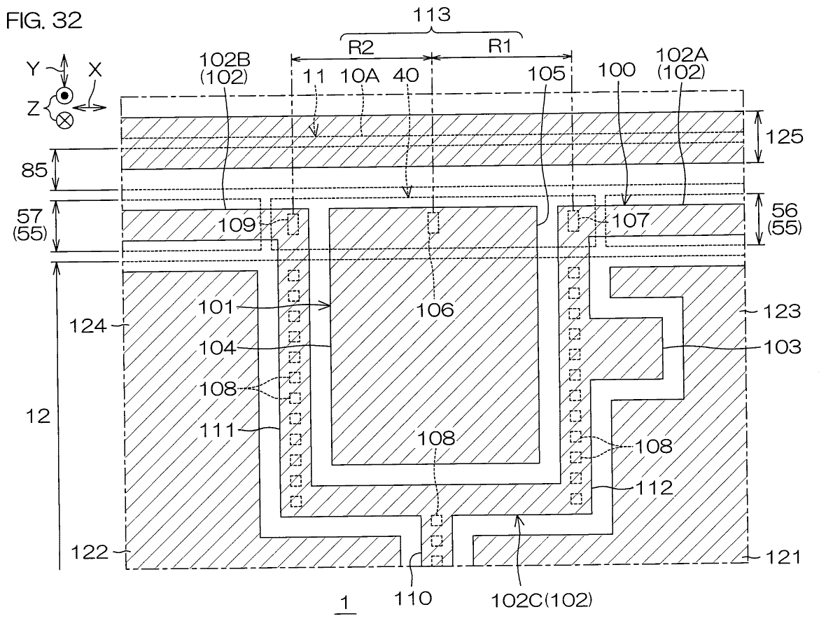

FIG. 32 is an enlarged plan view showing the gate pad 101 according to a modification example. The gate pad 101 according to the embodiment described above includes the pad main body portion 104 that is wider than the gate resistor 40 (the trench gate structures 20) in the first direction X and the drawer portion 105 that is narrower than the gate resistor 40 (the trench gate structures 20) in the first direction X.

On the other hand, the gate pad 101 according to the modification example includes the pad main body portion 104 that is narrower than the gate resistor 40 (the trench gate structures 20) in the first direction X and the drawer portion 105 that is narrower than the gate resistor 40 (the trench gate structures 20) in the first direction X. In this example, the drawer portion 105 has the width substantially equal to that of the pad main body portion 104 in the first direction X.

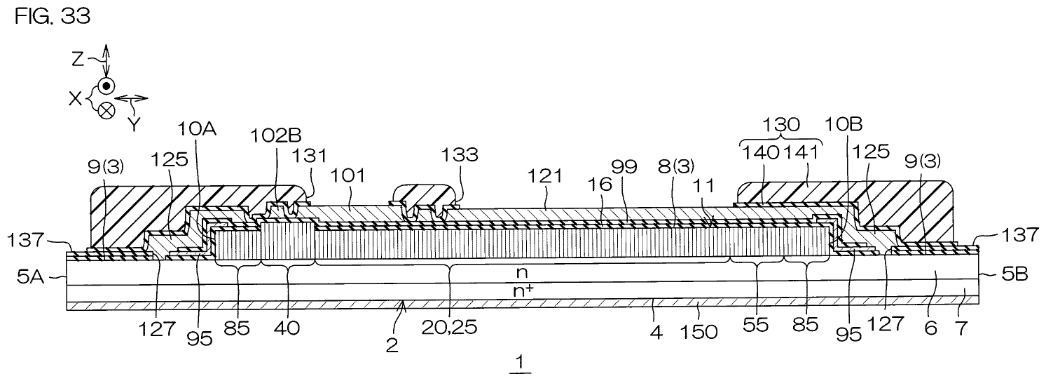

FIG. 33 is a cross sectional view showing the chip 2 according to a first modification example. With reference to FIG. 33, the semiconductor device 1 may, in an interior of the chip 2, include the second semiconductor region 7 having the thickness smaller than the thickness of the first semiconductor region 6. That is, the chip 2 may include the epitaxial layer that is thicker than the semiconductor substrate.

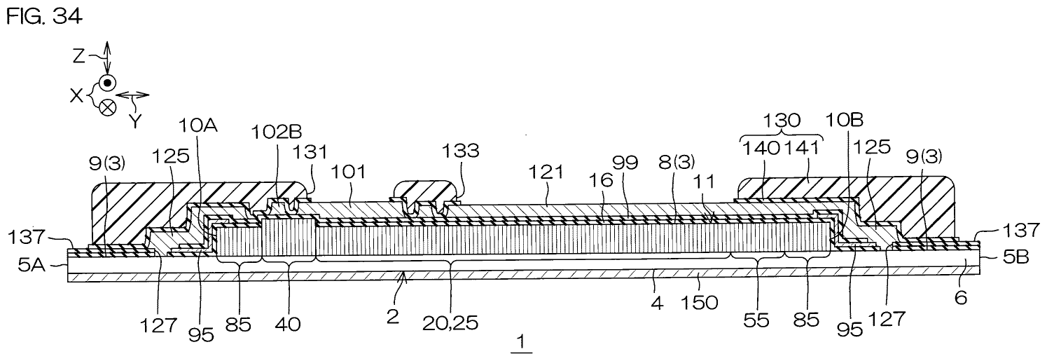

FIG. 34 is a cross sectional view showing the chip 2 according to a second modification example. With reference to FIG. 34, the semiconductor device 1 may, in the interior of the chip 2, be without the second semiconductor region 7 and include just the first semiconductor region 6. In this case, the first semiconductor region 6 is exposed from the first main surface 3, the second main surface 4, and the first to fourth side surfaces 5A to 5D of the chip 2. That is, in this embodiment, the chip 2 does not have the semiconductor substrate and has a single layer structure consisting of the epitaxial layer.

The embodiment described above can be implemented in yet other modes. With each embodiment described above, a mode in which the “first conductivity type” is the “n-type” and the “second conductivity type” is the “p-type” was illustrated. However, in each embodiment described above, a mode in which the “first conductivity type” is the “p-type” and the “second conductivity type” is the “n-type” may be adopted. A specific configuration in this case can be obtained by replacing the “n-type” with the “p-type” at the same time as replacing the “p-type” with the “n-type” in the above descriptions and attached drawings.

In the embodiment described above, the second semiconductor region 7 of the n-type was illustrated. However, the second semiconductor region 7 of the p-type may be adopted. In this case, an IGBT (insulated gate bipolar transistor) is formed instead of the MISFET. In this case, in the above descriptions, the “source” of the MISFET is replaced with an “emitter” of the IGBT and the “drain” of the MISFET is replaced with a “collector” of the IGBT. The second semiconductor region 7 of the p-type may be an impurity region that contains a p-type impurity introduced into a surface layer portion of the second main surface 4 of the chip 2 by an ion implantation method.

Hereinafter, examples of features extracted from the present description and the attached drawings shall be indicated below. Hereinafter, the alphanumeric characters, etc., in parentheses represent the corresponding components, etc., in the embodiment described above, but are not intended to limit the scope of each clause to the embodiment. The “semiconductor device” in the following clauses may be replaced with a “wide bandgap semiconductor device,” an “SiC semiconductor device,” a “semiconductor switching device,” an “SiC MISFET,” etc., as needed.

[A1] A semiconductor device (1) comprising: a chip (2) that has a main surface (3); a gate resistor (40) that includes a trench resistor structure (41 to 43) formed in the main surface (3); a gate pad (101) that has a lower resistance value than the trench resistor structure (41 to 43) and is arranged on the main surface (3) such as to be electrically connected to the trench resistor structure (41 to 43); and a gate wiring (102) that has a lower resistance value than the trench resistor structure (41 to 43) and is arranged on the main surface (3) such as to be electrically connected to the gate pad (101) via the trench resistor structure (41 to 43).

[A2] The semiconductor device (1) according to A1, wherein the gate pad (101) has a portion that is positioned directly above the trench resistor structure (41 to 43), and the gate wiring (102) has a portion that is positioned directly above the trench resistor structure (41 to 43).

[A3] The semiconductor device (1) according to A1 or A2, wherein the trench resistor structure (41 to 43) does not contribute to control of a channel.

[A4] The semiconductor device (1) according to any one of A1 to A3, wherein the gate resistor (40) includes a resistive film (50) that covers the trench resistor structure (41 to 43), the gate pad (101) is electrically connected to the resistive film (50), and the gate wiring (102) is electrically connected to the resistive film (50).

[A5] The semiconductor device (1) according to A4, wherein the resistive film (50) has a portion covering the main surface (3) and a portion covering the trench resistor structure (41 to 43).

[A6] The semiconductor device (1) according to A4 or A5, wherein the gate pad (101) opposes the trench resistor structure (41 to 43) with the resistive film (50) interposed therebetween, and the gate wiring (102) opposes the trench resistor structure (41 to 43) with the resistive film (50) interposed therebetween.

[A7] The semiconductor device (1) according to any one of A4 to A6, further comprising: an insulating film (99) that covers the resistive film (50); and wherein the gate pad (101) penetrates through the insulating film (99) and is connected to the resistive film (50) and the gate wiring (102) penetrates through the insulating film (99) and is connected to the resistive film (50).

[A8] The semiconductor device (1) according to any one of A1 to A7, wherein the trench resistor structures (41 to 43) are formed in the main surface (3).

[A9] The semiconductor device (1) according to A8, wherein the trench resistor structures (41 to 43) include a first trench resistor structure (42) and a second trench resistor structure (43) that is deeper than the first trench resistor structure (42).

[A10] The semiconductor device (1) according to any one of A1 to A9, further comprising: an active region (12) that is provided in an inner portion of the main surface (3); an outer region (13) that is provided in a peripheral edge portion of the main surface (3); and a terminal region (15) that is provided between the active region (12) and the outer region (13); and wherein the trench resistor structure (41 to 43) is formed in the main surface (3) in the terminal region (15), the gate pad (101) is electrically connected to the trench resistor structure (41 to 43) in the terminal region (15), and the gate wiring (102) is electrically connected to the gate pad (101) via the trench resistor structure (41 to 43) in the terminal region (15).

[A11] The semiconductor device (1) according to A10, further comprising: a trench gate structure (20) that is formed in the main surface (3) in the active region (12), and wherein the gate wiring (102) is electrically connected to the trench gate structure (20) in the active region (12).

[A12] The semiconductor device (1) according to A11, further comprising: a trench source structure (25, 30) that is formed in the main surface (3) such as to be adjacent to the trench gate structure (20) in the active region (12).

[A13] The semiconductor device (1) according to A12, wherein the trench source structure (25, 30) is deeper than the trench gate structure (20).

[A14] The semiconductor device (1) according to any one of A10 to A13, further comprising: a dummy trench structure (60 to 62) that is formed in the main surface (3) such as to be adjacent to the trench resistor structure (41 to 43) in the terminal region (15).

[A15] The semiconductor device (1) according to A14, wherein the dummy trench structures (60 to 62) are formed in the main surface (3).

[A16] The semiconductor device (1) according to A15, wherein the dummy trench structures (60 to 62) include a first dummy trench structure (61) and a second dummy trench structure (62) that is deeper than the first dummy trench structure (61).

[A17] The semiconductor device (1) according to any one of A10 to A16, further comprising: an active mesa (11) that is demarcated in the main surface (3) by a first surface portion (8) formed at an inner portion of the main surface (3), a second surface portion (9) formed at a peripheral edge portion of the main surface (3) such as to be recessed in a thickness direction of the chip (2) from the first surface portion (8), and a connecting surface portion (10A to 10D) connecting the first surface portion (8) and the second surface portion (9); and wherein the active region (12) is provided in the first surface portion (8), the outer region (13) is provided in the second surface portion (9), and the terminal region (15) is provided in the first surface portion (8).

[A18] The semiconductor device (1) according to any one of A1 to A17, further comprising: a semiconductor region (6) of a first conductivity type (n-type) that is formed in a surface layer portion of the main surface (3); the trench resistor structure (41 to 43) that is formed in the main surface (3) such as to be positioned inside the semiconductor region (6); and a well region (75, 76) of a second conductivity type (p-type) that is formed in a region inside the semiconductor region (6) along the trench resistor structure (41 to 43) such as to form a pn junction portion with the semiconductor region (6).

[A19] The semiconductor device (1) according to any one of A1 to A18, further comprising: a gate subpad (103) that has a lower resistance value than the trench resistor structure (41 to 43) and is arranged on the main surface (3) such as to be electrically connected to the gate pad (101) via the trench resistor structure (41 to 43).

[A20] The semiconductor device (1) according to A19, wherein the gate subpad (103) is formed to be narrower than the gate pad (101) and wider than the gate wiring (102).

[B1] A semiconductor device (1) comprising: a chip (2) that has a main surface (3); a first groove structure (42) that is formed in the main surface (3); a second groove structure (61) that is formed in the main surface (3) such as to be adjacent to the first groove structure (42) in a first direction (X); a third groove structure (43) that is formed in the main surface (3) such as to be adjacent to the first groove structure (42) in a second direction (Y) orthogonal to the first direction (X); a fourth groove structure (62) that is formed in the main surface (3) such as to be adjacent to the third groove structure (43) in the first direction (X); a first mesa portion (71) that is demarcated in a region between the first groove structure (42) and the second groove structure (61); and a second mesa portion (72) that is demarcated to be shifted in the first direction (X) with respect to the first mesa portion (71) in a region between the third groove structure (43) and the fourth groove structure (62).

[B2] The semiconductor device (1) according to B1, wherein a potential differing from that at the first groove structure (42) is to be applied to the second groove structure (61) and a potential differing from that at the third groove structure (43) is to be applied to the fourth groove structure (62).

[B3] The semiconductor device (1) according to B2, wherein a first potential is to be applied to the first groove structure (42), a second potential differing from the first potential is to be applied to the second groove structure (61), the first potential is to be applied to the third groove structure (43), and the second potential is to be applied to the fourth groove structure (62).

[B4] The semiconductor device (1) according to B3, wherein the first potential is a gate potential (VG), and the second potential is a source potential (VS).

[B5] The semiconductor device (1) according to any one of B1 to B4, wherein the fourth groove structure (62) is formed in the main surface (3) such as to be adjacent to the second groove structure (61) in the second direction (Y).

[B6] The semiconductor device (1) according to any one of B1 to B5, wherein the third groove structure (43) is formed deeper than the first groove structure (42), and the fourth groove structure (62) is formed deeper than the second groove structure (61).

[B7] The semiconductor device (1) according to B6, wherein the second groove structure (61) is formed at a substantially equal depth to the first groove structure (42), and the fourth groove structure (62) is formed at a substantially equal depth to the third groove structure (43).

[B8] The semiconductor device (1) according to any one of B1 to B7, further comprising: a main mesa portion (70) that is demarcated in a region between the first groove structure (42) and the third groove structure (43) and in a region between the second groove structure (61) and the fourth groove structure (62); and wherein the first mesa portion (71) is connected to the main mesa portion (70), and the second mesa portion (72) is connected to the main mesa portion (70).

[B9] The semiconductor device (1) according to B8, wherein a width in the first direction (X) of the first mesa portion (71) is not less than 0.5 times and not more than 2 times a width in the second direction (Y) of the main mesa portion (70), and a width in the first direction (X) of the second mesa portion (72) is not less than 0.5 times and not more than 2 times the width in the second direction (Y) of the main mesa portion (70).

[B10] The semiconductor device (1) according to any one of B1 to B9, wherein the first groove structure (42) extends in a band shape in the first direction (X), the second groove structure (61) extends in a band shape in the first direction (X), the third groove structure (43) extends in a band shape in the first direction (X), and the fourth groove structure (62) extends in a band shape in the first direction (X).

[B11] The semiconductor device (1) according to any one of B1 to B10, further comprising: an active mesa (11) that is demarcated in the main surface (3) by a first surface portion (8) formed at an inner portion of the main surface (3), a second surface portion (9) formed at a peripheral edge portion of the main surface (3) such as to be recessed in a thickness direction of the chip (2) from the first surface portion (8), and a connecting surface portion (10A to 10D) connecting the first surface portion (8) and the second surface portion (9); and wherein the first groove structure (42) is formed in the first surface portion (8), the second groove structure (61) is formed in the first surface portion (8), the third groove structure (43) is formed in the first surface portion (8), and the fourth groove structure (62) is formed in the first surface portion (8).

[B12] The semiconductor device (1) according to B11, wherein the first groove structure (42) is formed in the first surface portion (8) at an interval from the connecting surface portion (10A to 10D), the second groove structure (61) is formed in the first surface portion (8) such as to be exposed from the connecting surface portion (10A to 10D), the third groove structure (43) is formed in the first surface portion (8) at an interval from the connecting surface portion (10A to 10D), and the fourth groove structure (62) is formed in the first surface portion (8) such as to be exposed from the connecting surface portion (10A to 10D).

[B13] The semiconductor device (1) according to B11 or B12, further comprising: a side wall structure that is arranged on the second surface portion (9) such as to cover the connecting surface portion (10A to 10D).

[B14] The semiconductor device (1) according to B13, wherein the side wall structure consists of a side wall wiring (95) that is electrically connected to the second groove structure (61) and the fourth groove structure (62).

[B15] The semiconductor device (1) according to any one of B1 to B14, further comprising: a semiconductor region (6) of a first conductivity type (n-type) that is formed in a surface layer portion of the main surface (3); and a body region (17) of a second conductivity type (p-type) that is formed in a surface layer portion of the semiconductor region (6); and wherein the first groove structure (42) penetrates through the body region (17) such as to reach the semiconductor region (6), the second groove structure (61) penetrates through the body region (17) such as to reach the semiconductor region (6), the third groove structure (43) penetrates through the body region (17) such as to reach the semiconductor region (6), and the fourth groove structure (62) penetrates through the body region (17) such as to reach the semiconductor region (6).

[B16] The semiconductor device (1) according to B15, further comprising: a first contact region (79) of the second conductivity type (p-type) that is formed in a region inside the semiconductor region (6) along the third groove structure (43); and a second contact region (80) of the second conductivity type (p-type) that is formed in a region inside the semiconductor region (6) along the fourth groove structure (62).

[B17] The semiconductor device (1) according to B16, wherein the first contact region (79) is formed in the region along the third groove structure (43) at an interval from the second mesa portion (72), and the second contact region (80) is formed in the region along the fourth groove structure (62) at an interval from the second mesa portion (72).

[B18] The semiconductor device (1) according to B16 or B17, wherein the first contact region (79) is formed to be shifted in the first direction (X) with respect to the first mesa portion (71), and the second contact region (80) is formed to be shifted in the first direction (X) with respect to the first mesa portion (71).

[B19] The semiconductor device (1) according to any one of B1 to B18, further comprising: an insulating film (99) that covers the first groove structure (42); and a gate electrode (100) that is arranged on the insulating film (99) such as to oppose the first groove structure (42) with the insulating film (99) interposed therebetween.

[B20] The semiconductor device (1) according to any one of B1 to B19, wherein the chip (2) includes a wide bandgap semiconductor.

While an embodiment of the present invention has been described in detail above, this is merely a specific example used to clarify the technical contents. The various technical ideas extracted from this Description are not limited by the order of description, the order of embodiments, etc., in the Description and can be combined as appropriate with each other.

What is claimed is:

1. A semiconductor device comprising:
a chip that has a main surface;
a gate resistor that includes a trench resistor structure formed in the main surface;
a gate pad that has a lower resistance value than the trench resistor structure and is arranged on the main surface such as to be electrically connected to the trench resistor structure; and
a gate wiring that has a lower resistance value than the trench resistor structure and is arranged on the main surface such as to be electrically connected to the gate pad via the trench resistor structure.

2. The semiconductor device according to claim 1,
wherein the gate pad has a portion that is positioned directly above the trench resistor structure, and
the gate wiring has a portion that is positioned directly above the trench resistor structure.

3. The semiconductor device according to claim 1,
wherein the trench resistor structure does not contribute to control of a channel.

4. The semiconductor device according to claim 1,
wherein the gate resistor includes a resistive film that covers the trench resistor structure,
the gate pad is electrically connected to the resistive film, and
the gate wiring is electrically connected to the resistive film.

5. The semiconductor device according to claim 4,
wherein the resistive film has a portion covering the main surface and a portion covering the trench resistor structure.

6. The semiconductor device according to claim 4,
wherein the gate pad opposes the trench resistor structure with the resistive film interposed therebetween, and
the gate wiring opposes the trench resistor structure with the resistive film interposed therebetween.

7. The semiconductor device according to claim 4, further comprising:
an insulating film that covers the resistive film; and
wherein the gate pad penetrates through the insulating film and is connected to the resistive film, and
the gate wiring penetrates through the insulating film and is connected to the resistive film.

8. The semiconductor device according to claim 1,
wherein the trench resistor structures are formed in the main surface.

9. The semiconductor device according to claim 8,
wherein the trench resistor structures include a first trench resistor structure and a second trench resistor structure that is deeper than the first trench resistor structure.

10. The semiconductor device according to claim 1, further comprising:
an active region that is provided in an inner portion of the main surface;
an outer region that is provided in a peripheral edge portion of the main surface; and
a terminal region that is provided between the active region and the outer region; and
wherein the trench resistor structure is formed in the main surface in the terminal region,
the gate pad is electrically connected to the trench resistor structure in the terminal region, and
the gate wiring is electrically connected to the gate pad via the trench resistor structure in the terminal region.

11. The semiconductor device according to claim 10, further comprising:
a trench gate structure that is formed in the main surface in the active region, and
wherein the gate wiring is electrically connected to the trench gate structure in the active region.

12. The semiconductor device according to claim 11, further comprising:
a trench source structure that is formed in the main surface such as to be adjacent to the trench gate structure in the active region.

13. The semiconductor device according to claim 12,
wherein the trench source structure is deeper than the trench gate structure.

14. The semiconductor device according to claim 10, further comprising:
a dummy trench structure that is formed in the main surface such as to be adjacent to the trench resistor structure in the terminal region.

15. The semiconductor device according to claim 14,
wherein the dummy trench structures are formed in the main surface.

16. The semiconductor device according to claim 15,
wherein the dummy trench structures include a first dummy trench structure and a second dummy trench structure that is deeper than the first dummy trench structure.

17. The semiconductor device according to claim 10, further comprising:
an active mesa that is demarcated in the main surface by a first surface portion formed at an inner portion of the main surface, a second surface portion formed at a peripheral edge portion of the main surface such as to be recessed in a thickness direction of the chip from the first surface portion, and a connecting surface portion connecting the first surface portion and the second surface portion; and
wherein the active region is provided in the first surface portion,
the outer region is provided in the second surface portion, and
the terminal region is provided in the first surface portion.

18. The semiconductor device according to claim 1, further comprising:
a semiconductor region of a first conductivity type that is formed in a surface layer portion of the main surface;
the trench resistor structure that is formed in the main surface such as to be positioned inside the semiconductor region; and
a well region of a second conductivity type that is formed in a region inside the semiconductor region along the trench resistor structure such as to form a pn junction portion with the semiconductor region.

19. The semiconductor device according to claim 1, further comprising:
a gate subpad that has a lower resistance value than the trench resistor structure and is arranged on the main surface such as to be electrically connected to the gate pad via the trench resistor structure.

20. The semiconductor device according to claim 19,
wherein the gate subpad is formed to be narrower than the gate pad and wider than the gate wiring.
